(19) United States
(12) Patent Application Publication
(10) Pub. No.: US 2025/0384298 A1
(43) Pub. Date: Dec. 18, 2025

(54) Neural Network Representation Formats

(71) Applicant: Fraunhofer-Gesellschaft zur Foerderung der angewandten Forschung e.V., Munich (DE)

(72) Inventors: Stefan MATLAGE, Berlin (DE); Paul HAASE, Berlin (DE); Heiner KIRCHHOFFER, Berlin (DE); Karsten MUELLER, Berlin (DE); Wojciech SAMEK, Berlin (DE); Simon WIEDEMANN, Berlin (DE); Detlev MARPE, Berlin (DE); Thomas SCHIERL, Berlin (DE); Yago SÁNCHEZ DE LA FUENTE, Berlin (DE); Robert SKUPIN, Berlin (DE); Thomas WIEGAND, Berlin (DE)

(21) Appl. No.: 19/303,931

(22) Filed: Aug. 19, 2025

Related U.S. Application Data
(63) Continuation of application No. 17/711,569, filed on Apr. 1, 2022.
Application No. 17/711,569 is a continuation of application No. PCT/EP2020/077352, filed on Sep. 30, 2020.

(30) Foreign Application Priority Data
Oct. 1, 2019 (EP) 19200928.0

(51) Int. Cl. G06N 3/10; G06N 3/08; H03M 7/30; H03M 7/40

(52) U.S. Cl. CPC G06N 3/105; G06N 3/08; H03M 7/70; H03M 7/4018

(57) ABSTRACT

Data stream having a representation of a neural network encoded thereinto, the data stream including serialization parameter indicating a coding order at which neural network parameters, which define neuron interconnections of the neural network, are encoded into the data stream.

### CROSS-REFERENCES TO RELATED APPLICATIONS

This application is a continuation of copending U.S. patent application Ser. No. 17/711,569, filed Apr. 1, 2022, which in turn is a continuation of International Application No. PCT/EP2020/077352, filed Sep. 30, 2020, which is incorporated herein by reference in its entirety, and additionally claims priority from European Application No. EP 19200928.0, filed Oct. 1, 2019, which is incorporated herein by reference in its entirety.

The present application relates to concepts for Neural Network Representation Formats.

### BACKGROUND OF THE INVENTION

Neural Networks (NN) have led to break-throughs in many applications nowadays:
object detection or classification in image/video data
speech/keyword recognition in audio
speech synthesis
optical character recognition
language translation
and so on

However, the applicability in certain usage scenarios is still hampered by the sheer amount of data that is needed to represent NNs. In most cases, this data is comprised by two types of parameters, the weights and bias, that describe the connection between neurons. The weights are usually parameters that perform some type of linear transformation to the input values (e.g., dot product or convolution), or in other words, weight the neuron's inputs, and the bias are offsets that are added after the linear calculation, or in other words, offset the neuron's aggregation of inbound weighted messages. More specifically, these weights, biases and further parameter that characterize each connection between two of the potentially very large number of neurons (up to tens of millions) in each layer (up to hundreds) of the NN occupy the major portion of the data associated to a particular NN. Also, these parameters are typically consisting of sizable floating-point date types. These parameters are usually expressed as large tensors carrying all parameters of each layer. When applications involve frequent transmission/updates of the involved NNs, the data rate that may be used becomes a serious bottle neck. Therefore, efforts to reduce the coded size of NN representations by means of lossy compression of these matrices is a promising approach.

Typically, the parameter tensors are stored in container formats (ONNX (ONNX=Open Neural Network Exchange), Pytorch, TensorFlow, and the like) that carry all data (such as the above parameter matrices) and further properties (such as dimensions of the parameter tensors, type of layers, operations and so on) that that may be used to fully reconstruct the NN and execute it.

It would be advantageous to have a concept at hand which renders transmission/updates of machine learning predictors or, alternatively speaking, machine learning models such as a neural network more efficient such as more efficient in terms of conservation of inference quality with reducing, concurrently, a coded size of NN representations, computational inference complexity, complexity of describing or storing the NN representations, or which enables a more frequent transmission/update of a NN than currently or which even improves the inference quality for a certain task at hand and/or for a certain local input data statistic. Furthermore, it would be advantageous to provide a neural network representation, a derivation of such neural network representation and the usage of such neural network representation in performing neural network based prediction so that the usage of neural networks becomes more effective than currently.

### SUMMARY

An embodiment may have a data stream having a representation of a neural network encoded thereinto, the data stream comprising serialization parameter indicating a coding order at which neural network parameters, which define neuron interconnections of the neural network, are encoded into the data stream, wherein the neural network parameters are coded into the data stream using context-adaptive arithmetic coding.

Another embodiment may have an apparatus for encoding a representation of a neural network into a data stream, wherein the apparatus is configured to provide the data stream with a serialization parameter indicating a coding order at which neural network parameters, which define neuron interconnections of the neural network, are encoded into the data stream, wherein the apparatus is configured to encode, into the data stream, the neural network parameters using context-adaptive arithmetic encoding.

Another embodiment may have an apparatus for decoding a representation of a neural network from a data stream, wherein the apparatus is configured to decode from the data stream a serialization parameter indicating a coding order at which neural network parameters, which define neuron interconnections of the neural network, are encoded into the data stream, wherein the apparatus is configured to decode, from the data stream, the neural network parameters using context-adaptive arithmetic decoding.

Another embodiment may have an apparatus for performing an inference using a neural network, comprising an inventive apparatus for decoding a data stream, so as to derive from the data stream the neural network, and a processor configured to perform the inference based on the neural network.

According to another embodiment, a method for encoding a representation of a neural network into a data stream may have the step of: providing the data stream with a serialization parameter indicating a coding order at which neural network parameters, which define neuron interconnections of the neural network, are encoded into the data stream, wherein the method comprises encoding, into the data stream, the neural network parameters using context-adaptive arithmetic encoding.

According to another embodiment, a method for decoding a representation of a neural network from a data stream may have the step of: decoding from the data stream a serialization parameter indicating a coding order at which neural network parameters, which define neuron interconnections of the neural network, are encoded into the data stream, wherein the method comprises decoding, from the data stream, the neural network parameters using context-adaptive arithmetic decoding.

Another embodiment may have a non-transitory digital storage medium having a computer program stored thereon to perform the inventive methods for encoding and decoding a representation of a neural network when said computer program is run by a computer.

It is a basic idea underlying a first aspect of the present application that a usage of neural networks (NN) is rendered highly efficient, if a serialization parameter is encoded/decoded into/from a data stream having a representation of the NN encoded thereinto. The serialization parameter indicates a coding order at which NN parameters, which define neuron interconnections of the NN, are encoded into the data stream. The neuron interconnections might represent connections between neurons of different NN layers of the NN. In other words, a NN parameter might define a connection between a first neuron associated with a first layer of the NN and a second neuron associated with a second layer of the NN. A decoder might use the coding order to assign NN parameters serially decoded from the data stream to the neuron interconnections.

In particular, using the serialization parameter turns out to efficiently divide a bitstring into meaningful consecutive subsets of the NN parameters. The serialization parameter might indicate a grouping of the NN parameters allowing an efficient execution of the NN. This might be done dependent on application scenarios for the NN. For different application scenarios, an encoder might traverse the NN parameters using different coding orders. Thus, the NN parameters can be encoded using individual coding orders dependent on the application scenario of the NN and the decoder can reconstruct the NN parameters accordingly while decoding, because of the information provided by the serialization parameter. The NN parameters might represent entries of one or more parameter matrices or tensors, wherein the parameter matrices or tensors might be used for inference procedures. It was found that the one or more parameter matrices or tensors of the NN can be efficiently reconstructed by a decoder based on decoded NN parameters and the serialization parameter.

Thus, the serialization parameter allows the usage of different application specific coding orders allowing a flexible encoding and decoding with an improved efficiency. For instance, encoding parameters along different dimensions may benefit the resulting compression performance since the entropy coder may be able to better capture dependencies among them. In another example, it may be desirable to group parameters according to certain application specific criteria, i.e. what part of the input data they relate to or whether they can be jointly executed, so that they can be decoded/inferred in parallel. A further example is to encode the parameters following the General Matrix Matrix (GEMM) product scan order that support efficient memory allocation of the decoded parameters when performing a dot product operation (Andrew Kerr, 2017).

A further embodiment is directed to encoder-side chosen permutations of the data, e.g. in order to achieve, for instance, energy compaction of the NN parameter to be coded and subsequently process/serialize/code the resulting permutated data according to the resulting order. The permutation may, thus, sort the parameters so that same increase or so that same decrease steadily along the coding order.

In accordance with a second aspect of the present application, the inventors of the present application realized that a usage of neural networks, NN, is rendered highly efficient, if a numerical computation representation parameter is encoded/decoded into/from a data stream having a representation of the NN encoded thereinto. The numerical computation representation parameter indicates a numerical representation, e.g. among floating point or fixed point representation, and a bit size at which NN parameters of the NN, which are encoded into the data stream, are to be represented when using the NN for inference. An encoder is configured to encode the NN parameters. A decoder is configured to decode the NN parameters and might be configured to use the numerical representation and bit size for representing the NN parameters decoded from the data stream, DS.

This embodiment is based on the idea, that it may be advantageous to represent the NN parameters and activation values, which activation values result from a usage of the NN parameters at an inference using the NN, both with the same numerical representation and bit size. Based on the numerical computation representation parameter it is possible to compare efficiently the indicated numerical representation and bit size for the NN parameters with possible numerical representations and bit sizes for the activation values. This might be especially advantageous in case of the numerical computation representation parameter indicating a fixed point representation as numerical representation, since then, if both the NN parameters and the activation values can be represented in the fixed point representation, inference can be performed efficiently due to fixed-point arithmetic.

In accordance with a third aspect of the present application, the inventors of the present application realized that a usage of neural networks is rendered highly efficient, if a NN layer type parameter is encoded/decoded into/from a data stream having a representation of the NN encoded thereinto. The NN layer type parameter indicates a NN layer type, e.g., convolutional layer type or fully connected layer type, of a predetermined NN layer of the NN. The data stream is structured into one or more individually accessible portions, each individually accessible portion representing a corresponding NN layer of the NN. The predetermined NN layer represents one of the NN layer of the neural network. Optionally, for each of two or more predetermined NN layer of the NN, the NN layer type parameter is encoded/decoded into/from a data stream, wherein the NN layer type parameter can differ between at least some predetermined NN layer.

This embodiment is based on the idea, that it may be useful, that the data stream comprises the NN layer type parameter for NN layer, in order to, for instance, understand a meaning of the dimensions of a parameter tensor/matrix. Moreover, different layers may be treated differently while encoding in order to better capture the dependencies in the data and lead to a higher coding efficiency, e.g., by using different sets or modes of context models, information that may be crucial for the decoder to know prior to decoding.

Similarly, it may be advantageous to encode/decode into/from a data stream a type parameter indicting a parameter type of the NN parameters. The type parameter may indicate whether the NN parameters represent weights or bias. The data stream is structured into one or more individually accessible portions, each individually accessible portion representing a corresponding NN layer of the NN. An individually accessible portion representing a corresponding predetermined NN layer might be further structured into individually accessible sub-portions. Each individually accessible sub-portion is completely traversed by a coding order before a subsequent individually accessible sub-portion is traversed by the coding order. Into each individually accessible sub-portion, for example, NN parameters and a type parameter are encoded and can be decoded. NN parameter of a first individually accessible sub-portion may be of a different parameter type or of the same parameter type as NN parameter of a second individually accessible sub-portion. Different types of NN parameters associated with the same NN layer might be encoded/decoded into/from different individually accessible sub-portions associated with the same individually accessible portion. The distinction between the parameter types may be beneficial for encoding/decoding when, for instance, different types of dependencies can be used for each type of parameters, or if parallel decoding is wished, etc. It is, for example, possible to encode/decode different types of NN parameters associated with the same NN layer parallel. This enables a higher efficiency in encoding/decoding of the NN parameters and may also benefit the resulting compression performance since the entropy coder may be able to better capture dependencies among the NN parameters.

In accordance with a fourth aspect of the present application, the inventors of the present application realized that a transmission/updating of neural networks is rendered highly efficient, if a pointer is encoded/decoded into/from a data stream having a representation of the NN encoded thereinto. This is due to the fact, that the data stream is structured into individually accessible portions and for each of one or more predetermined individually accessible portions, a pointer points to a beginning of the respective predetermined individually accessible portion. Not all individually accessible portions need to be predetermined individually accessible portions, but it is possible, that all individually accessible portions represent predetermined individually accessible portions. The one or more predetermined individually accessible portions might be set by default or dependent on an application of the NN encoded into the data stream. The pointer indicates, for example, the beginning of the respective predetermined individually accessible portion as data stream position in bytes or as an offset, e.g., a byte offset with respect to a beginning of the data stream or with respect to a beginning of a portion corresponding to a NN layer, to which portion the respective predetermined individually accessible portion belongs to. The pointer might be encoded/decoded into/from a header portion of the data stream. According to an embodiment, for each of the one or more predetermined individually accessible portions, the pointer is encoded/decoded into/from a header portion of the data stream, in case of the respective predetermined individually accessible portion representing a corresponding NN layer of the neural network or the pointer is encoded/decoded into/from a parameter set portion of a portion corresponding to a NN layer, in case of the respective predetermined individually accessible portion representing a NN portion of a NN layer of the NN. A NN portion of a NN layer of the NN might represent a baseline section of the respective NN layer or an advanced section of the respective layer. With the pointer it is possible to efficiently access the predetermined individually accessible portions of the data stream enabling, for example, to parallelize the layer processing or package the data stream into respective container formats. The pointer allows easier, faster and more adequate access to the predetermined individually accessible portions in order to facilitate applications that involve parallel or partial decoding and execution of NNs.

In accordance with a fifth aspect of the present application, the inventors of the present application realized that a transmission/updating of neural networks is rendered highly efficient, if a start code, a pointer and/or a data stream length parameter is encoded/decoded into/from an individually accessible sub-portion of a data stream having a representation of the NN encoded thereinto. The data stream is structured into one or more individually accessible portions, each individually accessible portion representing a corresponding NN layer of the neural network. Additionally, the data stream is, within one or more predetermined individually accessible portions, further structured into individually accessible sub-portions, each individually accessible sub-portion representing a corresponding NN portion of the respective NN layer of the neural network. An apparatus is configured to encode/decode into/from the data stream, for each of the one or more predetermined individually accessible sub-portions, a start code at which the respective predetermined individually accessible sub-portion begins, and/or a pointer pointing to a beginning of the respective predetermined individually accessible sub-portion, and/or a data stream length parameter indicating a data stream length of the respective predetermined individually accessible sub-portion for skipping the respective predetermined individually accessible sub-portion in parsing the DS. The start code, the pointer and/or the data stream length parameter enable an efficient access to the predetermined individually accessible sub-portions. This is especially beneficial for applications that may rely on grouping NN parameter within a NN layer in a specific configurable fashion as it can be beneficial to have the NN parameter decoded/processed/inferred partially or in parallel. Therefore, an individually accessible sub-portion wise access to an individually accessible portion can help to access desired data in parallel or leave out unnecessary data portions. It was found, that it is sufficient to indicate an individually accessible sub-portion using a start code. This is based on the finding, that an amount of data per NN layer, i.e. individually accessible portion, is usually less than in case NN layers are to be detected by start codes within the whole data stream. Nevertheless, it is also advantageous to use the pointer and/or the data stream length parameter to improve the access to an individually accessible sub-portion. According to an embodiment, the one or more individually accessible sub-portions within an individually accessible portion of the data stream are indicated by a pointer indicating a data stream position in bytes in a parameter set portion of the individually accessible portion. The data stream length parameter might indicate a run length of individually accessible sub-portions. The data stream length parameter might be encoded/decoded into/from a header portion of the data stream or into/from the parameter set portion of the individually accessible portion. The data stream length parameter might be used in order to facilitate cut out of the respective individually accessible sub-portion for the purpose of packaging the one or more individually accessible sub-portion in appropriate containers. According to an embodiment, an apparatus for decoding the data stream is configured to use, for one or more predetermined individually accessible sub-portions, the start code and/or the pointer and/or the data stream length parameter for accessing the data stream.

In accordance with a sixth aspect of the present application, the inventors of the present application realized that a usage of neural networks is rendered highly efficient, if a processing option parameter is encoded/decoded into/from a data stream having a representation of the NN encoded thereinto. The data stream is structured into individually accessible portions and for each of one or more predetermined individually accessible portions a processing option parameter indicates one or more processing options which have to be used or which may optionally be used when using the neural network for inference. The processing option parameter might indicate one processing option out of various processing options that also determine if and how a client would access the individually accessible portions (P) and/or the individually accessible sub-portions (SP), like, for each of P and/or SP, a parallel processing capability of the respective P or SP and/or a sample wise parallel processing capability of the respective P or SP and/or a channel wise parallel processing capability of the respective P or SP and/or a classification category wise parallel processing capability of the respective P or SP and/or other processing options. The processing option parameter allows a client appropriate decision making and thus a highly efficient usage of the NN.

In accordance with a seventh aspect of the present application, the inventors of the present application realized that a transmission/updating of neural networks is rendered highly efficient, if a reconstruction rule for dequantizing NN parameters depends on a NN portion the NN parameters belong to. The NN parameters, which NN parameters represent a neural network, are encoded into a data stream in a manner quantized onto quantization indices. An apparatus for decoding is configured to dequantize the quantization indices to reconstruct the NN parameters, e.g., using the reconstruction rule. The NN parameters are encoded into the data stream so that NN parameters in different NN portions of the NN are quantized differently, and the data stream indicates, for each of the NN portions, a reconstruction rule for dequantizing NN parameters relating to the respective NN portion. The apparatus for decoding is configured to use, for each of the NN portions, the reconstruction rule indicated by the data stream for the respective NN portion to dequantize the NN parameter in the respective NN portion. The NN portions, for example, comprise one or more NN layers of the NN and/or portions of an NN layer into which portions a predetermined NN layer of the NN is subdivided.

According to an embodiment, a first reconstruction rule for dequantizing NN parameters relating to a first NN portion are encoded into the data stream in a manner delta-coded relative to a second reconstruction rule for dequantizing NN parameters relating to a second NN portion. The first NN portion might comprise first NN layers and the second NN portion might comprise second layers, wherein the first NN layers differ from the second NN layers. Alternatively, the first NN portion might comprise first NN layers and the second NN portion might comprise portions of one of the first NN layers. In this alternative case, a reconstruction rule, e.g., the second reconstruction rule, related to NN parameters in a portion of a predetermined NN layer are delta-coded relative to a reconstruction rule, e.g., the first reconstruction rule, related to the predetermined NN layer. This special delta-coding of the reconstruction rules might allow to only use few bits for signalling the reconstruction rules and can result in an efficient transmission/updating of neural networks.

In accordance with an eighth aspect of the present application, the inventors of the present application realized that a transmission/updating of neural networks is rendered highly efficient, if a reconstruction rule for dequantizing NN parameters depends on a magnitude of quantization indices associated with the NN parameters. The NN parameters, which NN parameters represent a neural network, are encoded into a data stream in a manner quantized onto quantization indices. An apparatus for decoding is configured to dequantize the quantization indices to reconstruct the NN parameters, e.g., using the reconstruction rule. The data stream comprises, for indicating the reconstruction rule for dequantizing the NN parameters, a quantization step size parameter indicating a quantization step size, and a parameter set defining a quantization-index-to-reconstruction-level mapping. The reconstruction rule for NN parameters in a predetermined NN portion is defined by the quantization step size for quantization indices within a predetermined index interval, and the quantization-index-to-reconstruction-level mapping for quantization indices outside the predetermined index interval. For each NN parameter, a respective NN parameter associated with a quantization index within the predetermined index interval, for example, is reconstructed by multiplying the respective quantization index with the quantization step size and a respective NN parameter corresponding to a quantization index outside the predetermined index interval, for example, is reconstructed by mapping the respective quantization index onto a reconstruction level using the quantization-index-to-reconstruction-level mapping. The decoder might be configured to determine the quantization-index-to-reconstruction-level mapping based on the parameter set in the data stream. According to an embodiment, the parameter set defines the quantization-index-to-reconstruction-level mapping by pointing to a quantization-index-to-reconstruction-level mapping out of a set of quantization-index-to-reconstruction-level mappings, wherein the set of quantization-index-to-reconstruction-level mappings might not be part of the data stream, e.g., it might be saved at encoder side and decoder side. Defining the reconstruction rule based on a magnitude of quantization indices can result in a signalling of the reconstruction rule with few bits.

In accordance with a ninth aspect of the present application, the inventors of the present application realized that a transmission/updating of neural networks is rendered highly efficient, if an identification parameter is encoded/decoded into/from individually accessible portions of a data stream having a representation of the NN encoded thereinto. The data stream is structured into individually accessible portions and, for each of one or more predetermined individually accessible portions, an identification parameter for identifying the respective predetermined individually accessible portion is encoded/decoded into/from the data stream. The identification parameter might indicate a version of the predetermined individually accessible portion. This is especially advantageous in scenarios such as distributed learning, where many clients individually further train a NN and send relative NN updates back to a central entity. The identification parameter can be used to identify the NN of individual clients through a versioning scheme. Thereby, the central entity can identify the NN that an NN update is built upon. Additionally, or alternatively, the identification parameter might indicate whether the predetermined individually accessible portion is associated with a baseline part of the NN or with an advanced/enhanced/complete part of the NN. This is, for example, advantageous in use cases, such as scalable NNs, where a baseline part of an NN can be executed, for instance, in order to generate preliminary results, before the complete or enhanced NN is carried out to receive full results. Further, transmission errors or involuntary changes of a parameter tensor reconstructable based on NN parameters representing the NN are easily recognizable using the identification parameter. The identification parameter allows for each predetermined individually accessible portions to check integrity and make operations more error robust when it could be verified based on the NN characteristics.

In accordance with a tenth aspect of the present application, the inventors of the present application realized that a transmission/updating of neural networks is rendered highly efficient, if different versions of the NN are encoded/decoded into/from a data stream using delta-coding or using a compensation scheme. The data stream has a representation of an NN encoded thereinto in a layered manner so that different versions of the NN are encoded into the data stream. The data stream is structured into one or more individually accessible portions, each individually accessible portion relating to a corresponding version of the NN. The data stream has, for example, a first version of the NN encoded into a first portion delta-coded relative to a second version of the NN encoded into a second portion. Additionally, or alternatively, the data stream has, for example, a first version of the NN encoded into a first portion in form of one or more compensating NN portions each of which is to be, for performing an inference based on the first version of the NN, executed in addition to an execution of a corresponding NN portion of a second version of the NN encoded into a second portion, and wherein outputs of the respective compensating NN portion and corresponding NN portion are to be summed up. With these encoded versions of the NN in the data stream, a client, e.g., a decoder, can match its processing capabilities or may be able to do inference on the first version, e.g., a baseline, first before processing the second version, e.g., a more complex advanced NN. Furthermore, by applying/using the delta-coding and/or the compensation scheme, the different versions of the NN can be encoded into the DS with few bits.

In accordance with an eleventh aspect of the present application, the inventors of the present application realized that a usage of neural networks is rendered highly efficient, if supplemental data is encoded/decoded into/from individually accessible portions of a data stream having a representation of the NN encoded thereinto. The data stream is structured into individually accessible portions and the data stream comprises for each of one or more predetermined individually accessible portions a supplemental data for supplementing the representation of the NN. This supplemental data is usually not necessary for decoding/reconstruction/inference of the NN, however, it can be essential from an application point of view. Therefore, it is advantageous to mark this supplemental data as irrelevant for the decoding of the NN for the purpose of sole inference so that clients, e.g. decoders, which do not require the supplemental data, are able to skip this part of the data.

In accordance with a twelfth aspect of the present application, the inventors of the present application realized that a usage of neural networks is rendered highly efficient, if hierarchical control data is encoded/decoded into/from a data stream having a representation of the NN encoded thereinto. The data stream comprises hierarchical control data structured into a sequence of control data portions, wherein the control data portions provide information on the NN at increasing details along the sequence of control data portions. It is advantageous to structure the control data hierarchically, since a decoder might only need the control data until a certain level of detail and can thus skip the control data providing more details. Thus, depending on the use case and its knowledge of environment, different levels of control data may be useful and with the aforementioned scheme of presenting such control data enables an efficient access to the needed control data for different use cases.

Although some aspects have been described in the context of an apparatus, it is clear that these aspects also represent a description of the corresponding method, where a block or device corresponds to a method step or a feature of a method step. An embodiment is related to a computer program having a program code for performing, when running on a computer, such a method.

### BRIEF DESCRIPTION OF THE DRAWINGS

Embodiments of the present invention will be detailed subsequently referring to the appended drawings, which are not necessarily to scale—emphasis instead generally being placed upon illustrating the principles of the invention—and in which:

FIG. 1 shows an example of an encoding/decoding pipeline for encoding/decoding a neural network;

FIG. 2 shows a neural network which might be encoded/decoded according to one of the embodiments;

FIG. 3 shows a serialization of parameter tensors of layers of a neural network, according to an embodiment;

FIG. 4 shows the usage of a serialization parameter for indicating how neural network parameters are serialized, according to an embodiment;

FIG. 5 shows an example for a single-output-channel convolutional layer;

FIG. 6 shows an example for a fully-connected layer;

FIG. 7 shows a set of n coding orders at which neural network parameters might be encoded, according to an embodiment;

FIG. 8 shows context-adaptive arithmetic coding of individually accessible portions or sub-portions, according to an embodiment;

FIG. 9 shows the usage of a numerical computation representation parameter, according to an embodiment;

FIG. 10 shows the usage of a neural network layer type parameter indicating a neural network layer type of a neural network layer of the neural network, according to an embodiment;

FIG. 11 shows a general embodiment of a data stream with pointer pointing to beginnings of individually accessible portions, according to an embodiment;

FIG. 12 shows a detailed embodiment of a data stream with pointer pointing to beginnings of individually accessible portions, according to an embodiment;

FIG. 13 shows the usage of start codes and/or pointer and/or data stream length parameter to enable an access to individually accessible sub-portions, according to an embodiment;

FIG. 14a shows a sub-layer access using pointer, according to an embodiment;

FIG. 14b shows a sub-layer access using start codes, according to an embodiment;

FIG. 15 shows exemplary types of random access as possible processing options for individually accessible portions, according to an embodiment;

FIG. 16 shows the usage of a processing option parameter, according to an embodiment;

FIG. 17 shows the usage of a neural network portion dependent reconstruction rule, according to an embodiment;

FIG. 18 shows a determination of a reconstruction rule based on quantization indices representing quantized neural network parameter, according to an embodiment;

FIG. 19 shows the usage of an identification parameter, according to an embodiment;

FIG. 20 shows an encoding/decoding of different versions of a neural network, according to an embodiment;

FIG. 21 shows a delta-coding of two versions of a neural network, wherein the two versions differ in their weights and/or biases, according to an embodiment;

FIG. 22 shows an alternative delta-coding of two versions of a neural network, wherein the two versions differ in their number of neurons or neuron interconnections, according to an embodiment;

FIG. 23 shows an encoding of different versions of a neural network using compensating neural network portions, according to an embodiment;

FIG. 24a shows an embodiment of a data stream with supplemental data, according to an embodiment;

FIG. 24b shows an alternative embodiment of a data stream with supplemental data, according to an embodiment; and

FIG. 25 shows an embodiment of a data stream with a sequence of control data portions.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

The following description of embodiments of the present application starts with a brief introduction and outline of embodiments of the present application in order to explain their advantages and how same achieve these advantages.

It was found, that in the current activities of coded representations of NN such as developed in the ongoing MPEG activity on NN compression, it can be beneficial to separate a model bitstream representing parameter tensors of multiple layers into smaller sub-bitstreams that contain the coded representation of the parameter tensors of individual layers, i.e. layer bitstreams. This can help in general when such model bitstreams need to be stored/loaded in context of a container format or in application scenarios that feature parallel decoding/execution of layers of the NN.

In the following, various examples are described which may assist in achieving an effective compression of a neural network, NN, and/or in improving an access to data representing the NN and thus resulting in an effective transmission/updating of the NN.

In order to ease the understanding of the following examples of the present application, the description starts with a presentation of possible encoders and decoders fitting thereto into which the subsequently outlined examples of the present application could be built.

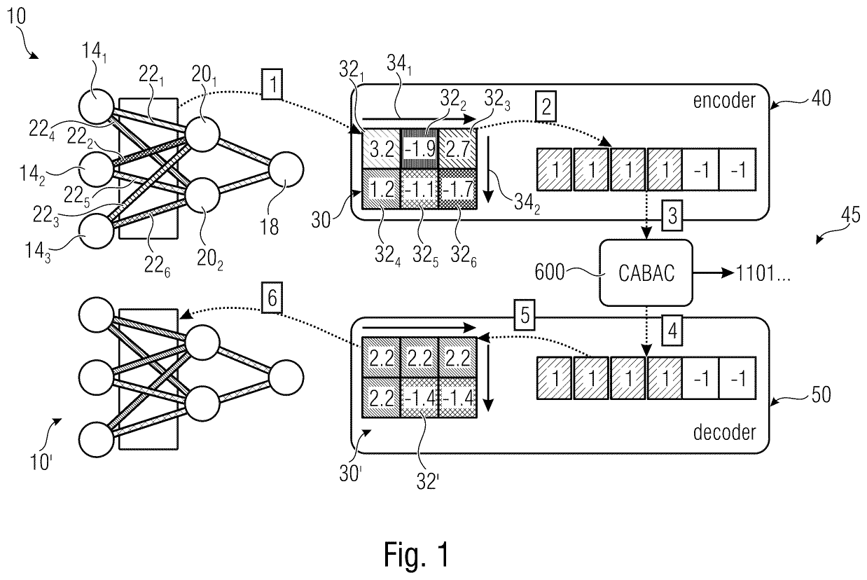

FIG. 1 shows a simple sketch example of an encoding/decoding pipeline according to DeepCABAC and illustrates the inner operations of such a compression scheme. First, the weights 32, e.g., the weights 32₁ to 326, of the connections 22, e.g., the connections 221 to 226, between neurons 14, 20 and/or 18, e.g., between predecessor neurons 141 to 143 and intermediate neurons 201 and 202, are formed into tensors, which are shown as matrices 30 in the example (step 1 in FIG. 1). In step 1 of FIG. 1, for example, the weights 32 associated with a first layer of a neural Network 10, NN, are formed into the matrix 30. According to the embodiment shown in FIG. 1, the columns of the matrix 30 are associated with the predecessor neurons 141 to 143 and the rows of the matrix 30 are associated with the intermediate neurons 201 and 202, but it is clear that the formed matrix can alternatively represent an inversion of the illustrated matrix 30.

Then, each NN parameter, e.g., the weights 32, is encoded, e.g., quantized and entropy coded, e.g. using context-adaptive arithmetic coding 600, as shown in steps 2 and 3, following a particular scanning order, e.g., row-major order (left to right, top to bottom). As will be outlined in more detail below, it is also possible to use a different scanning order, i.e. coding order. The steps 2 and 3 are performed by an encoder 40, i.e. an apparatus for encoding. The decoder 50, i.e. an apparatus for decoding, follows the same process in reverse processing order steps. That is, firstly it decodes the list of integer representation of the encoded values, as shown in step 4, and then reshapes the list into its tensor representation 30′, as shown in step 5. Finally, the tensor 30′ is loaded into the network architecture 10′, i.e. a reconstructed NN, as shown in step 6. The reconstructed tensor 30′ comprises reconstructed NN parameter, i.e. decoded NN parameter 32′.

The NN 10 shown in FIG. 1 is only a simple NN with few neurons 14, 20 and 18. A neuron might, in the following also be understood as node, element, model element or dimension. Furthermore, the reference sign 10 might indicate a machine learning (ML) predictor or, in other words, a machine learning model such as a neural network.

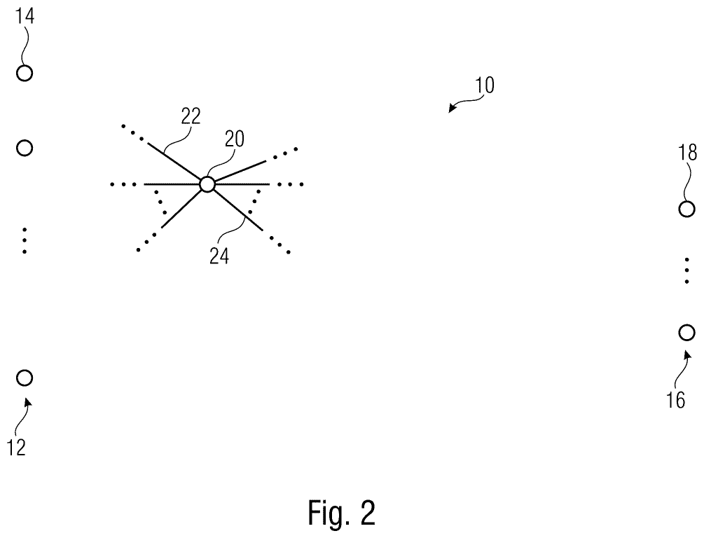

With reference to FIG. 2 a neural network is described in more detail. In particular, FIG. 2 shows an ML predictor 10 comprising an input interface 12 with input nodes or elements 14 and an output interface 16 with output nodes or elements 18. The input nodes/elements 14 receive the input data. In other words, the input data is applied thereonto. For instance, they may receive a picture with, for instance, each element 14 being associated with a pixel of the picture. Alternatively, the input data applied onto elements 14 may be a signal such as a one dimensional signal such as an audio signal, a sensor signal or the like. Even alternatively, the input data may represent a certain data set such as medical file data or the like. The number of input elements 14 may be any number and depends on the type of input data, for instance. The number of output nodes 18 may be one, as shown in FIG. 1, or larger than one, as shown in FIG. 2. Each output node or element 18 may be associated with a certain inference or prediction task. In particular, upon the ML predictor 10 being applied onto a certain input applied onto the ML predictor's 10 input interface 12, the ML predictor 10 outputs at the output interface 16 the inference or prediction result wherein the activation, i.e. an activation value, resulting at each output node 18 may be indicative, for instance, of an answer to a certain question on the input data such as whether or not, or how likely, the input data has a certain characteristic such as whether a picture having been input contains a certain object such as a car, a person, a phase or the like.

Insofar, the input applied onto the input interface may also be interpreted as an activation, namely an activation applied onto each input node or element 14.

Between the input nodes 14 and output node(s) 18, the ML predictor 10 comprises further elements or nodes 20 which are, via connections 22 connected to predecessor nodes so as to receive activations from these predecessor nodes, and via one or more further connections 24 to successor nodes in order to forward to the successor nodes the activation, i.e. an activation value, of node 20.

Predecessor nodes may be other internal nodes 20 of the ML predictor 10, via which intermediate node 20 exemplarily depicted in FIG. 2 is indirectly connected to input nodes 14, or may be an input node 14 directly, as shown in FIG. 1, and the successor nodes may be other intermediate nodes of the ML predictor 10, via which the exemplarily shown intermediate node 20 is connected to the output interface or output node, or may be an output node 28 directly, as shown in FIG. 1.

The input nodes 14, output nodes 18 and internal nodes 20 of ML predictor 10 may be associated or attributed to certain layers of the ML predictor 10, but a layered structuring of the ML predictor 10 is optional and ML predictors onto which embodiments of the present application apply are not restricted to such layered networks. As far as the exemplary shown intermediate node 20 of ML predictor 10 is concerned, same contributes to the inference or prediction task of ML predictor 10 by forwarding activations, i.e. activation values, from the predecessor nodes received via connections 22 from input interface 12 via connections 24 to successor nodes towards output interface 16. In doing so, node or element 20 computes its activation, i.e. activation value, forwarded via connections 24 towards the successor nodes based on the activations, i.e. activation values, at the input nodes 22 and the computation involves the computation of a weighted sum namely a sum having an addend for each connection 22 which, in turn, is a product between the input received from a respective predecessor node, namely its activation, and a weight associated with the connection 22 connecting the respective predecessor node and intermediate node 20. Note that alternatively or more generally, the activation x forwarded via connections 24 from a node or element i, 20, towards the successor nodes j by way of a mapping function mᵢⱼ(x). Thus, each connection 22 as well as 24 may have a certain weight associated therewith, or alternatively, the result of mapping function mᵢⱼ. Further parameters may be involved in the computation in the activation output by node 20 towards a certain successor node, optionally. In order to determine relevance scores for portions of the ML predictor 10, activations resulting at an output node 18 upon having finished a certain prediction or inference task on a certain input at the input interface 12 may be used, or a predefined or interesting output activation of interest. This activation at each output node 18 is used as starting point for the relevance score determination, and the relevance is back propagated towards the input interface 12. In particular, at each node of ML predictor 10, such as node 20, the relevance score is distributed towards the predecessor nodes such as via connections 22 in case of node 20, distributed in a manner proportional to the aforementioned products associated with each predecessor node and contributing, via the weighted summation, to the activation of the current node the activation of which is to be backward propagated such as node 20. That is, the relevance fraction back propagated from a certain node such as node 20 to a certain predecessor node thereof may be computed by multiplying the relevance of that node with a factor depending on a ratio between the activation received from that predecessor node times the weight using which the activation has contributed to the aforementioned sum of the respective node, divided by a value depending on a sum of all products between the activations of the predecessor nodes and the weights at which these activations have contributed to the weighted sum of the current node the relevance of which is to be back propagated.

In the manner described above, relevance scores for portions of the ML predictor 10, for example, are determined on the basis of an activation of these portions as manifesting itself in one or more inferences performed by the ML predictor. The “portions” for which such a relevance score is determined may, as discussed above, be nodes or elements of the predictor 10 wherein, again it should be noted that the ML predictor 10 is not restricted to any layered ML network so that, for instance, the element 20, for instance, may be any computation of an intermediate value as computed during the inference or prediction performed by predictor 10. For instance, in the manner discussed above, the relevance score for element or node 20 is computed by aggregating or summing up the inbound relevance messages this node or element 20 receives from its successor nodes/elements which, in turn, distribute their relevance scores in the manner outlined above representatively with respect to node 20.

The ML predictor 10, i.e. a NN, as described with regard to FIG. 2 might be encoded into a data stream 45 using an encoder 40 described with regard to FIG. 1 and might be reconstructed/decoded from the data stream 45 using a decoder 50 described with regard to FIG. 1.

The features and/or functionalities described in the following, can be implemented in the compression scheme described with regard to FIG. 1 and might relate to NNs as described with regard to FIG. 1 and FIG. 2.

### 1 PARAMETER TENSOR SERIALIZATION

There exist applications that can benefit from sub-layer wise processing of the bitstream. For instance, there exist NNs which are adaptive to the available client computing power in a way that layers are structured into independent subsets, e.g. separately trained baseline and advanced portion, and that a client can decide to execute only the baseline layer subset or the advanced layer subset in addition (Tao, 2018). Another example are NNs that feature data-channel specific operations, e.g. a layer of an image-processing NN whose operations can be executed separately per, e.g., colour-channel in a parallel fashion (Chollet, 2016).

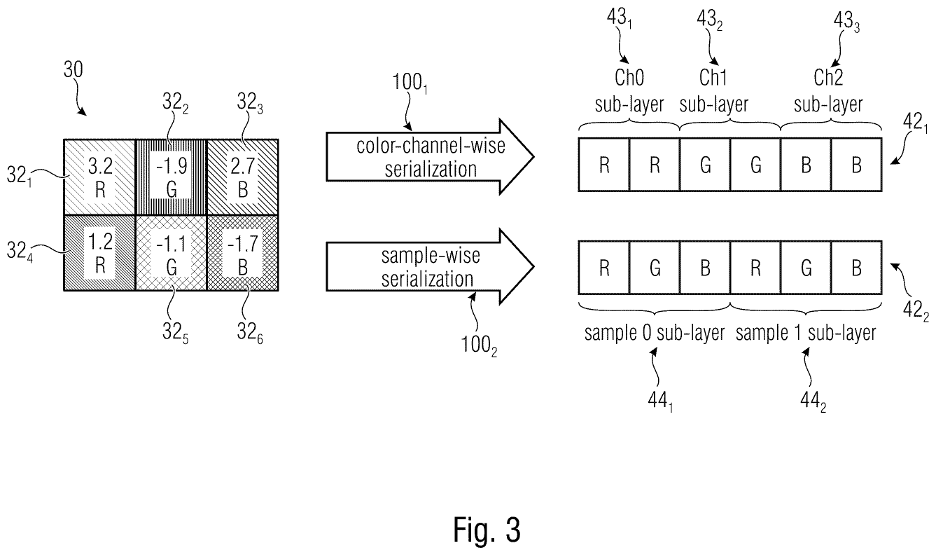

For the above purpose, with reference to FIG. 3, the serialization 100₁ or 100₂ of the parameter tensors 30 of layers involves a bitstring 421 or 422, e.g., before entropy coding, that can be easily divided into meaningful consecutive subsets 431 to 433 or 441 and 442 from the point of view of the application. This can include grouping of all NN parameters, e.g., the weights 32, per channel 100₁ or per sample 100₂ or grouping of neurons of the baseline vs. advanced portion. Such bitstrings can subsequently be entropy coded to form sub-layer bitstream with a functional relationship.

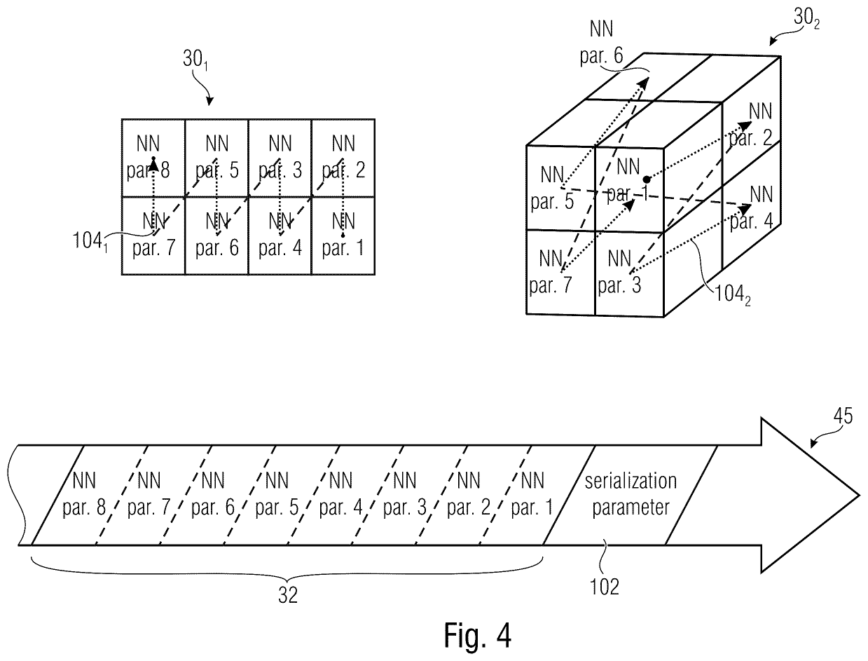

As shown in FIG. 4, a serialization parameter 102 can be encoded/decoded into/from a data stream 45. The serialization parameter might indicate, how the NN parameters 32 are grouped before or at an encoding of the NN parameters 32. The serialization parameter 102 might indicate how NN parameters 32 of a parameter tensor 30 are serialized into a bitstream, to enable an encoding of the NN parameters into the data stream 45.

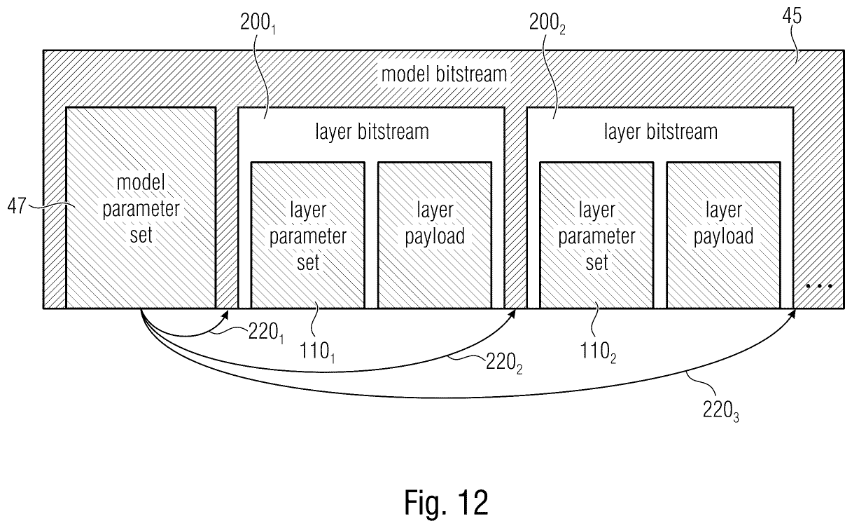

In one embodiment, the serialization information, i.e. a serialization parameter 102, is indicated in a parameter set portion 110 of the bitstream, i.e., the data stream 45, with the scope of a layer, see e.g. FIG. 12, 14a, 14b or 24b.

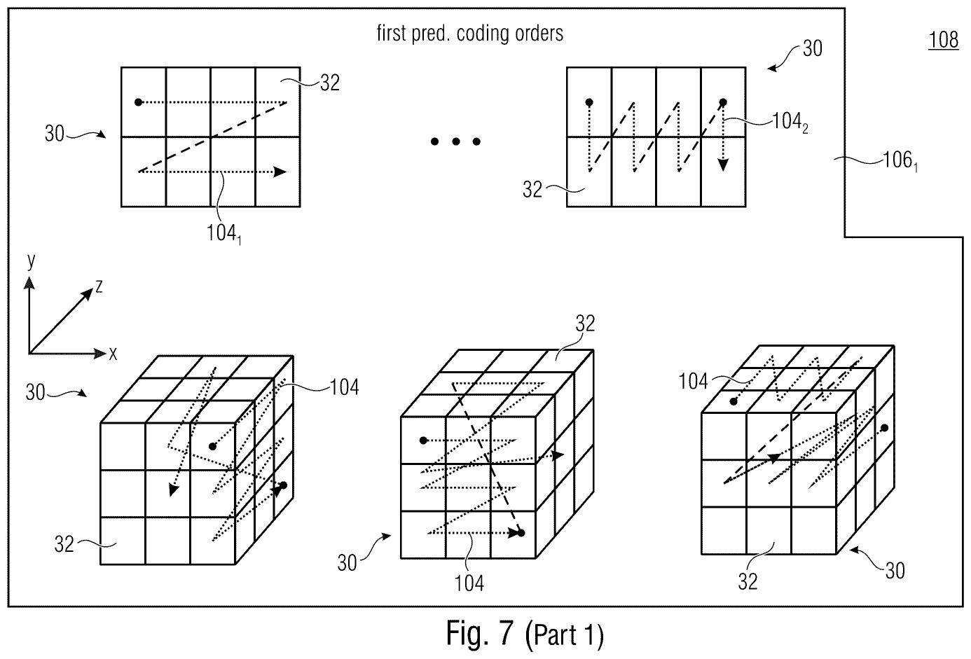

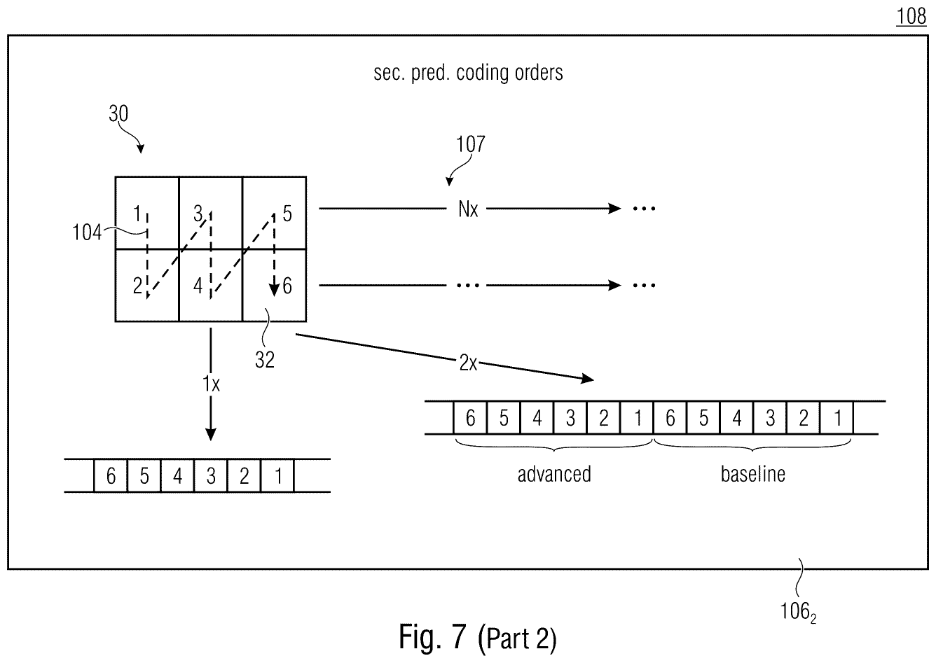

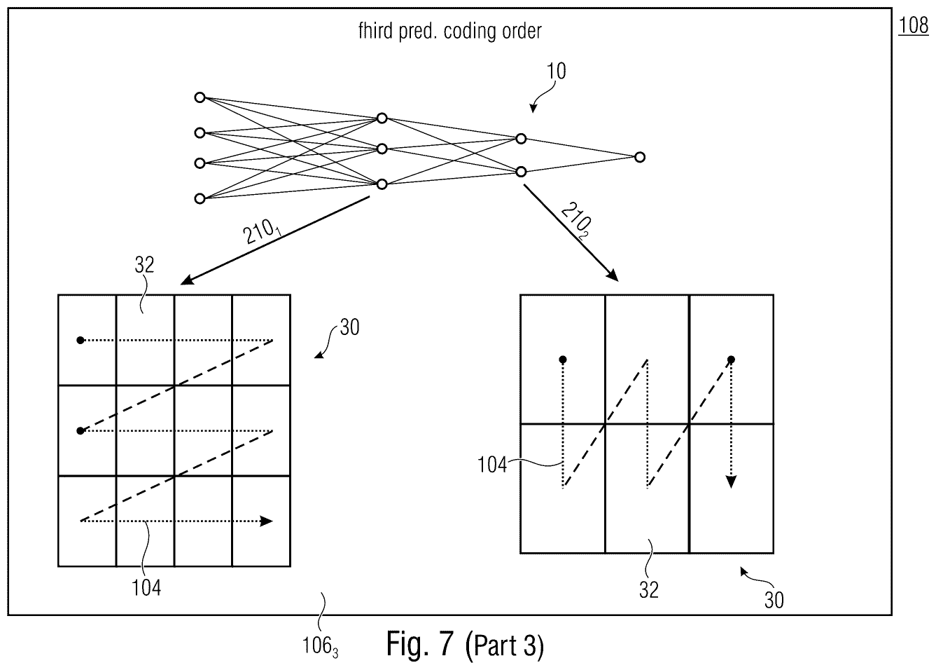

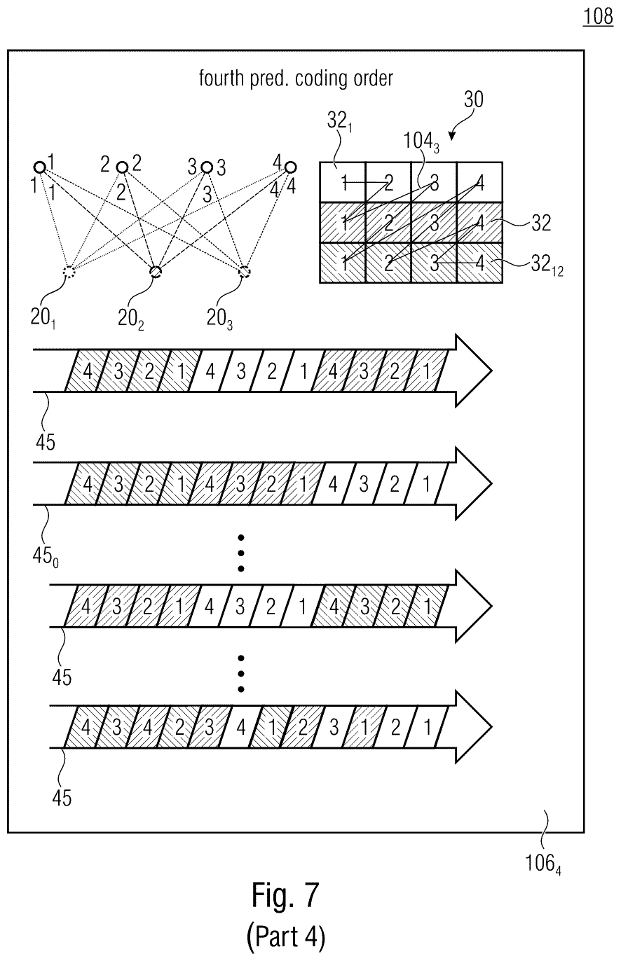

Another embodiment signals the dimensions 341 and 342 of the parameter tensor 30 (see FIG. 1 and the coding orders 106₁ in FIG. 7) as the serialization parameter 102. This information can be useful in cases where the decoded list of parameters ought to be grouped/organized in the respective manner, for instance in memory, in order to allow for efficient execution, e.g. as illustrated in FIG. 3 for an exemplary image-processing NN with a clear association between entries, i.e. the weights 32, of the parameter matrices, i.e. the parameter tensor 30, and samples 100₂ and color channels 100₁. FIG. 3 shows an exemplary illustration of two different serialization modes 100₁ and 100₂ and the resulting sub-layers 43 and 44.

In a further embodiment, as shown in FIG. 4, the bitstream, i.e. the data stream 45, specifies the order 104 in which the encoder 40 traversed the NN parameters 32, e.g., layers, neurons, tensors, while encoding so that the decoder 50 can reconstruct the NN parameters 32 accordingly while decoding, see FIG. 1 for a description of the encoder 40 and decoder 50. That is, different scanning orders 301, 302 of the NN parameters 32 may be applied in different application scenarios.

For instance, encoding parameters along different dimensions may benefit the resulting compression performance since the entropy coder may be able to better capture dependencies among them. In another example, it may be desirable to group parameters according to certain application specific criteria, i.e. what part of the input data they relate to or whether they can be jointly executed, so that they can be decoded/inferred in parallel. A further example is to encode the parameters following the General Matrix Matrix (GEMM) product scan order that support efficient memory allocation of the decoded parameters when performing the dot product operation (Andrew Kerr, 2017).

A further example is related to encoder-side chosen permutations of the data, e.g., illustrated by the coding orders 106₄ in FIG. 7, e.g. in order to achieve, for instance, energy compaction of the NN parameter 32 to be coded and subsequently process/serialize/code the resulting permutated data according to the resulting order 104. The permutation may, thus, sort the NN parameters 32 so that same increase or so that same decrease steadily along the coding order 104.

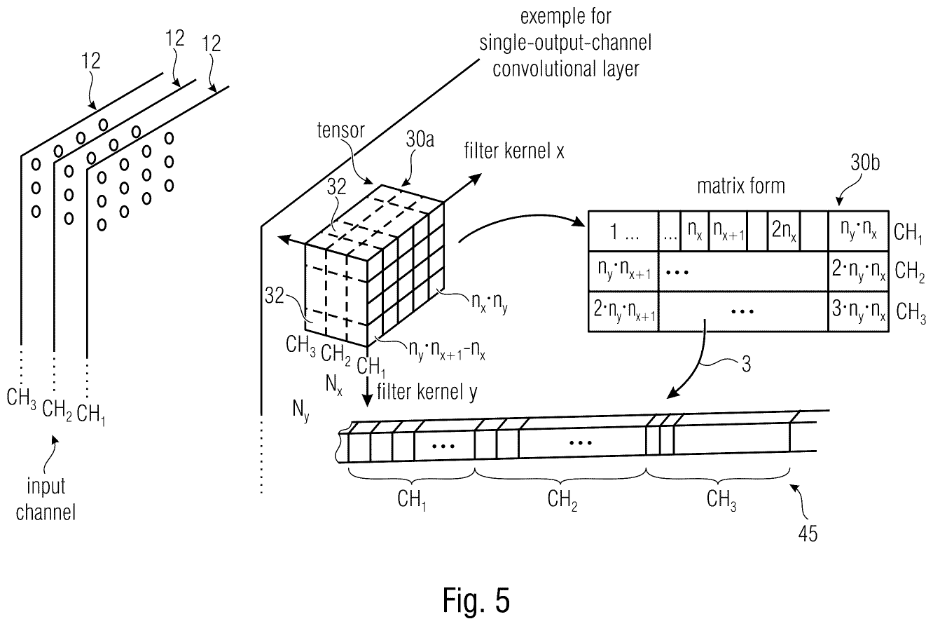

FIG. 5 shows an example for a single-output-channel convolutional layer, e.g., for a picture and/or video analysing application. Color images have multiple channels, typically one for each color channel, such as red, green, and blue. From a data perspective, that means that a single image provided as input to the model is, in fact, three images.

A tensor 30a might be applied to the input data 12 and scans over the input like a window with a constant step size. The tensor 30a might be understood as a filter. The tensor 30a might move from left to right across the input data 12 and jump to the next lower row after each pass. An optional so-called padding determines how the tensor 30a should behave when it hits the edge of the input matrices. The tensor 30a has NN parameter 32, e.g., fixed weights, for each point in its field of view, and it calculates, for example, a result matrix from pixel values in the current field of view and these weights. The size of this result matrix depends on the size (kernel size) of the tensor 30a, the padding and especially on the step size. The input image has 3 channels (e.g. a depth of 3), then a tensor 30a applied to that image has, for example, also 3 channels (e.g. a depth of 3). Regardless of the depth of the input 12 and depth of the tensor 30a, the tensor 30a is applied to the input 12 using a dot product operation which results in a single value.

By default, DeepCABAC converts any given tensor 30a into its respective matrix 30b form and encodes 3 the NN parameters 32 in row-major order 104₁, that is, from left to right and top to bottom into a data stream 45, as shown in FIG. 5. But as will be described with respect to FIG. 7, other coding orders 104/106 might be advantageous to achieve a high compression.

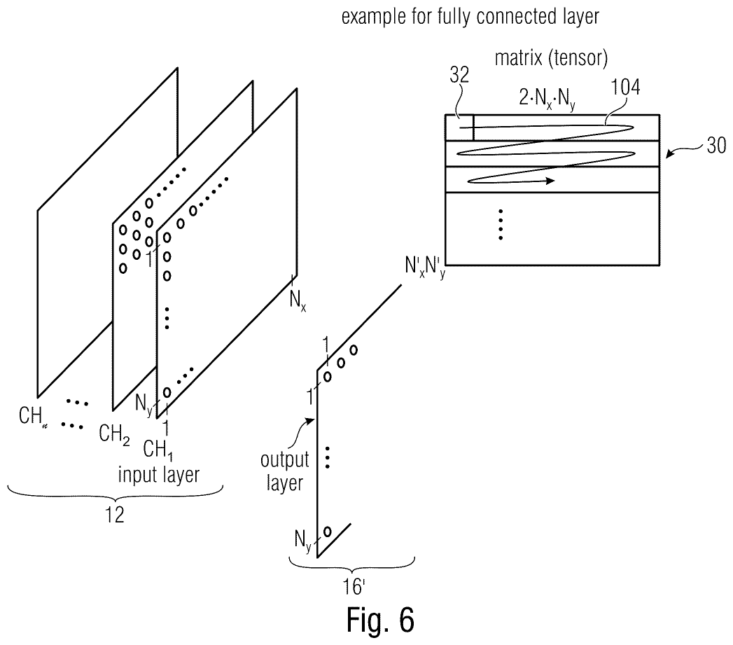

FIG. 6 shows an example for a fully-connected layer. The Fully Connected Layer or Dense Layer is a normal neural network structure, where all neurons are connected to all inputs 12, i.e. predecessor nodes, and all outputs 16′, i.e. successor nodes. The tensor 30 represents a corresponding NN layer and the tensor 30 comprises NN parameter 32. The NN parameters 32 are encoded into a data stream according to a coding order 104. As will be described with respect to FIG. 7, certain coding orders 104/106 might be advantageous to achieve a high compression.

Now the description returns to FIG. 4, to enable a general description of a serialization of the NN parameters 32. The concept described with regard to FIG. 4 might be applicable for both single-output-channel convolutional layer, see FIG. 5, and fully-connected layer, see FIG. 6.

As shown in FIG. 4, an embodiment A1 of the present application is related to a data stream 45 (DS) having a representation of a neural network (NN) encoded thereinto. The data stream comprises serialization parameter 102 indicating a coding order 104 at which NN parameters 32, which define neuron interconnections of the neural network, are encoded into the data stream 45.

According to an embodiment ZA1, an apparatus for encoding a representation of a neural network into the DS 45 is configured to provide the data stream 45 with the serialization parameter 102 indicating the coding order 104 at which the NN parameters 32, which define neuron interconnections of the neural network, are encoded into the data stream 45.

According to an embodiment XA1, an apparatus for decoding a representation of a neural network from the DS 45 is configured to decode from the data stream 45 the serialization parameter 102 indicating the coding order 104 at which the NN parameters 32, which define neuron interconnections of the neural network, are encoded into the data stream 45, e.g., and use the coding order 104 to assign the NN parameters 32 serially decoded from the DS 45 to the neuron interconnections.

FIG. 4 shows different representations of a NN layer with NN parameter 32 associated with the NN layer. According to an embodiment, a two-dimensional tensor 301, i.e. a matrix, or a three-dimensional tensor 302 can represent a corresponding NN layer.

In the following, different features and/or functionalities are described in the context of the data stream 45, but the features and/or functionalities can also, in the same way or in a similarly way, be features and/or functionalities of the apparatus, according to the embodiment ZA1, or of the apparatus, according to the embodiment XA1.

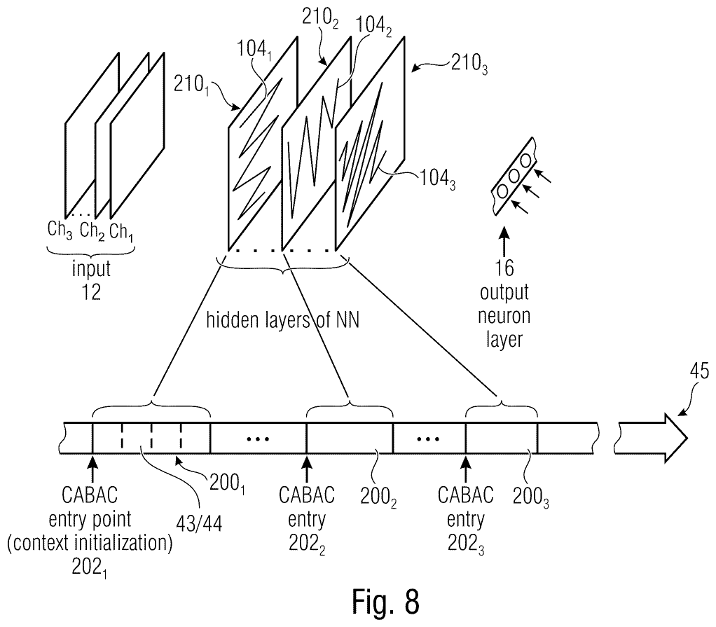

According to an embodiment A2, of the DS 45 of the previous embodiment A1, the NN parameters 32 are coded into the DS 45 using context-adaptive arithmetic coding 600, see, for example, FIG. 1 and FIG. 8. Thus, the apparatus, according to embodiment ZA1, can be configured to encode the NN parameters 32 using context-adaptive arithmetic coding 600 and the apparatus, according to embodiment XA1 can be configured to decode the NN parameters 32 using context-adaptive arithmetic decoding.

According to an embodiment A3, of the DS 45 of embodiment A1 or A2, the data stream 45 is structured into one or more individually accessible portions 200, as shown in FIG. 8 or one of the following Figures, each individually accessible portion 200 representing a corresponding NN layer 210 of the neural network, wherein the serialization parameter 102 indicates the coding order 104 at which NN parameters 32, which define neuron interconnections of the neural network within a predetermined NN layer 210, are encoded into the data stream 45.

According to an embodiment A4, of the DS 45 of any previous embodiments A1 to A3, the serialization parameter 102 is an n-ary parameter which indicates the coding order 104 out of a set 108 of n coding orders, as, for example, shown in FIG. 7.

According to an embodiment A4a, of the DS 45 of embodiment A4, the set 108 of n coding orders comprises
first 106₁ predetermined coding orders which differ in an order at which the predetermined coding orders 104 traverse dimensions, e.g., the x-dimension, the y-dimension and/or the z-dimension, of a tensor 30 describing a predetermined NN layer of the NN; and/or
second 106₂ predetermined coding orders which differ in a number of times 107 at which the predetermined coding orders 104 traverse a predetermined NN layer of the NN for sake of scalable coding of the NN; and/or
third 106₃ predetermined coding orders which differ in an order at which the predetermined coding orders 104 traverse NN layers 210 of the NN; and/or and/or
fourth 106₄ predetermined coding orders which differ in an order at which neurons 20 of an NN layer of the NN are traversed.

The first 106₁ predetermined coding orders, for example, differ among each other in how the individual dimensions of a tensor 30 are traversed at an encoding of the NN parameters 32. The coding order 104₁, for example, differs from the coding order 104₂ in that, the predetermined coding order 104₁ traverses the tensor 30 in row-major order, that is, a row is traversed from left to right, row after row from top to bottom and the predetermined coding order 104₂ traverses the tensor 30 in column-major order, that is, a column is traversed from top to bottom, column after column from left to right. Similarly, the first 106₁ predetermined coding orders can differ in an order at which the predetermined coding orders 104 traverse dimensions of a three-dimensional tensor 30.

The second 106₂ predetermined coding orders differ in how often a NN layer, e.g. represented by the tensor/matrix 30 is traversed. A NN layer, for example, can be traversed two times of a predetermined coding order 104, whereby a baseline portion and an advanced portion of the NN layer can be encoded/decoded into/from the data stream 45. The number of times 107 the NN layer is to be traversed by the predetermined coding order defines the number of versions of the NN layer encoded into the data stream. Thus, in case of the serialization parameter 102 indicating a coding order traversing the NN layer at least twice, the decoder might be configured to decide based on its processing capabilities which version of the NN layer can be decoded and decode the NN parameters 32 corresponding to the chosen NN layer version.

The third 106₃ predetermined coding orders define whether NN parameters associated with different NN layers 210₁ and 210₂ of the NN 10 are encoded into the data stream 45 using a different predetermined coding order or the same coding order as one or more other NN layers 210 of the NN 10.

The fourth 106₄ predetermined coding orders might comprise a predetermined coding order 104₃ traversing a tensor/matrix 30 representing a corresponding NN layer from a top left NN parameter 32₁ to a bottom right NN parameter 32₁₂ in a diagonal staggered manner.

According to an embodiment A4a, of the DS 45 of any previous embodiments A1 to A4a, the serialization parameter 102 is indicative of a permutation using which the coding order 104 permutes neurons of a NN layer relative to a default order. In other words, the serialization parameter 102 is indicative of a permutation and at a usage of the permutation the coding order 104 permutes neurons of a NN layer relative to a default order. A shown in FIG. 7 for the fourth 106₄ predetermined coding orders, a row-major order, as illustrated for the data stream 45₀, might represent a default order. The other data streams 45 comprise NN parameters encoded thereinto using a permutation relative to the default order.

According to an embodiment A4b, of the DS 45 of embodiment A4a, the permutation orders the neurons of the NN layer 210 in a manner so that the NN parameters 32 monotonically increase along the coding order 104 or monotonically decrease along the coding order 104.

According to an embodiment A4c, of the DS 45 of embodiment A4a, the permutation orders the neurons of the NN layer 210 in a manner so that, among predetermined coding orders 104 signalable by the serialization parameter 102, a bitrate for coding the NN parameters 32 into the data stream 45 is lowest for the permutation indicated by the serialization parameter 102.

According to an embodiment A5, of the DS 45 of any previous embodiments A1 to A4c, the NN parameters 32 comprise weights and biases.

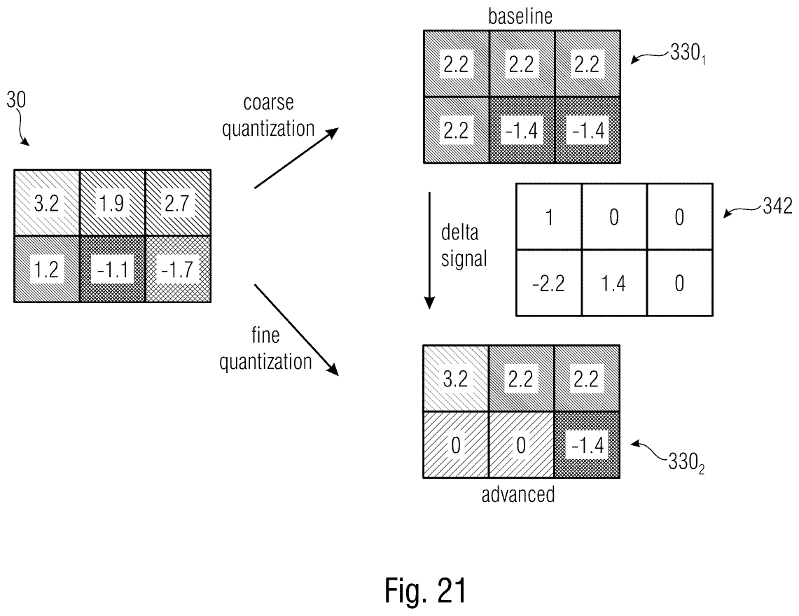

According to an embodiment A6, of the DS 45 of any previous embodiments A1 to A5, the data stream 45 is structured into individually accessible sub-portions 43/44, each sub-portion 43/44 representing a corresponding NN portion, e.g. a portion of a NN layer 210, of the neural network 10, so that each sub-portion 43/44 is completely traversed by the coding order 104 before a subsequent sub-portion 43/44 is traversed by the coding order 104. Rows, columns or channels of the tensor 30 representing the NN layer might be encoded into the individually accessible sub-portions 43/44. Different individually accessible sub-portions 43/44 associated with the same NN layer might comprise different neurons 14/18/20 or neuron interconnections 22/24 associated with the same NN layer. The individually accessible sub-portions 43/44 might represent rows, columns or channels of the tensor 30. Individually accessible sub-portions 43/44 are, for example, shown in FIG. 3. Alternatively, as shown in FIGS. 21 to 23, the individually accessible sub-portions 43/44 might represent different versions of a NN layer, like a baseline section of the NN layer and an advanced section of the NN layer.

According to an embodiment A7, of the DS 45 of any of embodiments A3 and A6, the NN parameters 32 are coded into the DS 45 using context-adaptive arithmetic coding 600 and using context initialization at a start 202 of any individually accessible portion 200 or sub-portion 43/44, see, for example, FIG. 8.

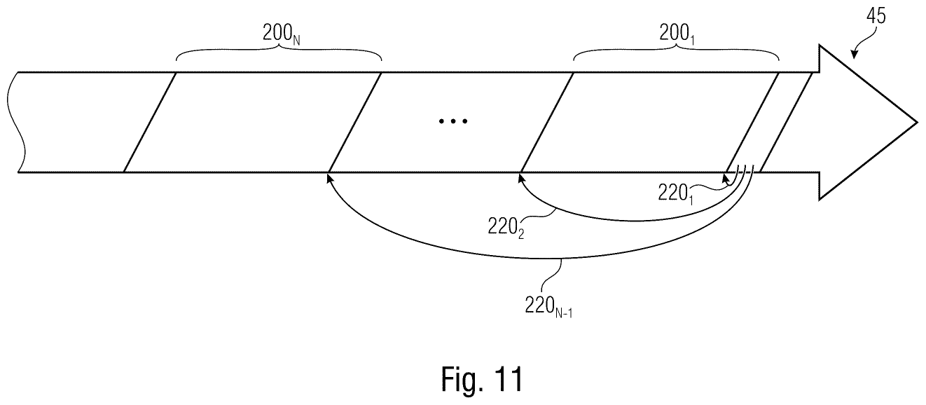

According to an embodiment A8, of the DS 45 of any of embodiments A3 and A6, the data stream 45 comprises start codes 242 at which each individually accessible portion 200 or sub-portion 240 begins, and/or pointers 220/244 pointing to beginnings of each individually accessible portion 200 or sub-portion 240, and/or pointers data stream lengths, i.e. a parameter indicating a data stream length 246 of each individually accessible portion 200 or sub-portion 240, of each individually accessible portion 200 or sub-portion 240 for skipping the respective individually accessible portion 200 or sub-portion 240 in parsing the DS 45, as shown in FIGS. 11 to 14.

Another embodiment identifies the bit-size and numerical representation of the decoded parameters 32′ in the bitstream, i.e. data stream 45. For instance, the embodiment may specify that the decoded parameters 32′ can be represented in an 8-bit signed fixed-point format. This specification can be very useful in applications where, for instance, it is possible to also represent the activation values in, e.g., 8-bit fixed-point representation, since then inference can be performed more efficiently due to fixed-point arithmetic.

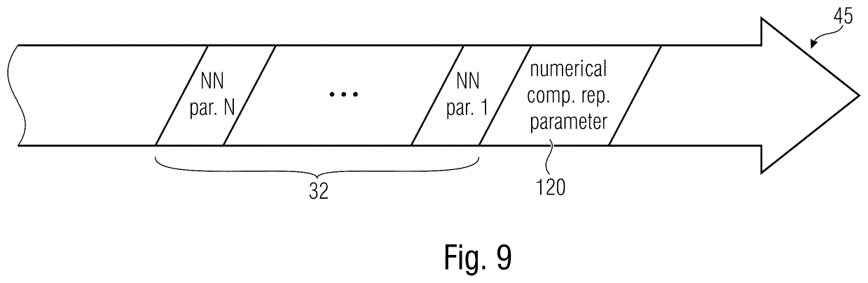

According to an embodiment A9, of the DS 45 of any of the previous embodiments A1 to A8, further comprising a numerical computation representation parameter 120 indicating a numerical representation and bit size at which the NN parameters 32 are to be represented when using the NN for inference, see, for example, FIG. 9.

FIG. 9 shows an embodiment B1, of a data stream 45 having a representation of a neural network encoded thereinto, the data stream 45 comprising a numerical computation representation parameter 120 indicating a numerical representation, e.g. among floating point, fixed point representation, and bit size at which NN parameters 32 of the NN, which are encoded into the DS 45, are to be represented when using the NN for inference.

A corresponding embodiment ZB1, is related to an apparatus for encoding a representation of a neural network into the DS 45, wherein the apparatus is configured to provide the data stream 45 with the numerical computation representation parameter 120 indicating a numerical representation, e.g. among floating point, fixed point representation, and bit size at which the NN parameters 32 of the NN, which are encoded into the DS 45, are to be represented when using the NN for inference.

A corresponding embodiment XB1, is related to an apparatus for decoding a representation of a neural network from the DS 45, wherein the apparatus is configured to decode from the data stream 45 the numerical computation representation parameter 120 indicating a numerical representation, e.g. among floating point, fixed point representation, and bit size at which NN parameters 32 of the NN, which are encoded into the DS 45, are to be represented when using the NN for inference, and to optionally use the numerical representation and bit size for representing the NN parameters 32 decoded from the DS 45.

In the following, different features and/or functionalities are described in the context of the data stream 45, but the features and/or functionalities can also, in the same way or in a similarly way, be features and/or functionalities of the apparatus, according to the embodiment ZB1, or of the apparatus, according to the embodiment XB1.

A further embodiment signals the parameter type within the layer. In most cases, a layer is comprised by two types of parameters 32, the weights and bias. The distinction between these two types of parameters may be beneficial prior to decoding when, for instance, different types of dependencies have been used for each while encoding, or if parallel decoding is wished, etc.

According to an embodiment A10, of the DS 45 of any of the previous embodiments A1 to B1, wherein the data stream 45 is structured into individually accessible sub-portions 43/44, each sub-portion 43/44 representing a corresponding NN portion, e.g. a portion of a NN layer, of the neural network, so that each sub-portion 43/44 is completely traversed by the coding order 104 before a subsequent sub-portion 43/44 is traversed by the coding order 104, wherein the data stream 45 comprises for a predetermined sub-portion a type parameter indicting a parameter type of the NN parameter 32 encoded into the predetermined sub-portion.

According to an embodiment A10a, of the DS of embodiment A10, wherein the type parameter discriminates, at least, between NN weights and NN biases.

Finally, a further embodiment signals the type of layer 210 in which the NN parameter 32 is contained, e.g., convolution or fully connected. This information may be useful in order to, for instance, understand the meaning of the dimensions of the parameter tensor 30. For instance, weight parameters of a 2d convolutional layer may be expressed as a 4d tensor 30, where the first dimension specifies the number of filters, the second the number of channels, and the rest the 2d spatial dimensions of the filter. Moreover, different layers 210 may be treated differently while encoding in order to better capture the dependencies in the data and lead to a higher coding efficiency (e.g. by using different sets or modes of context models), information that may be crucial for the decoder to know prior to decoding.

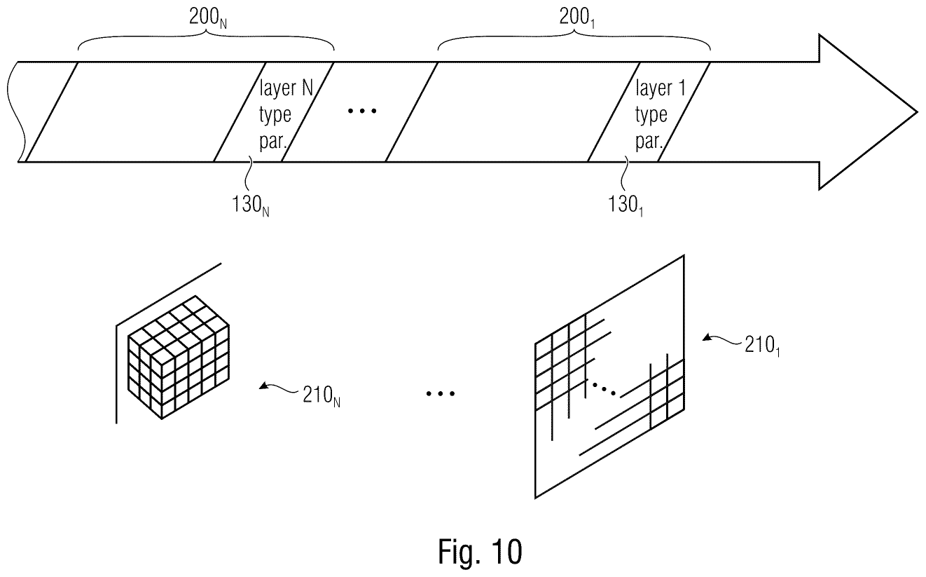

According to an embodiment A11, of the DS 45 of any of the previous embodiments A1 to A10a, wherein the data stream 45 is structured into one or more individually accessible portions 200, each portion 200 representing a corresponding NN layer 210 of the neural network 10, wherein the data stream 45 further comprises for a predetermined NN layer an NN layer type parameter 130 indicating a NN layer type of the predetermined NN layer of the NN, see, for example, FIG. 10.

FIG. 10 shows an embodiment C1, of a data stream 45 having a representation of a neural network encoded thereinto, wherein the data stream 45 is structured into one or more individually accessible portions 200, each portion representing a corresponding NN layer 210 of the neural network, wherein the data stream 45 further comprises, for a predetermined NN layer, a NN layer type parameter 130 indicating a NN layer type of the predetermined NN layer of the NN.

A corresponding embodiment ZC1, relates to an apparatus for encoding a representation of a neural network into the DS 45, so that the data stream 45 is structured into one or more individually accessible portions 200, each portion 200 representing a corresponding NN layer 210 of the neural network, wherein the apparatus is configured to provide the data stream 45 with, for a predetermined NN layer 210, a NN layer type parameter 130 indicating a NN layer type of the predetermined NN layer 210 of the NN.

A corresponding embodiment XC1, relates to an apparatus for decoding a representation of a neural network from a DS 45, wherein the data stream 45 is structured into one or more individually accessible portions 200, each portion 200 representing a corresponding NN layer 210 of the neural network, wherein the apparatus is configured to decode from the data stream 45, for a predetermined NN layer 210, a NN layer type parameter indicating a NN layer type of the predetermined NN layer 210 of the NN.

According to an embodiment A12, of the DS 45 of any of embodiments A11 and C1, wherein the NN layer type parameter 130 discriminates, at least, between a fully-connected, see NN layer 210₁, and a convolutional layer type, see NN layer 210_{N}. Thus, the apparatus, according to the embodiment ZC1, can encode the NN layer type parameter 130 to discriminate between the two layer types and the apparatus, according to the embodiment XB1, can decode the NN layer type parameter 130 to discriminate between the two layer types.

### 2 BITSTREAM RANDOM ACCESS

### 2.1 Layer Bitstream Random Access

Accessing subsets of bitstreams is vital in many applications, e.g. to parallelize the layer processing, or package the bitstream into respective container formats. One way in the state-of-the-art for allowing such access, for instance, is breaking coding dependencies after the parameter tensors 30 of each layer 210 and inserting start codes into the model bitstream, i.e. data stream 45, before each of the layer bitstreams, e.g. individually accessible portions 200. In particular, start codes in the model bitstream are not an adequate method to separate layer bitstreams as the detection of start codes involves parsing through the whole model bitstream from the beginning over a potentially very large number of start codes.

This aspect of the invention is concerned with further techniques for structuring the coded model bitstream of parameter tensors 30 in a better way than state-of-the-art and allow easier, faster and more adequate access to bitstream portions, e.g. layer bitstreams in order to facilitate applications that involve parallel or partial decoding and execution of NNs.

In one embodiment of the invention, the individual layer bitstreams, e.g., individually accessible portions 200, within the model bitstream, i.e. data stream 45, are indicated through bitstream position in bytes or offsets (e.g. byte offsets with respect to the beginning of a coding unit) in a parameter set/header portion 47 of the bitstream with the scope of the model. FIGS. 11 and 12 illustrate the embodiment. FIG. 12 shows a layer access from through bitstream positions or offsets indicated by a pointer 220. Additionally, each individually accessible portions 200 comprises optionally a layer parameter set 110, into which layer parameter set 110 one or more of the aforementioned parameters can be encoded and decoded.

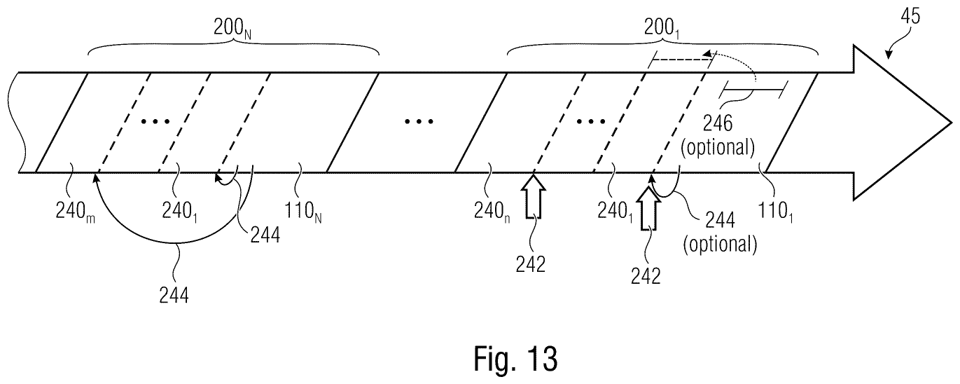

According to an embodiment A13, of the DS 45 of any of the previous embodiments A1 to A12, the data stream 45 is structured into individually accessible portions 200, each portion 200 representing a corresponding NN portion, e.g. one or more NN layer or portions of a NN layer, of the neural network, wherein the data stream 45 comprises for each of one or more predetermined individually accessible portions 200 a pointer 220 pointing to a beginning of each individually accessible portion 200, for example, see FIG. 11 or FIG. 12, in case of the individually accessible portions representing a corresponding NN layer and see FIGS. 13 to 15, in case of the individually accessible portions representing portions of a predetermined NN layer, e.g., individually accessible sub-portions 240. In the following the pointer 220 might also be denoted with the reference sign 244.

For each NN layer, the individually accessible portions 200 associated with the respective NN layer might represent corresponding NN portions of the respective NN layer. In this case, here and in the following description, such individually accessible portions 200 might also be understood as individually accessible sub-portions 240.

FIG. 11 shows a more general embodiment D1, of a data stream 45 having a representation of a neural network encoded thereinto, wherein the data stream 45 is structured into individually accessible portions 200, each individually accessible portion 200 representing a corresponding NN portion, e.g. one or more NN layer or portions of a NN layer, of the neural network, wherein the data stream 45 comprises for each of one or more predetermined individually accessible portions 200 a pointer 220 pointing to a beginning of the respective predetermined individually accessible portion 200.

According to an embodiment, the pointer 220 indicates an offset with respect to a beginning of a first individually accessible portion 200₁. A first pointer 2201 pointing to the first individually accessible portion 200₁ might indicate no offset. Thus it might be possible to omit the first pointer 2201. Alternatively, the pointer 220, for example, indicates an offset with respect to an end of a parameter set into which the pointer 220 is encoded.

A corresponding embodiment ZD1, is related to an apparatus for encoding a representation of a neural network into the DS 45, so that the data stream 45 is structured into the one or more individually accessible portions 200, each portion 200 representing a corresponding NN portion, e.g. one or more NN layer or portions of a NN layer, of the neural network, wherein the apparatus is configured to provide the data stream 45 with, for each of one or more predetermined individually accessible portions 200, a pointer 220 pointing to a beginning of the respective predetermined individually accessible portion 200.

A corresponding embodiment XD1, is related to an apparatus for decoding a representation of a neural network from the DS 45, wherein the data stream 45 is structured into the one or more individually accessible portions 200, each portion 200 representing a corresponding NN portion, e.g. one or more NN layer or portions of a NN layer, of the neural network, wherein the apparatus is configured to decode from the data stream 45, for each of one or more predetermined individually accessible portions 200, a pointer 220 pointing to a beginning of the respective predetermined individually accessible portion 200 and e.g. use one or more of the pointers 220 for accessing the DS 45.

According to an embodiment A14, of the DS 45 of any of previous embodiments A13 and D1, wherein each individually accessible portion 200 represents
a corresponding NN layer 210 of the neural network or
a NN portion of a NN layer 210 of the NN, e.g., see, for instance, FIG. 3 or one of FIGS. 21 to 23.

### 2.2 Sub-Layer Bitstream Random Access

As mentioned in Section 1, there exist applications that may rely on grouping parameter tensors 30 within a layer 210 in a specific configurable fashion as it can be beneficial to have them decoded/processed/inferred partially or in parallel. Therefore, sub-layer wise access to the layer bitstream, e.g. individually accessible portions 200, can help to access desired data in parallel or leave out unnecessary data portions.

In one embodiment, the coding dependencies within the layer bitstream are reset at sub-layer granularity, i.e. reset the DeepCABAC probability states.

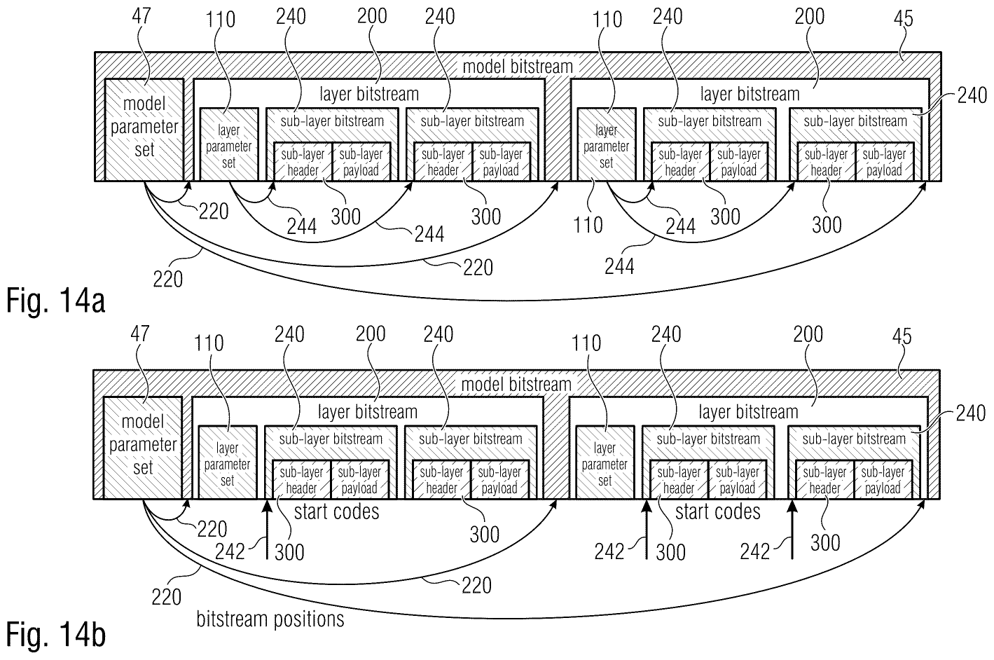

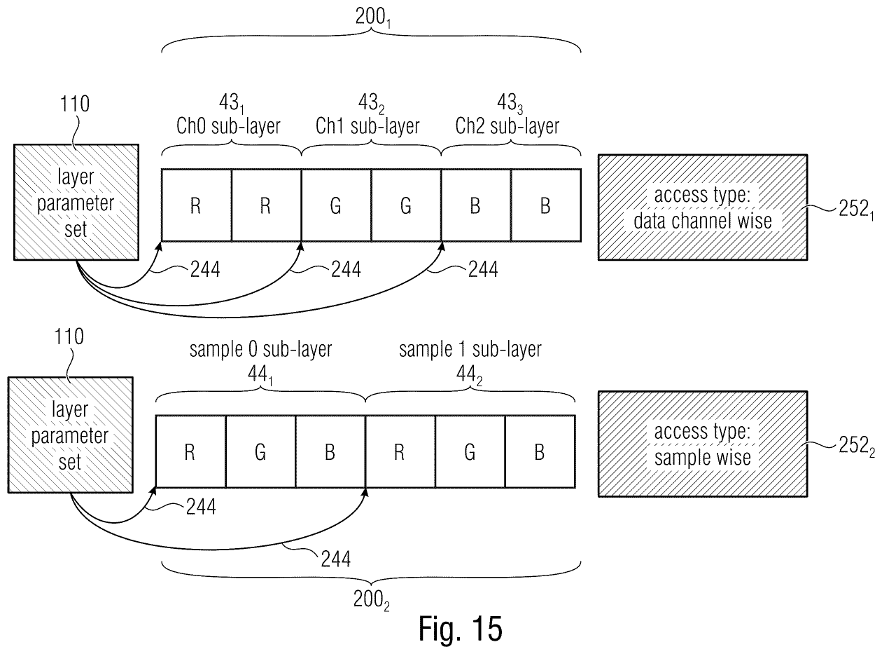

In another embodiment of the invention, the individual sub-layer bitstreams, i.e. individually accessible sub-portions 240, within a layer bitstream, i.e. the individually accessible portions 200, are indicated through bitstream position, e.g., a pointer 244, or an offset, e.g., a pointer 244, in bytes in a parameter set portion 110 of the bitstream, i.e. data stream 45, with the scope of the layer or model. FIG. 13, FIG. 14a and FIG. 15 illustrate the embodiment. FIG. 14a illustrates a sub-layer access, i.e. an access to the individually accessible sub-portions 240, through relative bitstream positions or offsets. Additionally, for example, the individually accessible portions 200, can also be accessed by pointers 220 on a layer-level. The pointer 220 on a layer-level, for example, is encoded into a model parameter set 47, i.e. a header, of the DS 45. The pointer 220 points to individually accessible portions 200 representing a corresponding NN portion comprising a NN layer of the NN. The pointer 244 on a sublayer-level, for example, is encoded into a layer parameter set 110 of an individually accessible portion 200 representing a corresponding NN portion comprising a NN layer of the NN. The pointer 244 points to beginnings of individually accessible sub-portions 240 representing a corresponding NN portion comprising portions of a NN layer of the NN.

According to an embodiment, the pointer 220 on a layer-level indicates an offset with respect to a beginning of the first individually accessible portion 200₁. The pointer 244 on a sublayer-level indicates the offset of individually accessible sub-portions 240 of a certain individually accessible portion 200 with respect to a beginning of a first individually accessible sub-portion 240 of the certain individually accessible portion 200.

According to an embodiment, the pointers 220/244 indicate byte offsets with respect to an aggregate unit, which contains a number of units. The pointers 220/244 might indicate byte offsets from a start of the aggregate unit to a start of a unit in an aggregate unit's payload.

In another embodiment of the invention, the individual sub-layer bitstreams, i.e. individually accessible sub-portions 240, within a layer bitstream, i.e. individually accessible portions 200, are indicated through detectable start codes 242 in the bitstream, i.e. data stream 45, which would be sufficient as the amount of data per layer is usually less than in case layers are to be detected by start codes 242 within the whole model bitstream, i.e. the data stream 45. The FIGS. 13 and 14b illustrate the embodiment. FIG. 14b illustrates a usage of start codes 242 on sub-layer level, i.e. for each individually accessible sub-portion 240, and bitstream positions, i.e. pointer 220, on layer-level, i.e. for each individually accessible portion 200.

In another embodiment, run length, i.e. a data stream length 246, of (sub-) layer bitstream portions, individually accessible sub-portion 240, is indicated in the parameter set/header portion 47 of the bitstream 45 or in the parameter set portions 110 of an individually accessible portion 200 in order to facilitate cut out of said portions, i.e. the individually accessible sub-portion 240, for the purpose of packaging them in appropriate containers. As illustrated in FIG. 13, the data stream length 246 of an individually accessible sub-portion 240 might be indicated by a data stream length parameter.

FIG. 13 shows an embodiment E1, of a data stream 45 having a representation of a neural network encoded thereinto, wherein the data stream 45 is structured into one or more individually accessible portions 200, each individually accessible portion 200 representing a corresponding NN layer of the neural network, wherein the data stream 45 is, within a predetermined portion, e.g. an individually accessible portion 200, further structured into individually accessible sub-portions 240, each sub-portion 240 representing a corresponding NN portion of the respective NN layer of the neural network, wherein the data stream 45 comprises for each of one or more predetermined individually accessible sub-portions 240
a start code 242 at which the respective predetermined individually accessible sub-portion 240 begins, and/or
a pointer 244 pointing to a beginning of the respective predetermined individually accessible sub-portion 240, and/or
a data stream length parameter indicating a data stream length 246 of the respective predetermined individually accessible sub-portion 240 for skipping the respective predetermined individually accessible sub-portion 240 in parsing the DS 45.

The herein described individually accessible sub-portions 240 might have the same or similar features and or functionalities, as described with regard to the individual accessible sub-portions 43/44.

The individually accessible sub-portions 240 within the same predetermined portion might all have the same data stream length 246, whereby it is possible that the data stream length parameter indicates one data stream length 246, which data stream length 246 is applicable for each individually accessible sub-portion 240 within the same predetermined portion. The data stream length parameter might be indicative of the data stream length 246 of all individually accessible sub-portions 240 of the whole data stream 45 or the data stream length parameter might, for each individually accessible portion 200, be indicative of the data stream length 246 of all individually accessible sub-portions 240 of the respective individually accessible portion 200. The one or more data stream length parameter might be encoded in a header portion 47 of the data stream 45 or in a parameter set portion 110 of the respective individually accessible portion 200.

A corresponding embodiment ZE1, is related to an apparatus for encoding a representation of a neural network into the DS 45, so that the data stream 45 is structured into one or more individually accessible portions 200, each individually accessible portion 200 representing a corresponding NN layer of the neural network, and so that the data stream 45 is, within a predetermined portion, e.g. an individually accessible portion 200, further structured into individually accessible sub-portions 240, each sub-portion 240 representing a corresponding NN portion of the respective NN layer of the neural network, wherein the apparatus is configured to provide the data stream 45 with, for each of one or more predetermined individually accessible sub-portions 240
the start code 242 at which the respective predetermined individually accessible sub-portion 240 begins, and/or
the pointer 244 pointing to a beginning of the respective predetermined individually accessible sub-portion 240, and/or
the data stream length parameter indicating a data stream length 246 of the respective predetermined individually accessible sub-portion 240 for skipping the respective predetermined individually accessible sub-portion 240 in parsing the DS 45.

Another corresponding embodiment XE1, is related to an apparatus for decoding a representation of a neural network from the DS 45, wherein the data stream 45 is structured into one or more individually accessible portions 200, each individually accessible portion 200 representing a corresponding NN layer of the neural network, and wherein the data stream 45 is, within a predetermined portion, e.g. an individually accessible portion 200, further structured into individually accessible sub-portions 240, each sub-portion 240 representing a corresponding NN portion of the respective NN layer of the neural network, wherein the apparatus is configured to decode from the data stream 45, for each of one or more predetermined individually accessible sub-portions 240
the start code 242 at which the respective predetermined individually accessible sub-portion 240 begins, and/or
the pointer 244 pointing to a beginning of the respective predetermined individually accessible sub-portion 240, and/or
the data stream length parameter indicating a data stream length 246 of the respective predetermined individually accessible sub-portion 240 for skipping the respective predetermined individually accessible sub-portion 240 in parsing the DS 45
and e.g. use for one or more predetermined individually accessible sub-portions 240, this information, e.g., the start code 242, the pointer 244 and/or the data stream length parameter, for accessing the DS 45.

According to an embodiment E2, of the DS 45 of embodiment E1, the data stream 45 has the representation of the neural network encoded thereinto using context-adaptive arithmetic coding and using context initialization at a start of each individually accessible portion 200 and each individually accessible sub-portion 240, see, for example, FIG. 8.

According to an embodiment E3, the data stream 45 of embodiment E1 or embodiment E2, is according to any other embodiment herein. And it is clear, that the apparatuses of the embodiments ZE1 and XE1 might also be completed by any other feature and/or functionality described herein.

### 2.3 Bitstream Random Access Types

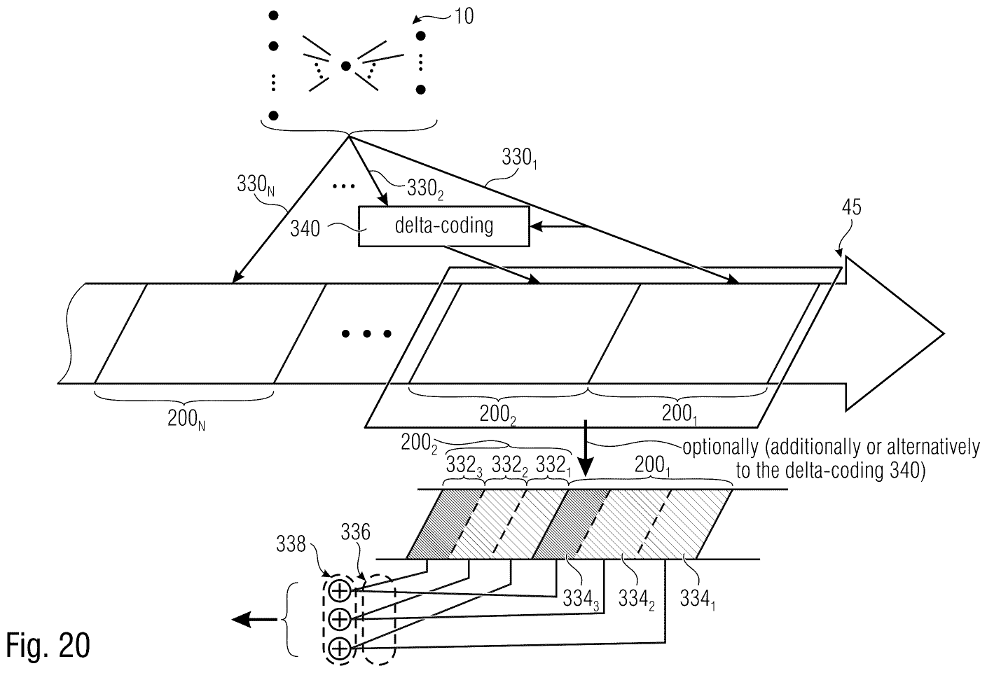

Depending on the type of a (sub-) layer 240 resulting from the selected serialization type, e.g. the serialization types 100₁ and 100₂ shown in FIG. 3, various processing options are available that also determine if and how a client would access the (sub-) layer bitstream 240. For instance, when the chosen serialization 100₁ results in sub-layers 240 being image color channel specific and this allowing for data channel-wise parallelization of decoding/inference, this should be indicated in the bitstream 45 to a client. Another example is the derivation of preliminary results from a baseline NN subset that could be decoded/inferred independent of the advanced NN subset of a specific layer/model, as described with regard to FIGS. 20 to 23.

In one embodiment, a parameter set/header 47 in the bitstream 45 with scope of the whole model, one or multiple layers indicates the type of the (sub-) layer random access in order to allow a client appropriate decision making. FIG. 15 shows two exemplary types of random access 252₁ and 252₂, determined by the serialization. The illustrated types of random access 252₁ and 252₂ might represent possible processing options for an individually accessible portion 200 representing a corresponding NN layer. A first processing option 252₁ might indicate a data channel wise access to the NN parameter within the individually accessible portion 200₁ and a second processing option 252₂ might indicate a sample wise access to the NN parameter within the individually accessible portion 200₂.

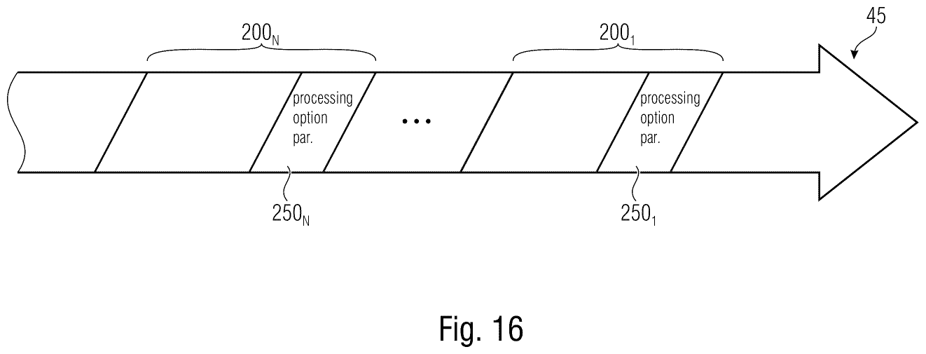

FIG. 16 shows a general embodiment F1, of a data stream 45 having a representation of a neural network encoded thereinto, wherein the data stream 45 is structured into individually accessible portions 200, each individually accessible portion 200 representing a corresponding NN portion, e.g. comprising one or more NN layer or comprising portions of a NN layer, of the neural network, wherein the data stream 45 comprises for each of one or more predetermined individually accessible portions 200 a processing option parameter 250 indicating one or more processing options 252 which have to be used or which may optionally be used when using the NN for inference.

A corresponding embodiment ZF1, is related to an apparatus for encoding a representation of a neural network into the DS 45, so that the data stream 45 is structured into individually accessible portions 200, each individually accessible portion 200 representing a corresponding NN portion, e.g. comprising one or more NN layer or comprising portions of a NN layer, of the neural network, wherein the apparatus is configured to provide the data stream 45 with, for each of one or more predetermined individually accessible portions 200, the processing option parameter 250 indicating one or more processing options 252 which have to be used or which may optionally be used when using the NN for inference.

Another corresponding embodiment XF1, is related to an apparatus for decoding a representation of a neural network from the DS 45, wherein the data stream 45 is structured into individually accessible portions 200, each individually accessible portion 200 representing a corresponding NN portion, e.g. comprising one or more NN layer or comprising portions of a NN layer, of the neural network, wherein the apparatus is configured to decode from the data stream 45, for each of one or more predetermined individually accessible portions 200, a processing option parameter 250 indicating one or more processing options 252 which have to be used or which may optionally be used when using the NN for inference, e.g. decode based on the latter as to which of the one or more predetermined individually accessible portions to access, skip and/or decode. Based on the one or more processing options 252, the apparatus might be configured to decide how and/or which individually accessible portions or individually accessible sub-portions can be accessed, skipped and/or decoded.

According to an embodiment F2 of the DS 45 of embodiment F1, the processing option parameter 250 indicates the one or more available processing options 252 out of a set of predetermined processing options including
parallel processing capability of the respective predetermined individually accessible portion 200; and/or
sample wise parallel processing capability 252₁ of the respective predetermined individually accessible portion 200; and/or
channel wise parallel processing capability 252₂ of the respective predetermined individually accessible portion 200; and/or
classification category wise parallel processing capability of the respective predetermined individually accessible portion 200; and/or
dependency of the NN portion, e.g., a NN layer, represented by the respective predetermined individually accessible portion on a computation result gained from another individually accessibly portion of the DS relating to the same NN portion but belonging to another version of versions of the NN which are encoded into the DS in a layered manner, as shown in FIGS. 20 to 23.

The apparatus, according to embodiment ZF1, might be configured to encode the processing option parameter 250 such that the processing option parameter 250 points to one or more processing options out of the set of predetermined processing options and the apparatus, according to embodiment XF1, might be configured to decode the processing option parameter 250 indicating one or more processing options out of the set of predetermined processing options.

### 3 SIGNALING OF QUANTIZATION PARAMETERS

The layer payload, e.g., the NN parameter 32 encoded into the individual accessible portions 200, or the sub-layer payload, e.g., the NN parameter 32 encoded into the individual accessible sub-portions 240, may contain different types of parameters 32 that represent rational numbers like e.g. weights, biases, etc.

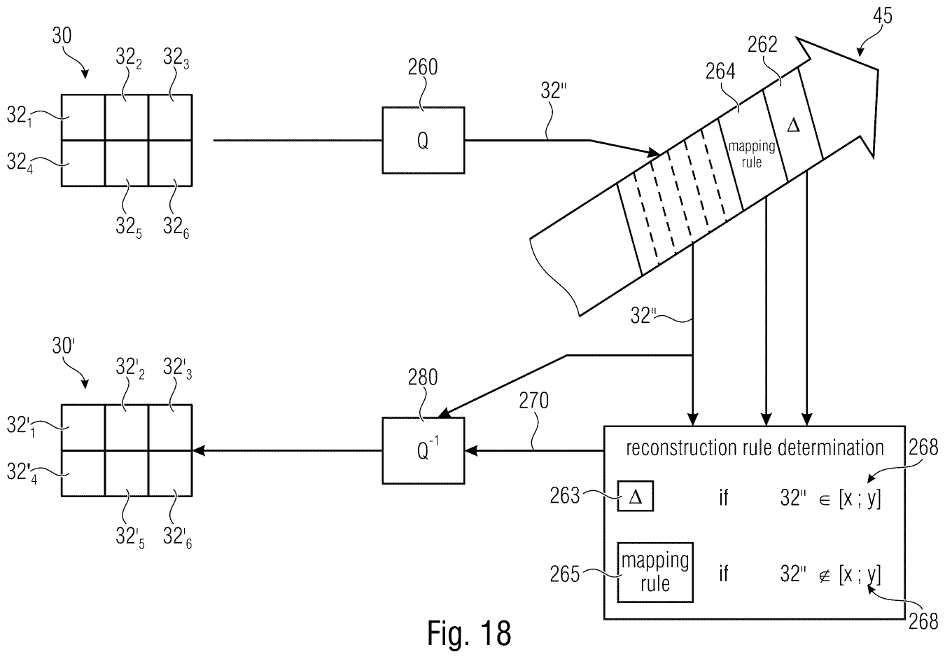

In an advantageous embodiment, shown in FIG. 18, one such type of parameters is signalled as integer values in the bitstream such that the reconstructed values, i.e. the reconstructed NN parameters 32′, are derived applying a reconstruction rule 270 to these values, i.e. quantization indices 32″, that involves reconstruction parameters. For example, such a reconstruction rule 270 may consist of multiplying each integer value, i.e. quantization indices 32″, with an associated quantization step size 263. The quantization step size 263 is the reconstruction parameter in this case.

In an advantageous embodiment, the reconstruction parameters are signalled either in the model parameter set 47, or in the layer parameter set 110, or in the sub-layer header 300.

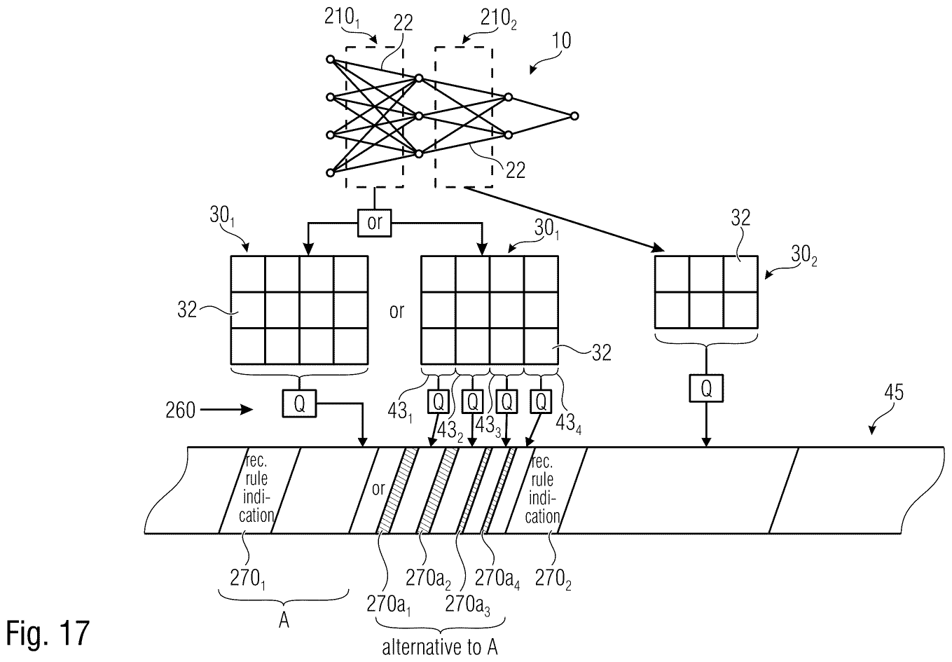

In another advantageous embodiment, a first set of reconstruction parameters is signalled in the model parameter set and, optionally, a second set of reconstruction parameters is signalled in the layer parameter set and, optionally, a third set of reconstruction parameters is signalled in the sub-layer header. If present, the second set of reconstruction parameters depends on the first set of reconstruction parameters. If present, the third set of reconstruction parameters may depend on the first and/or second set of reconstruction parameters. This embodiment is described in more detail with respect to FIG. 17.

For example, a rational number s, i.e. a predetermined basis, is signalled in the first set of reconstruction parameters, a first integer number x₁, i.e. a first exponent value, is signalled in the second set of reconstruction parameters, and a second integer x₂, i.e. a second exponent value, is signalled in the third set of reconstruction parameters. Associated parameters of the layer or sub-layer payload, encoded in the bitstream as integer values wₙ, are reconstructed using the following reconstruction rule. Each integer value wₙ is multiplied with a quantization stepsize A that is calculated as s^{x}^{₁}^{+x}^{₂}.

In an advantageous embodiment, s=2^{-0.5}.

The rational number s may, for example, be encoded as a floating point value. The first and second integer number x₁ and x₂ may be signalled using a fixed or variable number of bits in order to minimize the overall signalling cost. For example, if the quantization stepsize of sub-layers of a layer are similar, the associated values x₂ would be rather small integers and it may be efficient to allow only few bits for signalling them.

In an advantageous embodiment, as shown in FIG. 18, reconstruction parameters may consist of a code book, i.e. a quantization-index-to-reconstruction-level mapping, which is a list of mappings of integers to rational numbers. Associated parameters of the layer or sub-layer payload, encoded in the bitstream 45 as integer values wₙ, are reconstructed using the following reconstruction rule 270. Each integer value wₙ is looked up in the code book. The one mapping where the associated integer matches wₙ is selected and the associated rational number is the reconstructed value, i.e. the reconstructed NN parameter 32′.

In another advantageous embodiment, the first and/or the second and/or the third set of reconstruction parameters each consist of a code book according to the previous advantageous embodiment. However, for applying the reconstruction rule, one joint code book is derived by creating the set union of mappings of code books of the first, and/or, the second, and/or the third set of reconstruction parameters. If there exist mappings with the same integers, the mappings of the code book of the third set of reconstruction parameters take precedence over the mappings of the code book of the second set of reconstruction parameters and the mappings of the code book of the second set of reconstruction parameters take precedence over the mappings of the code book of the first set of reconstruction parameters.

FIG. 17 shows an embodiment G1, of a data stream 45 having NN parameters 32 encoded thereinto, which represent a neural network 10, wherein the NN parameters 32 are encoded into the DS 45 in a manner quantized 260 onto quantization indices, and wherein the NN parameters 32 are encoded into the DS 45 so that NN parameters 32 in different NN portions of the NN 10 are quantized 260 differently, and the DS 45 indicates, for each of the NN portions, a reconstruction rule 270 for dequantizing NN parameters relating to the respective NN portion.

Each NN portion of the NN, for example, might comprise interconnections between nodes of the NN and different NN portion might comprise different interconnections between nodes of the NN.

According to an embodiment, the NN portions comprise a NN layer 210 of the NN 10 and/or layer subportions 43 into which a predetermined NN layer of the NN is subdivided. As shown in FIG. 17 all NN parameters 32 within one layer 210 of the NN might represent a NN portion of the NN, wherein the NN parameter 32 within a first layer 210₁ of the NN 10 are quantized 260 differently than NN parameter 32 within a second layer 210₂ of the NN 10. It is also possible, that the NN parameter 32 within a NN layer 210₁ are grouped into different layer subportions 43, i.e. individually accessible sub-portions, wherein each group might represent a NN portion. Thus different layer subportions 43 of a NN layer 210₁ might be quantized 260 differently.

A corresponding embodiment ZG1, relates to an apparatus for encoding NN parameters 32, which represent a neural network 10, into a DS 45, so that the NN parameters 32 are encoded into the DS 45 in a manner quantized 260 onto quantization indices, and the NN parameters 32 are encoded into the DS 45 so that NN parameters 32 in different NN portions of the NN 10 are quantized 260 differently, wherein the apparatus is configured to provide the DS 45 indicating, for each of the NN portions, a reconstruction rule for dequantizing NN parameters 32 relating to the respective NN portion. Optionally, the apparatus may also perform the quantization 260.

Another corresponding embodiment XG1, is related to an apparatus for decoding NN parameters 32, which represent a neural network 10, from the DS 45, wherein the NN parameters 32 are encoded into the DS 45 in a manner quantized 260 onto quantization indices, and the NN parameters 32 are encoded into the DS 45 so that NN parameters 32 in different NN portions of the NN 10 are quantized 260 differently, wherein the apparatus is configured to decode from the data stream 45, for each of the NN portions, a reconstruction rule 270 for dequantizing NN parameters 32 relating to the respective NN portion. Optionally, the apparatus may also perform the dequantization using the reconstruction rule 270, i.e. the one relating to the NN portion which the currently dequantized NN parameters 32 belong to. The apparatus might, for each of the NN portions, be configured to dequantize the NN parameter of the respective NN portion using the decoded reconstruction rule 270 relating to the respective NN portion.

In the following, different features and/or functionalities are described in the context of the data stream 45, but the features and/or functionalities can also, in the same way or in a similarly way, be features and/or functionalities of the apparatus, according to the embodiment ZG1, or of the apparatus, according to the embodiment XG1.

As already mentioned above, according to an embodiment G2, of the DS 45 of embodiment G1, the NN portions comprise NN layers 210 of the NN 10 and/or layer portions into which a predetermined NN layer 210 of the NN 10 is subdivided.

According to an embodiment G3, of the DS 45 of embodiment G1 or G2, the DS 45 has a first reconstruction rule 270₁ for dequantizing NN parameters 32 relating to a first NN portion encoded thereinto in a manner delta-coded relative to a second reconstruction rule 270₂ for dequantizing 260 NN parameters 32 relating to a second NN portion. Alternatively, as shown in FIG. 17, a first reconstruction rule 270a₁ for dequantizing NN parameters 32 relating to a first NN portion, i.e. a layer subportion 431, is encoded into the DS 45 in a manner delta-coded relative to a second reconstruction rule 270a₂, relating to a second NN portion, i.e. a layer subportion 432. It is also possible, that a first reconstruction rule 270a₁ for dequantizing NN parameters 32 relating to a first NN portion, i.e. a layer subportion 431, is encoded into the DS 45 in a manner delta-coded relative to a second reconstruction rule 270₂, relating to a second NN portion, i.e. a NN layer 210₂.

In the following embodiments, the first reconstruction rule will be denoted as 270₁ and the second reconstruction rule will be denoted as 270₂ to avoid obscuring embodiments, but it is clear, that also in the following embodiments the first reconstruction rule and/or the second reconstruction rule might correspond to NN portions representing layer subportions 43 of a NN layer 210, as described above.

According to an embodiment G4, of the DS 45 of embodiment G3,
the DS 45 comprises, for indicating the first reconstruction rule 270₁, a first exponent value and, for indicating the second reconstruction rule 270₂, a second exponent value,
the first reconstruction rule 270₁ is defined by a first quantization step size defined by an exponentiation of a predetermined basis and a first exponent defined by the first exponent value, and
the second reconstruction rule 270₂ is defined by a second quantization step size defined by an exponentiation of the predetermined basis and a second exponent defined by a sum over the first and second exponent values.

According to an embodiment G4a, of the DS of embodiment G4, the DS 45 further indicates the predetermined basis.

According to an embodiment G4′, of the DS of any previous embodiment G1 to G3,
the DS 45 comprises, for indicating the first reconstruction rule 270₁ for dequantizing NN parameters 32 relating to a first NN portion, a first exponent value and, for indicating a second reconstruction rule 270₂ for dequantizing NN parameters 32 relating to a second NN portion, a second exponent value,
the first reconstruction rule 270₁ is defined by a first quantization step size defined by an exponentiation of a predetermined basis and a first exponent defined by a sum over the first exponent value and a predetermined exponent value, and
the second reconstruction rule is defined by a second quantization step size defined by an exponentiation of the predetermined basis and a second exponent defined by a sum over the second exponent values and the predetermined exponent value.

According to an embodiment G4′a, of the DS of embodiment G4′, the DS further indicates the predetermined basis.

According to an embodiment G4′b, of the DS of embodiment G4′a, the DS indicates the predetermined basis at a NN scope, i.e. relating to the whole NN.

According to an embodiment G4′c, of the DS of any previous embodiment G4′ to G4′b, wherein the DS 45 further indicates the predetermined exponent value.

According to an embodiment G4′d, of the DS 45 of embodiment G4′c, the DS 45 indicates the predetermined exponent value at a NN layer scope, i.e. for a predetermined NN layer 210 which the first 431 and second 432 NN portions are part of.

According to an embodiment G4′e, of the DS of any previous embodiment G4′c and G4′d, the DS 45 further indicates the predetermined basis and the DS 45 indicates the predetermined exponent value at a scope finer than a scope at which the predetermined basis is indicated by the DS 45.

According to an embodiment G4f, of the DS 45 of any of previous embodiment G4 to G4a or G4′ to G4′e, the DS 45 has the predetermined basis encoded thereinto in a non-integer format, e.g. floating point or rational number or fixed-point number, and the first and second exponent values in integer format, e.g. signed integer. Optionally, the predetermined exponent value might also be encoded into the DS 45 in integer format.

According to an embodiment G5, of the DS of any of embodiments G3 to G4f, the DS 45 comprises, for indicating the first reconstruction rule 270₁, a first parameter set defining a first quantization-index-to-reconstruction-level mapping, and for indicating the second reconstruction rule 270₂, a second parameter set defining a second quantization-index-to-reconstruction-level mapping, wherein
the first reconstruction rule 270₁ is defined by the first quantization-index-to-reconstruction-level mapping, and
the second reconstruction rule 270₂ is defined by an extension of the first quantization-index-to-reconstruction-level mapping by the second quantization-index-to-reconstruction-level mapping in a predetermined manner.

According to an embodiment G5′, of the DS 45 of any of embodiments G3 to G5, the DS 45 comprises, for indicating the first reconstruction rule 270₁, a first parameter set defining a first quantization-index-to-reconstruction-level mapping, and for indicating the second reconstruction rule 270₂, a second parameter set defining a second quantization-index-to-reconstruction-level mapping, wherein
the first reconstruction rule 270₁ is defined by an extension of a predetermined quantization-index-to-reconstruction-level mapping by the first quantization-index-to-reconstruction-level mapping in a predetermined manner, and
the second reconstruction rule 270₂ is defined by an extension of the predetermined quantization-index-to-reconstruction-level mapping by the second quantization-index-to-reconstruction-level mapping in the predetermined manner.

According to an embodiment G5′a, of the DS 45 of embodiment G5′, wherein the DS 45 further indicates the predetermined quantization-index-to-reconstruction-level mapping.

According to an embodiment G5′b, of the DS 45 of embodiment G5′a, wherein the DS 45 indicates the predetermined quantization-index-to-reconstruction-level mapping at a NN scope, i.e. relating to the whole NN, or at a NN layer scope, i.e. for a predetermined NN layer 210 which the first 431 and second 432 NN portions are part of. The predetermined quantization-index-to-reconstruction-level mapping might be indicated at the NN scope, in case of the NN portions representing NN layer, e.g., for each of the NN portions, a respective NN portion represents a corresponding NN layer, wherein, for example, a first NN portion represents a different NN layer than a second NN portion. However, it is also possible, to indicate the predetermined quantization-index-to-reconstruction-level mapping at the NN scope, in case of at least some of NN portions representing layer subportions 43. Additionally, or alternatively, the predetermined quantization-index-to-reconstruction-level mapping might be indicated at the NN layer scope, in case of the NN portions representing layer subportions 43.

According to an embodiment G5c, of the DS 45 of any of previous embodiments G5 or G5′ to G5′b, according to the predetermined manner,
a mapping of each index value, i.e. quantization index 32″, according to the quantization-index-to-reconstruction-level mapping to be extended, onto a first reconstruction level is superseded by, if present, a mapping of the respective index value, according to the quantization-index-to-reconstruction-level mapping extending the quantization-index-to-reconstruction-level mapping to be extended, onto a second reconstruction level, and/or
for any index value, for which according to the quantization-index-to-reconstruction-level mapping to be extended, no reconstruction level is defined onto which the respective index value should be mapped, and which is, according to the quantization-index-to-reconstruction-level mapping extending the quantization-index-to-reconstruction-level mapping to be extended, mapped onto a corresponding reconstruction level, the mapping from the respective index value onto the corresponding reconstruction level is adopted, and/or
for any index value, for which according to the quantization-index-to-reconstruction-level mapping extending the quantization-index-to-reconstruction-level mapping to be extended, no reconstruction level is defined onto which the respective index value should be mapped, and which is, according to the quantization-index-to-reconstruction-level mapping to be extended, mapped onto a corresponding reconstruction level, the mapping from the respective index value onto the corresponding reconstruction level is adopted.

According to an embodiment G6, shown in FIG. 18, of the DS 45 of any previous embodiment G1 to G5c, the DS 45 comprises, for indicating the reconstruction rule 270 of a predetermined NN portion, e.g. representing a NN layer or comprising layer subportions of a NN layer,
a quantization step size parameter 262 indicating a quantization step size 263, and
a parameter set 264 defining a quantization-index-to-reconstruction-level mapping 265,
wherein the reconstruction rule 270 of the predetermined NN portion is defined by
   the quantization step size 263 for quantization indices 32″ within a predetermined index interval 268, and
   the quantization-index-to-reconstruction-level mapping 265 for quantization indices 32″ outside the predetermined index interval 268.

FIG. 18 shows an embodiment H1, of a data stream 45 having NN parameters 32 encoded thereinto, which represent a neural network,
wherein the NN parameters 32 are encoded into the DS 45 in a manner quantized 260 onto quantization indices 32″,
wherein the DS 45 comprises, for indicating a reconstruction rule 270 for dequantizing 280 the NN parameters, i.e. the quantization indices 32″,
   a quantization step size parameter 262 indicating a quantization step size 263, and
   a parameter set 264 defining a quantization-index-to-reconstruction-level mapping 265,
   wherein the reconstruction rule 270 of the predetermined NN portion is defined by
      the quantization step size 263 for quantization indices 32″ within a predetermined index interval 268, and
      the quantization-index-to-reconstruction-level mapping 265 for quantization indices 32″ outside the predetermined index interval 268.

A corresponding embodiment ZH1, is related to an apparatus for encoding the NN parameters 32, which represent a neural network, into the DS 45, so that the NN parameters 32 are encoded into the DS 45 in a manner quantized 260 onto quantization indices 32″, wherein the apparatus is configured to provide the DS 45 with, for indicating a reconstruction rule 270 for dequantizing 280 the NN parameters 32,
the quantization step size parameter 262 indicating a quantization step size 263, and
the parameter set 264 defining a quantization-index-to-reconstruction-level mapping 265,
wherein the reconstruction rule 270 of the predetermined NN portion is defined by
   the quantization step size 263 for quantization indices 32″ within a predetermined index interval 268, and
   the quantization-index-to-reconstruction-level mapping 265 for quantization indices 32″ outside the predetermined index interval 268.

Another corresponding embodiment XH1, relates to an apparatus for decoding NN parameters 32, which represent a neural network, from the DS 45, wherein the NN parameters 32 are encoded into the DS 45 in a manner quantized onto quantization indices 32″, wherein the apparatus is configured to derive from the DS 45 a reconstruction rule 270 for dequantizing 280 the NN parameters, i.e. the quantization indices 32″, by decoding from the DS 45
the quantization step size parameter 262 indicating a quantization step size 263, and
the parameter set 264 defining a quantization-index-to-reconstruction-level mapping 265,
wherein the reconstruction rule 270 of the predetermined NN portion is defined by the
   the quantization step size 263 for quantization indices 32″ within a predetermined index interval 268, and
   the quantization-index-to-reconstruction-level mapping 265 for quantization indices 32″ outside the predetermined index interval 268.

In the following, different features and/or functionalities are described in the context of the data stream 45, but the features and/or functionalities can also, in the same way or in a similarly way, be features and/or functionalities of the apparatus, according to the embodiment ZH1, or of the apparatus, according to the embodiment XH1.

According to an embodiment G7, of the DS 45 of any of previous embodiments G6 or H1, the predetermined index interval 268 includes zero.

According to an embodiment G8, of the DS 45 of embodiment G7, the predetermined index interval 268 extends up to a predetermined magnitude threshold value y and quantization indices 32″ exceeding the predetermined magnitude threshold value y represent escape codes which signal that the quantization-index-to-reconstruction-level mapping 265 is to be used for dequantization 280.

According to an embodiment G9, of the DS 45 of any of previous embodiments G6 to G8, the parameter set 264 defines the quantization-index-to-reconstruction-level mapping 265 by way of a list of reconstruction levels associated with quantization indices 32″ outside the predetermined index interval 268.

According to an embodiment G10, of the DS 45 of any of previous embodiments G1 to G9, the NN portions comprise one or more sub-portions of an NN layer of the NN and/or one or more NN layers of the NN. FIG. 18 shows an example for a NN portion comprising one NN layer of the NN. A NN parameter tensor 30 comprising the NN parameter 32 might represent a corresponding NN layer.

According to an embodiment G11, of the DS 45 of any of previous embodiment G1 to G10, the data stream 45 is structured into individually accessible portions, each individually accessible portion having the NN parameters 32 for a corresponding NN portions encoded thereinto, see, for example, one of FIG. 8 or FIGS. 10 to 17.

According to an embodiment G12, of the DS 45 of G11, the individually accessible portions are encoded using context-adaptive arithmetic coding and using context initialization at a start of each individually accessible portion, as, for example, shown in FIG. 8.

According to an embodiment G13, of the DS 45 of any previous embodiment G11 or G12, the data stream 45 comprises for each individually accessible portion, as, for example, shown in one of FIGS. 11 to 15,
a start code 242 at which the respective individually accessible portion begins, and/or
a pointer 220/244 pointing to a beginning of the respective individually accessible portion, and/or
a data stream length parameter 246 indicating a data stream length of the respective individually accessible portion for skipping the respective individually accessible portion in parsing the DS 45.

According to an embodiment G14, of the DS 45 of any previous embodiment G11 to G13, the data stream 45 indicates, for each of the NN portions, the reconstruction rule 270 for dequantizing 280 NN parameters 32 relating to the respective NN portion in
a main header portion 47 of the DS 45 relating the NN as a whole,
a NN layer related header portion 110 of the DS 45 relating to the NN layer 210 the respective NN portion is part of, or
an NN portion specific header portion 300 of the DS 45 relating to the respective NN portion is part of, e.g., in case the NN portion representing a layer subportion, i.e. an individually accessible sub-portion 43/44/240, of a NN layer 210.

According to an embodiment G15, of the DS 45 of any previous embodiment G11 to G14, the DS 45 is according to any previous embodiment A1 to F2.

### 4 IDENTIFIER DEPENDING ON PARAMETER HASHES

In scenarios such as distributed learning, where many clients individually further train a network and send relative NN updates back to a central entity, it is important to identify networks through a versioning scheme. Thereby, the central entity can identify the NN that an NN update is built upon.

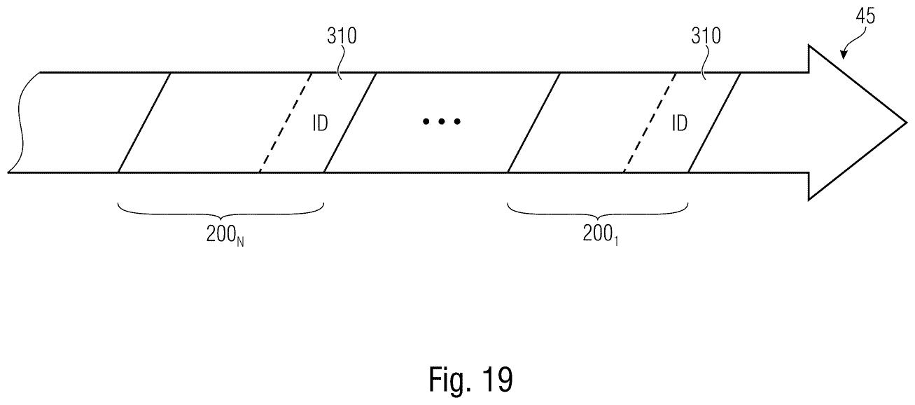

In other use cases, such as scalable NNs, baseline part of an NN can be executed, for instance, in order to generate preliminary results, before the complete or enhanced NN is carried out to receive full results. It can be the case that the enhanced NN uses a slightly different version of the baseline NN, e.g. with updated parameter tensors. When such updated parameter tensors are coded differentially, i.e. as update of formerly coded parameter tensors, it is useful to identify the parameter tensors that the differentially coded update is built upon, for example, with an identification parameter 310 as shown in FIG. 19.

Further, there exist use cases where the integrity of the NN is of highest important, i.e. transmission errors or involuntary changes of the parameter tensors are to be easily recognizable. An identifier, i.e. identification parameter 310, would make operations more error robust when it could be verified based on the NN characteristics.

However, state-of-the-art versioning is carried out via a checksum or a hash of the whole container data format and it is not easily possible to match equivalent NN in different containers. However, the clients involved may use different frameworks/containers. In addition, it is not possible to identify/verify just an NN subset (layers, sub-layers) without full reconstruction of the NN.

Therefore, as part of the invention, in one embodiment, an identifier, i.e. the identification parameter 310, is carried with each entity, i.e. model, layer, sub-layer, in order to allow for each entity to
check identity, and/or
refer or be referred to, and/or
check integrity.

In another embodiment, the identifier is derived from the parameter tensors using a hash algorithm, such as MD5 or SHA5, or an error detection codes, such as CRC or checksum.

In another embodiment, one such identifier of a certain entity is derived using identifiers of lower-level entities, e.g. a layer identifier would be derived from the identifiers of the constituting sub-layers, a model identifier would be derived from the identifiers of the constituting layers.

FIG. 19 shows an embodiment I1, of a data stream 45 having a representation of a neural network encoded thereinto, wherein the data stream 45 is structured into individually accessible portions 200, each portion 200 representing a corresponding NN portion, e.g. comprising one or more NN layer or comprising portions of a NN layer, of the neural network, wherein the data stream 45 comprises for each of one or more predetermined individually accessible portions 200 an identification parameter 310 for identifying the respective predetermined individually accessible portion 200.

A corresponding embodiment ZI1, is related to an apparatus for encoding a representation of a neural network into the DS 45, so that the data stream 45 is structured into the individually accessible portions 200, each portion 200 representing a corresponding NN portion e.g. comprising one or more NN layer or comprising portions of a NN layer, of the neural network, wherein the apparatus is configured to provide the data stream 45 with, for each of one or more predetermined individually accessible portions 200, an identification parameter 310 for identifying the respective predetermined individually accessible portion 200.

Another corresponding embodiment XI1, relates to an apparatus for decoding a representation of a neural network from the DS 45, wherein the data stream 45 is structured into individually accessible portions 200, each portion 200 representing a corresponding NN portion, e.g. comprising one or more NN layer or comprising portions of a NN layer, of the neural network, wherein the apparatus is configured to decode from the data stream 45, for each of one or more predetermined individually accessible portions 200, an identification parameter 310 for identifying the respective predetermined individually accessible portion 200.

In the following, different features and/or functionalities are described in the context of the data stream 45, but the features and/or functionalities can also, in the same way or in a similarly way, be features and/or functionalities of the apparatus, according to the embodiment ZI1, or of the apparatus, according to the embodiment XI1.

According to an embodiment I2, of the DS 45 of embodiment I1, the identification parameter 310 is related to the respective predetermined individually accessible portion 200 via a hash function or error detection code or error correction code.

According to an embodiment I3, of the DS 45 of any of previous embodiments I1 and I2, further comprising a higher-level identification parameter for identifying a collection of more than one predetermined individually accessible portion 200.

According to an embodiment I4, of the DS 45 of I3, the higher-level identification parameter is related to the identification parameters 310 of the more than one predetermined individually accessible portion 200 via a hash function or error detection code or error correction code.

According to an embodiment I5, of the DS 45 of any of previous embodiment I1 to I4, the individually accessible portions 200 are encoded using context-adaptive arithmetic coding and using context initialization at a start of each individually accessible portion, as, for example, shown in FIG. 8.

According to an embodiment I6, of the DS 45 of any of previous embodiments I1 to I5, wherein the data stream 45 comprises for each individually accessible portion 200, as, for example, shown in one of FIGS. 11 to 15,
a start code 242 at which the respective individually accessible portion 200 begins, and/or
a pointer 220/244 pointing to a beginning of the respective individually accessible portion 200, and/or
a data stream length parameter 246 indicating a data stream length of the respective individually accessible portion 200 for skipping the respective individually accessible portion 200 in parsing the DS 45.

According to an embodiment I7, of the DS 45 of any of previous embodiments I1 to I6, the NN portions comprise one or more sub-portions of an NN layer of the NN and/or one or more NN layers of the NN.

According to an embodiment I8, of the DS 45 of any of previous embodiments I1 to I7, the DS 45 is according to any previous embodiment A1 to G15.

### 5 SCALABLE NN BITSTREAMS

As mentioned previously, some applications rely on further structuring NNs 10, e.g., as shown in FIGS. 20 to 23, dividing layers 210 or groups thereof, i.e. sublayer 43/44/240, into a baseline, e.g., a second version 330₁ of the NN 10, and advanced section 330₂, e.g., a first version 330₂ of the NN 10, so that a client can match its processing capabilities or may be able to do inference on the baseline first before processing the more complex advanced NN. In such cases, it is beneficial as described in Sections 1 to 4, to be able to independently sort, code, and access the parameter tensors 30 of the respective subsection of NN layers in an informed way.

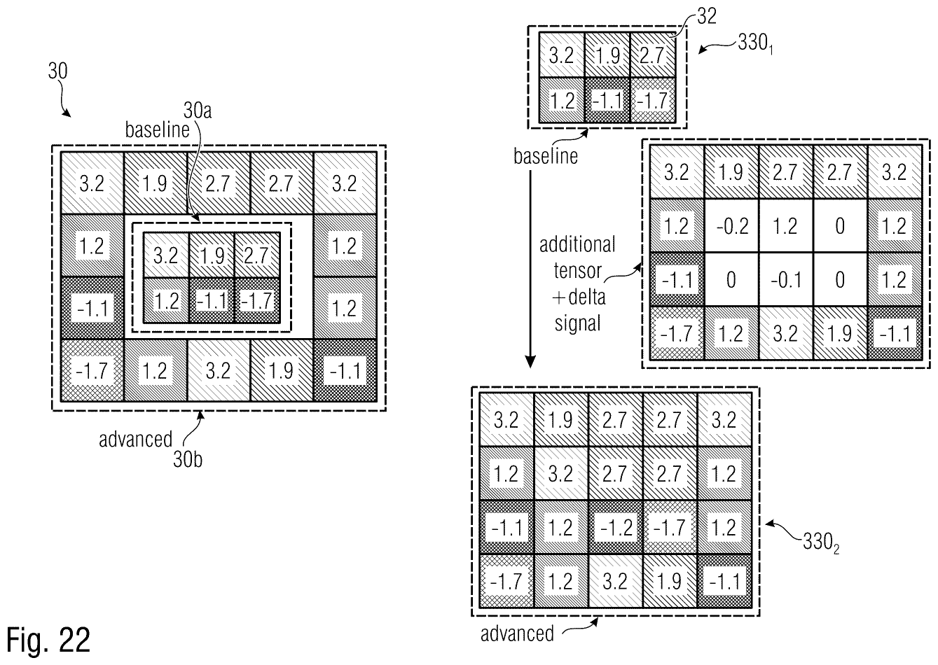

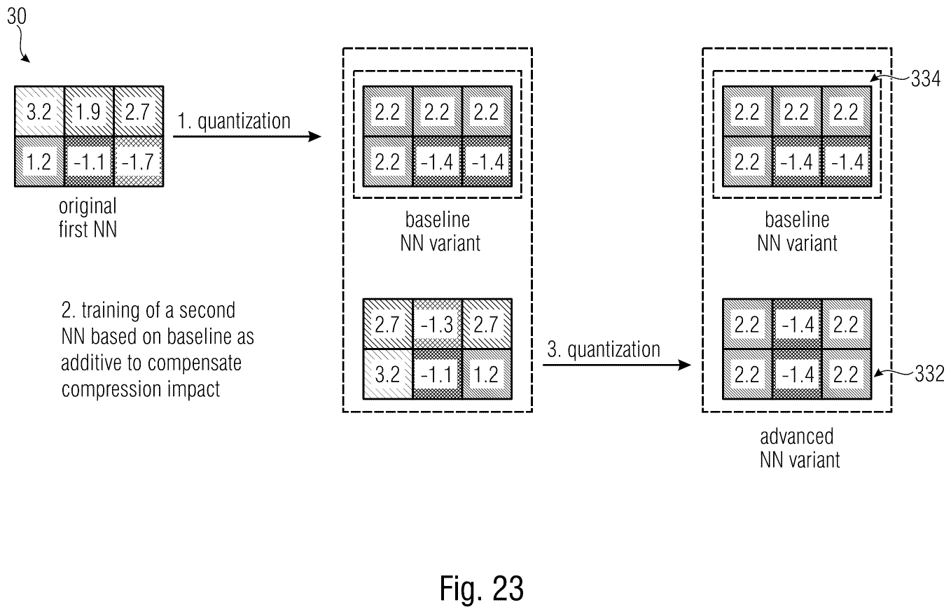

Further, in some cases, a NN 10 can be split in a baseline and advanced variant by:
reducing the number of neurons in layers, e.g., involving less operations, as shown in FIG. 22, and/or
coarser quantization of weights, e.g., allowing faster reconstruction, as shown in FIG. 21 and/or
different training, e.g. general baseline NN vs. personalized advanced NN, as shown in FIG. 23,
and so on.

FIG. 21 shows variants of a NN and a differential delta signal 342. A baseline version, e.g., a second version 330₁ of the NN, and an advanced version, e.g., a first version 330₂ of the NN, are illustrated. FIG. 21 illustrates one of the above cases of the creation of two layer variants from a single layer, e.g., a parameter tensor 30 representing the corresponding layer, of the original NN with two quantization settings and creation of the respective delta signal 342. The baseline version 330₁ is associated with a coarse quantization and the advanced version 330₂ is associate with a fine quantization. The advanced version 330₂ can be delta-coded relative to the baseline version 330₁.

FIG. 22 shows further variants of separation of the origin NN. In the FIG. 22, further variants of NN separation are shown, e.g. on the left-hand side, a separation of a layer, e.g., a parameter tensor 30 representing the corresponding layer, into baseline 30a and advanced 30b portion is indicated, i.e. the advanced portion 30b extents the baseline portion 30a. For inference of the advanced portion 30b, it is useful to do inference on the baseline portion 30a. On the right-hand side of FIG. 22, it is shown that the central part of the advanced portion 30b consists of an update of the baseline portion 30a, which could also be delta coded as illustrated in FIG. 21.

In these cases, the NN parameter 32, e.g., weights, of the baseline 330₁ and advanced 330₂ NN version have a clear dependency and/or the baseline version 330₁ of NN is in some form part of the advanced version 330₂ of the NN.

Therefore, it can be beneficial in terms of coding efficiency, processing overhead, parallelization and so on to code the parameter tensors 30b of the advanced NN portion, i.e. the first version 330₂ of the NN, as a delta to parameter tensors 30b of the baseline NN version, i.e. the second version 330₁ of the NN, on an NN scale or layer scale or even sublayer scale.

Further variants are depicted in FIG. 23, wherein an advanced version of the NN is created to compensate for a compression impact on the original NN by training in presence of the lossy compressed baseline NN variant. The advanced NN is inferred in parallel to the baseline NN and its NN parameter, e.g., weights, connect to the same neurons as the baseline NN. FIG. 23 shows, for example, a training of an augmentation NN based on a lossy coded baseline NN variant.

In one embodiment, a (sub-) layer bitstream, i.e. an individually accessible portion 200 or an individually accessible sub-portion 34/44/220 is divided into two or more (sub-) layer bitstreams, the first representing a baseline version 330₁ of the (sub-) layer and the second one being an advanced version 330₂ of the first (sub-) layer and so on, wherein the baseline version 330₁ precedes the advanced version 330₂ in bitstream order.

In another embodiment, a (sub-) layer bitstream is indicated as containing an incremental update of parameter tensors 30 of another (sub-) layer within the bitstream, e.g. incremental update comprising delta parameter tensors, i.e. the delta signal 342, and/or parameter tensors.

In another embodiment, a (sub-) layer bitstream is carrying a reference identifier referring to the (sub-) layer bitstream with a matching identifier that he contains an incremental update of parameter tensors 30 for.

FIG. 20 shows an embodiment J1, of a data stream 45 having a representation of a neural network 10 encoded thereinto in a layered manner so that different versions 330 of the NN 10 are encoded into the data stream 45, wherein the data stream 45 is structured into one or more individually accessible portions 200, each portion 200 relating to a corresponding version 330 of the neural network 10, wherein the data stream 45 has a first version 330₂ of the NN 10 encoded into a first portion 200₂
delta-coded 340 relative to a second version 330₁ of the NN 10 encoded into a second portion 200₁, and/or
in form of one or more compensating NN portions 332 each of which is to be, for performing an inference based on the first version 330₂ of the NN 10,
   executed in addition to an execution of a corresponding NN portion 334 of a second version 330₁ of the NN 10 encoded into a second portion 200₁, and
   wherein outputs 336 of the respective compensating NN portion 332 and corresponding NN portion 334 are to be summed up 338.

According to an embodiment, the compensating NN portions 332 might comprise a delta signal 342, as shown in FIG. 21, or an additional tensor and a delta signal, as shown in FIG. 22, or NN parameter differently trained than NN parameter within the corresponding NN portion 334, e.g., as shown in FIG. 23.

According to the embodiment, shown in FIG. 23, a compensating NN portion 332 comprises quantized NN parameters of a NN portion of a second neural network, wherein the NN portion of the second neural network is associated with a corresponding NN portion 334 of the NN 10, i.e. a first NN. The second neural network might be trained such that the compensating NN portions 332 can be used to compensate a compression impact, e.g. a quantization error, on the corresponding NN portions 334 of the first NN. The outputs of the respective compensating NN portion 332 and corresponding NN portion 334 are summed up to reconstruct NN parameter corresponding to the first version 330₂ of the NN 10 to allow an inference based on the first version 330₂ of the NN 10.

Although the above discussed embodiments mainly focus on providing the different versions 330 of the NN 10 in one data stream, it is also possible to provide the different versions 330 in different data streams. The different versions 330, for example, are delta coded relative to a simpler version into the different data streams. Thus, separate data streams (DSs) might be used. For example, first, a DS is sent, containing initial NN data and later a DS is sent, containing updated NN data.

A corresponding embodiment ZJ1, relates to an apparatus for encoding a representation of a neural network into the DS 45 in a layered manner so that different versions 330 of the NN 10 are encoded into the data stream 45, and so that the data stream 45 is structured into one or more individually accessible portions 200, each portion 200 relating to a corresponding version 330 of the neural network 10, wherein the apparatus is configured encode a first version 330₂ of the NN 10 encoded into a first portion 200₂
delta-coded 340 relative to a second version 330₁ of the NN 10 encoded into a second portion 200₁, and/or
in form of one or more compensating NN portions 332 each of which is to be, for performing an inference based on the first version 330₂ of the NN 10,
   executed in addition to an execution of a corresponding NN portion 334 of a second version 330₁ of the NN 10 encoded into a second portion 200₁, and
   wherein outputs 336 of the respective compensating NN portion 332 and corresponding NN portion 334 are to be summed up 338.

Another corresponding embodiment XJ1 relates to an apparatus for decoding a representation of a neural network 10 from the DS 45, into which same is encoded in a layered manner so that different versions 330 of the NN 10 are encoded into the data stream 45, and so that the data stream 45 is structured into one or more individually accessible portions 200, each portion 200 relating to a corresponding version 330 of the neural network 10, wherein the apparatus is configured decode a first version 330₂ of the NN 10 encoded from a first portion 200₂
by using delta-decoding 340 relative to a second version 330₁ of the NN 10 encoded into a second portion 200₁, and/or
by decoding from the DS 45 one or more compensating NN portions 332 each of which is to be, for performing an inference based on the first version 330₂ of the NN 10,
   executed in addition to an execution of a corresponding NN portion 334 of a second version 330₁ of the NN 10 encoded into a second portion 200₁, and
   wherein outputs 336 of the respective compensating NN portion 332 and corresponding NN portion 334 are to be summed up 338.

In the following, different features and/or functionalities are described in the context of the data stream 45, but the features and/or functionalities can also, in the same way or in a similarly way, be features and/or functionalities of the apparatus, according to the embodiment ZJ1, or of the apparatus, according to the embodiment XJ1.

According to an embodiment J2, of the data stream 45 of embodiment J1, the data stream 45 has the first version 330₁ of the NN 10 encoded into a first portion 200₁ delta-coded 340 relative to the second version 330₂ of the NN 10 encoded into the second portion 200₂ in terms of
weight and/or bias differences, i.e. differences between NN parameters associated with the first version 330₁ of the NN 10 and NN parameters associated with the second version 330₂ of the NN 10 as, for example, shown in FIG. 21, and/or
additional neurons or neuron interconnections as, for example, shown in FIG. 22.

According to an embodiment J3, of the DS of any previous embodiment J1 and J2, the individually accessible portions 200 are encoded using context-adaptive arithmetic coding and using context initialization at a start of each individually accessible portion 200 as, for example, shown in FIG. 8.

According to an embodiment J4, of the DS of any previous embodiment J1 to J3, the data stream 45 comprises for each individually accessible portion 200 as, for example, shown in one of FIGS. 11 to 15,
a start code 242 at which the respective individually accessible portion 200 begins, and/or
a pointer 220/244 pointing to a beginning of the respective individually accessible portion 200, and/or
a data stream length parameter indicating a data stream length 246 of the respective individually accessible portion 200 for skipping the respective individually accessible portion 200 in parsing the DS 45.

According to an embodiment J5, of the DS 45 of any previous embodiment J1 to J4, the data stream 45 comprises for each of one or more predetermined individually accessible portions 200 an identification parameter 310 for identifying the respective predetermined individually accessible portion 200 as, for example, shown in FIG. 19.

According to an embodiment J6, of the DS 45 of any of previous embodiment J1 to J5, the DS 45 is according to any previous embodiment A1 to I8.

### 6 AUGMENTATION DATA

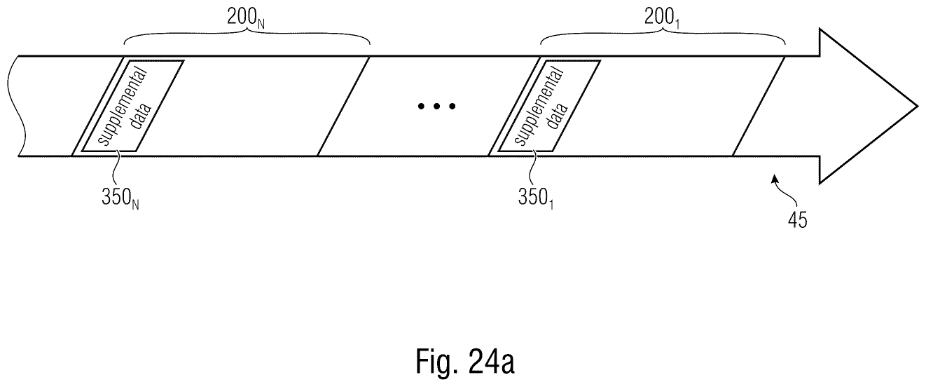

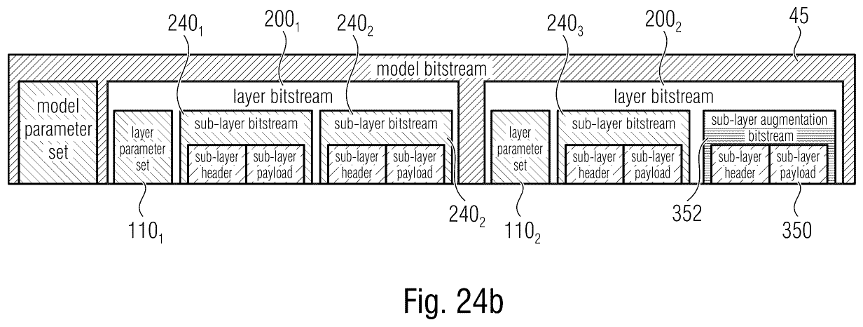

There exist application scenarios in which the parameter tensors 30 are accompanied by additional augmentation (or auxiliary/supplemental) data 350, as shown in FIGS. 24a and 24b. This augmentation data 350 is usually not necessary for decoding/reconstruction/inference of the NN, however, it can be essential from an application point of view. Examples may, for instance, be information regarding the relevance of each parameter 32 (Sebastian Lapuschkin, 2019), or regarding sufficient statistics of the parameter 32 such as intervals or variances that signal the robustness of each parameter 32 to perturbations (Christos Louizos, 2017).

Such augmentation information, i.e. supplemental data 350, can introduce a substantial amount of data with respect to the parameter tensors 30 of the NN, such that it is desirable to encode the augmentation data 350 using schemes such as DeepCABAC as well. However, it is important to mark this data as irrelevant for the decoding of the NN for the purpose of sole inference so that clients, which do not require the augmentation, are able to skip this part of the data.

In one embodiment, augmentation data 350 is carried in additional (sub-) layer augmentation bitstreams, i.e. further individually accessible portions 352, that are coded without dependency to the (sub-) layer bitstream data, e.g., without dependency to the individually accessible portions 200 and/or the individually accessible sub-portions 240, but interspersed with the respective (sub-) layer bitstreams to form the model bitstream, i.e. the data stream 45. FIGS. 24a and 24b illustrate the embodiment. FIG. 24b illustrates an Augmentation Bitstream 352.

FIGS. 24a and 24b show an embodiment K1, of a data stream 45 having a representation of a neural network encoded thereinto, wherein the data stream 45 is structured into individually accessible portions 200, each portion 200 representing a corresponding NN portion of the neural network, wherein the data stream 45 comprises for each of one or more predetermined individually accessible portions 200 a supplemental data 350 for supplementing the representation of the NN alternatively, as shown in FIG. 24b, the data stream 45 comprises for one or more predetermined individually accessible portions 200 the supplemental data 350 for supplementing the representation of the NN.

A corresponding embodiment ZK1, is related to an apparatus for encoding a representation of a neural network into the DS 45, so that the data stream 45 is structured into the individually accessible portions 200, each portion 200 representing a corresponding NN portion of the neural network, wherein the apparatus is configured to provide the data stream 45 with, for each of one or more predetermined individually accessible portions 200 the supplemental data 350 for supplementing the representation of the NN. Alternatively, the apparatus is configured to provide the data stream 45 with, for one or more predetermined individually accessible portions 200 the supplemental data 350 for supplementing the representation of the NN.

Another corresponding embodiment XK1, is related to an apparatus for decoding a representation of a neural network from the DS 45, wherein the data stream 45 is structured into the individually accessible portions 200, each portion 200 representing a corresponding NN portion of the neural network, wherein the apparatus is configured to decode from the data stream 45, for each of one or more predetermined individually accessible portions 200 the supplemental data 350 for supplementing the representation of the NN. Alternatively, the apparatus is configured to decode from the data stream 45, for one or more predetermined individually accessible portions 200 the supplemental data 350 for supplementing the representation of the NN.

In the following, different features and/or functionalities are described in the context of the data stream 45, but the features and/or functionalities can also, in the same way or in a similarly way, be features and/or functionalities of the apparatus, according to the embodiment ZK1, or of the apparatus, according to the embodiment XK1.

According to an embodiment K2, of the data stream 45 of embodiment K1, the DS 45 indicates the supplemental data 350 as being dispensable for inference based on the NN.

According to an embodiment K3, of the data stream 45 of any previous embodiment K1 and K2, the data stream 45 has the supplemental data 350 for supplementing the representation of the NN for the one or more predetermined individually accessible portions 200 coded into further individually accessible portions 352, as shown in FIG. 24b, so that the DS 45 comprises for one or more predetermined individually accessible portions 200, e.g. for each of the one or more predetermined individually accessible portions 200, a corresponding further predetermined individually accessible portion 352 relating to the NN portion to which the respective predetermined individually accessible portion 200 corresponds.

According to an embodiment K4, of the DS 45 of any previous embodiment K1 to K3, the NN portions comprise one or more NN layers of the NN and/or layer portions into which a predetermined NN layer of the NN is subdivided. According to FIG. 24b, for example, the individually accessible portion 200₂ and the corresponding further predetermined individually accessible portion 352 relate to a NN portion comprising one or more NN layers.

According to an embodiment K5, of the DS 45 of any previous embodiment K1 to K4, the individually accessible portions 200 are encoded using context-adaptive arithmetic coding and using context initialization at a start of each individually accessible portion 200 as, for example, shown in FIG. 8.

According to an embodiment K6, of the DS 45 of any previous embodiment K1 to K5, the data stream 45 comprises for each individually accessible portion 200 as, for example, shown in one of FIGS. 11 to 15,
a start code 242 at which the respective individually accessible portion 200 begins, and/or
a pointer 220/244 pointing to a beginning of the respective individually accessible portion 200, and/or
a data stream length parameter indicating a data stream length 246 of the respective individually accessible portion 200 for skipping the respective individually accessible portion 200 in parsing the DS 45.

According to an embodiment K7, of the DS 45 of any previous embodiment K1 to K6, the supplemental data 350 relates to
relevance scores of NN parameters, and/or
perturbation robustness of NN parameters.

According to an embodiment K8, of the DS 45 of any of previous embodiments K1 to K7, the DS 45 is according to any previous embodiment A1 to J6.

### 7 EXTENDED CONTROL DATA

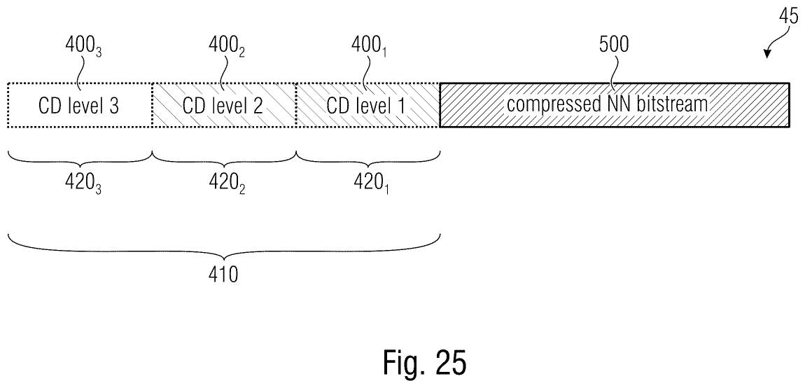

Besides the described functionalities of different access functionalities, an extended hierarchical control data structure, i.e. a sequence 410 of control data portions 420, may be useful for different application and usage scenarios. On one hand, the compressed NN representation (or bitstream) may be used from inside a specific framework, such as TensorFlow or Pytorch, in which case only a minimum of control data 400 may be used, e.g. to decode the deepCABAC-encoded parameter tensors. On the other hand, the specific type of framework might not be known to the decoder, in which case additional control data 400 may be used. Thus, depending on the use case and its knowledge of environment, different levels of control data 400 may be useful, as shown in FIG. 25.

FIG. 25 shows a Hierarchical Control Data (CD) Structure, i.e. the sequence 410 of control data portions 420, for compressed neural networks, where different CD levels, i.e. control data portions 420, e.g. the dotted boxes, are present or absent, depending on the usage environments. In FIG. 25, the compressed bitstream, e.g. comprising a representation 500 of a neural network, may be any of the above model bitstream types, e.g. including all compressed data of a network with or without subdivision into sub-bitstreams.

Accordingly, if a specific network (e.g. TensorFlow, Pytorch, Keras, etc.) with type and architecture known to decoder and encoder included compressed NN technology, only the Compressed NN Bitsream may be used. However, if a decoder is unaware of any encoder setting, the full set of Control data, i.e. the complete sequence 410 of control data portions 420, may be used in addition to allow full network reconstruction.

Examples of different hierarchical control data layers, i.e. control data portions 420, are:
CD Level 1: Compressed Data Decoder Control information.
CD Level 2: Specific syntax elements from the respective frameworks (Tensor Flow, Pytorch, Keras)
CD Level 3: Inter-Framework format elements, such as ONNX (ONNX=Open Neural Network Exchange) for usage in different frameworks
CD Level 4: Information regarding the networks topology.
CD Level 5: Full network parameter information (for full reconstruction without any knowledge regarding the networks topology)

Accordingly, this embodiment would describe a hierarchical control data structure of N levels, i.e. N control data portions 420, where 0 to N level may be present to allow for different usage modes ranging from specific compression-only core data usage up to fully self-contained network reconstruction. Levels, i.e. control data portions 420, may even contain syntax from existing network architectures and frameworks.

In another embodiment different levels, i.e. control data portions 420, may entail information about the neural network at different granularity. For instance, the level structure may be composed in the following manner:
CD Level 1: Entails information regarding the parameters of the network. E.g., type, dimensions, etc.
CD Level 2: Entails information regarding the layers of the network. E.g., type, identification, etc.
CD Level 3: Entails information regarding the topology of the network. E.g., connectivity between layers.
CD Level 4: Entails information regarding the neural network model. E.g., version, training parameters, performance, etc.
CD Level 5: Entails information regarding the data set it was trained and validated on. E.g., 227×227 resolution input natural images with 1000 labelled categories, etc.

FIG. 25 shows an embodiment L1, of a data stream 45 having a representation 500 of a neural network encoded thereinto, wherein the data stream 45 comprises hierarchical control data 400 structured into a sequence 410 of control data portions 420, wherein the control data portions 420 provide information on the NN at increasing details along the sequence 410 of control data portions 420. Second hierarchical control data 400₂ of a second control data portion 420₂ might comprise information with more details than first hierarchical control data 400₁ of a first control data portion 420₁.

According to an embodiment, the control data portions 420 might represent different units, which may contain additional topology information.

A corresponding embodiment ZL1, is related to an apparatus for encoding the representation 500 of a neural network into the DS 45, wherein the apparatus is configured to provide the data stream 45 with the hierarchical control data 400 structured into the sequence 410 of control data portions 420, wherein the control data portions 420 provide information on the NN at increasing details along the sequence 410 of control data portions 420.

Another corresponding embodiment XL1, relates to an apparatus for decoding the representation 500 of a neural network from the DS 45, wherein the apparatus is configured to decode from the data stream 45 the hierarchical control data 400 structured into the sequence 410 of control data portions 420, wherein the control data portions 420 provide information on the NN at increasing details along the sequence 410 of control data portions 420.

In the following, different features and/or functionalities are described in the context of the data stream 45, but the features and/or functionalities can also, in the same way or in a similarly way, be features and/or functionalities of the apparatus, according to the embodiment ZL1, or of the apparatus, according to the embodiment XL1.

According to an embodiment L2, of the data stream 45 of embodiment L1, at least some of the control data portions 420 provide information on the NN, which is partially redundant.

According to an embodiment L3, of the data stream 45 of embodiment L1 or L2, a first control data portion 420₁ provides the information on the NN by way of indicating a default NN type implying default settings and a second control data portion 420₂ comprises a parameter to indicate each of the default settings.

According to an embodiment L4, of the DS 45 of any of previous embodiments L1 to L3, the DS 45 is according to any previous embodiment A1 to K8.

An embodiment X1, relates to an apparatus for decoding a data stream 45 according to any previous embodiment, configured to derive from the data stream 45 a NN 10, e.g., according to any of above embodiments XA1 to XL1, e.g. further configured to encode/decode such that the DS 45 is according to any of previous embodiments.

This apparatus, for instance,
searches for start codes 242 and/or
skips individually accessible portions 200 using data stream length 45 parameter and/or
uses pointers 220/244 to resume parsing the data stream 45 at beginnings of individually accessible portions 200, and/or
associates decoded NN parameters 32′ to neurons 14, 18, 20 or neuron interconnections 22/24 according to the coding order 104, and/or
performs the context adaptive arithmetic decoding and context initializations, and/or
performs the dequantization/value reconstruction 280 and/or
performs the summation of exponents to compute quantization step size 263, and/or
performs a look-up in the quantization-index-to-reconstruction-level mapping 265 responsive to a quantization index 32″ leaving the predetermined index interval 268 such as assuming the escape code, and/or
performs hashing on or apply error detection/correction code onto a certain individually accessible portion 200 and compare the result with its corresponding identification parameter 310 so as to check a correctness of the individually accessible portion 200, and/or
reconstructs a certain version 330 of the NN 10 by performing adding weight and/or bias differences to an underlying NN version 330 and/or adding the additional neurons 14, 18, 20 or neuron interconnections 22/24 to the underlying NN version 330, or performing the joint execution of the one or more compensating NN portions and the corresponding NN portion along with performing the summation of the outputs thereof, and/or
sequentially reads the control data portions 420 with stopping reading as soon as a currently read control data portion 420 assumes a parameter state known to the apparatus and providing information, i.e. hierarchical control data 400, at a details sufficient to conform to a predetermined degree of detail.

An embodiment Y1 is related to an apparatus for performing an inference using a NN 10, comprising an apparatus for decoding a data stream 45 according to embodiment X1, so as to derive from the data stream 45 the NN 10, and a processor configured to perform the inference based on the NN 10.

An embodiment Z1 is related to an apparatus for encoding a data stream 45 according to any previous embodiment, e.g., according to any of above embodiments ZA1 to ZL1, e.g. further configured to encode/decode such that the DS 45 is according to any of previous embodiments.

This apparatus, for instance, selects the coding order 104 to find an optimum one for an optimum compression efficiency.

An embodiment U relates to methods performed by any of the apparatuses of embodiments XA1 to XL1 or ZA1 to ZL1.

An embodiment W relates to a computer program for, when executed by a computer, causing the computer to perform the method of embodiment U.

### Embodiments

Embodiments of the invention also include the following:

1. Data stream (45) having a representation of a neural network (10) encoded thereinto, the data stream (45) comprising serialization parameter (102) indicating a coding order (104) at which neural network parameters (32), which define neuron interconnections (22, 24) of the neural network (10), are encoded into the data stream (45).

2. Data stream (45) of embodiment 1, wherein the neural network parameters (32) are coded into the data stream (45) using context-adaptive arithmetic coding (600).

3. Data stream (45) of embodiment 1 or embodiment 2, wherein the data stream (45) is structured into one or more individually accessible portions (200), each individually accessible portion (200) representing a corresponding neural network layer (210, 30) of the neural network (10), wherein the serialization parameter (102) indicates the coding order (104) at which neural network parameters, which define neuron interconnections (22, 24) of the neural network within a predetermined neural network layer (210, 30), are encoded into the data stream (45).

4. Data stream (45) of any previous embodiment 1 to 3, wherein the serialization parameter (102) is an n-ary parameter which indicates the coding order (104) out of a set (108) of n coding orders (104).

5. Data stream (45) of embodiment 4, wherein the set (108) of n coding orders (104) comprises first predetermined coding orders (106i) which differ in an order at which the predetermined coding orders traverse dimensions (34) of a tensor (30) describing a predetermined neural network layer (210, 30) of the neural network (10); and/or second predetermined coding orders (106₂) which differ in a number (107) of times at which the predetermined coding orders traverse a predetermined neural network layer (210, 30) of the neural network for sake of scalable coding of the neural network; and/or third predetermined coding orders (106₃) which differ in an order at which the predetermined coding orders traverse neural network layers (210, 30) of the neural network; and/or and/or fourth predetermined coding orders (106₄) which differ in an order at which neurons (14, 18, 20) of a neural network layer (210, 30) of the neural network are traversed.

6. Data stream (45) of any previous embodiment 1 to 5, wherein the serialization parameter (102) is indicative of a permutation using which the coding order (104) permutes neurons (14, 18, 20) of a neural network layer (210, 30) relative to a default order.

7. Data stream (45) of embodiment 6, wherein the permutation orders the neurons (14, 18, 20) of the neural network layer (210, 30) in a manner so that the neural network parameters (32) monotonically increase along the coding order (104) or monotonically decrease along the coding order (104).

8. Data stream (45) of embodiment 6, wherein the permutation orders the neurons (14, 18, 20) of the neural network layer (210, 30) in a manner so that, among predetermined coding orders signalable by the serialization parameter (102), a bitrate for coding the neural network parameters (32) into the data stream (45) is lowest for the permutation indicated by the serialization parameter (102).

9. Data stream (45) of any previous embodiment 1 to 8, wherein the neural network parameters (32) comprise weights and biases.

10. Data stream (45) of any previous embodiment 1 to 9, wherein the data stream (45) is structured into individually accessible sub-portions (43, 44, 240), each sub-portion (43, 44, 240) representing a corresponding neural network portion of the neural network (10), so that each sub-portion (43, 44, 240) is completely traversed by the coding order (104) before a subsequent sub-portion is traversed by the coding order (104).

11. Data stream (45) of any of embodiments 3 to 10, wherein the neural network parameters (32) are coded into the data stream (45) using context-adaptive arithmetic coding (600) and using context initialization at a start of any individually accessible portion (200) or subportion (43, 44, 240).

12. Data stream (45) of any of embodiments 3 to 11, wherein the data stream (45) comprises start codes (242) at which each individually accessible portion (200) or sub-portion (43, 44, 240) begins, and/or pointers (220, 244) pointing to beginnings of each individually accessible portion or sub-portion, and/or pointers data stream lengths (246) of each individually accessible portion or sub-portion for skipping the respective individually accessible portion or sub-portion in parsing the data stream (45).

13. Data stream (45) of any of the previous embodiments 1 to 12, further comprising a numerical computation representation parameter (120) indicating a numerical representation and bit size at which the neural network parameters (32) are to be represented when using the neural network (10) for inference.

14. Data stream (45) having a representation of a neural network (10) encoded thereinto, the data stream (45) comprising a numerical computation representation parameter (120) indicating a numerical representation and bit size at which neural network parameters (32) of the neural network, which are encoded into the data stream, are to be represented when using the neural network (10) for inference.

15. Data stream (45) of any of the previous embodiments 1 to 14, wherein the data stream (45) is structured into individually accessible sub-portions (43, 44, 240), each individually accessible sub-portion representing a corresponding neural network portion of the neural network, so that each individually accessible sub-portion is completely traversed by the coding order (104) before a subsequent individually accessible sub-portion is traversed by the coding order (104), wherein the data stream (45) comprises for a predetermined individually accessible sub-portion a type parameter indicting a parameter type of the neural network parameter (32) encoded into the predetermined individually accessible sub-portion.

16. Data stream (45) of embodiment 15, wherein the type parameter discriminates, at least, between neural network weights and neural network biases.

17. Data stream (45) of any of the previous embodiments 1 to 16, wherein the data stream (45) is structured into one or more individually accessible portions (200), each individually accessible portion representing a corresponding neural network layer (210, 30) of the neural network, wherein the data stream (45) further comprises for a predetermined neural network layer a neural network layer type parameter (130) indicating a neural network layer type of the predetermined neural network layer of the neural network.

18. Data stream (45) having a representation of a neural network (10) encoded thereinto, wherein the data stream (45) is structured into one or more individually accessible portions (200), each individually accessible portion representing a corresponding neural network layer (210, 30) of the neural network, wherein the data stream (45) further comprises, for a predetermined neural network layer, a neural network layer type parameter (130) indicating a neural network layer type of the predetermined neural network layer of the neural network.

19. Data stream (45) of any of embodiments 17 and 18, wherein the neural network layer type parameter (130) discriminates, at least, between a fully-connected and a convolutional layer type.

20. Data stream (45) of any of the previous embodiments 1 to 19, wherein the data stream (45) is structured into individually accessible portions (200), each individually accessible portion representing a corresponding neural network portion of the neural network, wherein the data stream (45) comprises for each of one or more predetermined individually accessible portions (200) a pointer (220, 244) pointing to a beginning of each individually accessible portion.

21. Data stream (45) having a representation of a neural network (10) encoded thereinto, wherein the data stream (45) is structured into individually accessible portions (200), each individually accessible portion representing a corresponding neural network portion of the neural network, wherein the data stream (45) comprises for each of one or more predetermined individually accessible portions (200) a pointer (220, 244) pointing to a beginning of the respective predetermined individually accessible portion.

22. Data stream (45) of any of previous embodiments 20 and 21, wherein each individually accessible portion represents a corresponding neural network layer (210) of the neural network or a neural network portion (43, 44, 240) of a neural network layer (210) of the neural network.

23. Data stream (45) of any of embodiments 1 to 22, having a representation of a neural network (10) encoded thereinto, wherein the data stream (45) is structured into one or more individually accessible portions (200), each individually accessible portion representing a corresponding neural network layer (210, 30) of the neural network, wherein the data stream (45) is, within a predetermined portion, further structured into individually accessible sub-portions (43, 44, 240), each sub-portion (43, 44, 240) representing a corresponding neural network portion of the respective neural network layer (210, 30) of the neural network, wherein the data stream (45) comprises for each of one or more predetermined individually accessible sub-portions (43, 44, 240) a start code (242) at which the respective predetermined individually accessible sub-portion begins, and/or a pointer (244) pointing to a beginning of the respective predetermined individually accessible sub-portion, and/or a data stream length parameter indicating a data stream length (246) of the respective predetermined individually accessible sub-portion for skipping the respective predetermined individually accessible sub-portion in parsing the data stream (45).

24. Data stream (45) of embodiment 23, wherein the data stream (45) has the representation of the neural network encoded thereinto using context-adaptive arithmetic coding (600) and using context initialization at a start of each individually accessible portion and each individually accessible sub-portion.

25. Data stream (45) having a representation of a neural network (10) encoded thereinto, wherein the data stream (45) is structured into one or more individually accessible portions (200), each individually accessible portion representing a corresponding neural network layer (210, 30) of the neural network, wherein the data stream (45) is, within a predetermined portion, further structured into individually accessible sub-portions (43, 44, 240), each sub-portion (43, 44, 240) representing a corresponding neural network portion of the respective neural network layer (210, 30) of the neural network, wherein the data stream (45) comprises for each of one or more predetermined individually accessible sub-portions (43, 44, 240) a start code (242) at which the respective predetermined individually accessible subportion begins, and/or a pointer (244) pointing to a beginning of the respective predetermined individually accessible sub-portion, and/or a data stream length parameter indicating a data stream length (246) of the respective predetermined individually accessible sub-portion for skipping the respective predetermined individually accessible sub-portion in parsing the data stream (45).

26. Data stream (45) of embodiment 25, wherein the data stream (45) has the representation of the neural network encoded thereinto using context-adaptive arithmetic coding (600) and using context initialization at a start of each individually accessible portion and each individually accessible sub-portion.

27. Data stream (45) of any previous embodiment 1 to 26, wherein the data stream (45) is structured into individually accessible portions (200), each individually accessible portion representing a corresponding neural network portion of the neural network, wherein the data stream (45) comprises for each of one or more predetermined individually accessible portions (200) a processing option parameter (250) indicating one or more processing options (252) which have to be used or which may optionally be used when using the neural network (10) for inference.

28. Data stream (45) of embodiment 27, wherein the processing option parameter (250) indicates the one or more available processing options (252) out of a set of predetermined processing options (252) including parallel processing capability of the respective predetermined individually accessible portion; and/or sample wise parallel processing capability (252₂) of the respective predetermined individually accessible portion; and/or channel wise parallel processing capability (252i) of the respective predetermined individually accessible portion; and/or classification category wise parallel processing capability of the respective predetermined individually accessible portion; and/or dependency of the neural network portion represented by the respective predetermined individually accessible portion on a computation result gained from another individually accessibly portion of the data stream (45) relating to the same neural network portion but belonging to another version of versions (330) of the neural network which are encoded into the data stream (45) in a layered manner.

29. Data stream (45) having a representation of a neural network (10) encoded thereinto, wherein the data stream (45) is structured into individually accessible portions (200), each individually accessible portion representing a corresponding neural network portion of the neural network, wherein the data stream (45) comprises for each of one or more predetermined individually accessible portions (200) a processing option parameter (250) indicating one or more processing options (252) which have to be used or which may optionally be used when using the neural network (10) for inference.

30. Data stream (45) of embodiment 29, wherein the processing option parameter (250) indicates the one or more available processing options (252) out of a set of predetermined processing options (252) including parallel processing capability of the respective predetermined individually accessible portion; and/or sample wise parallel processing capability (252₂) of the respective predetermined individually accessible portion; and/or channel wise parallel processing capability (252i) of the respective predetermined individually accessible portion; and/or classification category wise parallel processing capability of the respective predetermined individually accessible portion; and/or dependency of the neural network portion represented by the respective predetermined individually accessible portion on a computation result gained from another individually accessibly portion of the data stream (45) relating to the same neural network portion but belonging to another version of versions (330) of the neural network which are encoded into the data stream (45) in a layered manner.

31. Data stream (45) of one of embodiments 1 to 30, having neural network parameters (32) encoded thereinto, which represent a neural network, wherein the neural network parameters (32) are encoded into the data stream (45) in a manner quantized (260) onto quantization indices (32″), and wherein the neural network parameters (32) are encoded into the data stream (45) so that neural network parameters (32) in different neural network portions of the neural network are quantized (260) differently, and the data stream (45) indicates, for each of the neural network portions, a reconstruction rule (270) for dequantizing neural network parameters (32) relating to the respective neural network portion.

32. Data stream (45) having neural network parameters (32) encoded thereinto, which represent a neural network, wherein the neural network parameters (32) are encoded into the data stream (45) in a manner quantized (260) onto quantization indices (32″), and wherein the neural network parameters (32) are encoded into the data stream (45) so that neural network parameters (32) in different neural network portions of the neural network are quantized (260) differently, and the data stream (45) indicates, for each of the neural network portions, a reconstruction rule (270) for dequantizing neural network parameters (32) relating to the respective neural network portion.

33. Data stream (45) of embodiment 31 or embodiment 32, wherein the neural network portions comprise neural network layers (210, 30) of the neural network and/or layer portions into which a predetermined neural network layer (210, 30) of the neural network is subdivided.

34. Data stream (45) of any previous embodiment 31 to 33, wherein the data stream (45) has a first reconstruction rule (270₁, 270a₁) for dequantizing neural network parameters (32) relating to a first neural network portion encoded thereinto in a manner delta-coded relative to a second reconstruction rule (270₂, 270a₂) for dequantizing neural network parameters (32) relating to a second neural network portion.

35. Data stream (45) of embodiment 34, wherein the data stream (45) comprises, for indicating the first reconstruction rule (270₁, 270a₁), a first exponent value and, for indicating the second reconstruction rule (270₂, 270a₂), a second exponent value, the first reconstruction rule (270₁, 270a₁) is defined by a first quantization step size defined by an exponentiation of a predetermined basis and a first exponent defined by the first exponent value, and the second reconstruction rule (270₂, PO&2) is defined by a second quantization step size defined by an exponentiation of the predetermined basis and a second exponent defined by a sum over the first and second exponent values.

36. Data stream (45) of embodiment 35, wherein the data stream (45) further indicates the predetermined basis.

37. Data stream (45) of any previous embodiment 31 to 34, wherein the data stream (45) comprises, for indicating a first reconstruction rule (270₁, 270a₁) for dequantizing neural network parameters (32) relating to a first neural network portion, a first exponent value and, for indicating a second reconstruction rule (270₂, 270a₂) for dequantizing neural network parameters (32) relating to a second neural network portion, a second exponent value, the first reconstruction rule (270₁, 270a₁) is defined by a first quantization step size defined by an exponentiation of a predetermined basis and a first exponent defined by a sum over the first exponent value and a predetermined exponent value, and the second reconstruction rule (2702, 270az) is defined by a second quantization step size defined by an exponentiation of the predetermined basis and a second exponent defined by a sum over the second exponent values and the predetermined exponent value.

38. Data stream (45) of embodiment 37, wherein the data stream (45) further indicates the predetermined basis.

39. Data stream (45) of embodiment 38, wherein the data stream (45) indicates the predetermined basis at a neural network scope.

40. Data stream (45) of any previous embodiment 37 to 39, wherein the data stream (45) further indicates the predetermined exponent value.

41. Data stream (45) of embodiment 40, wherein the data stream (45) indicates the predetermined exponent value at a neural network layer (210, 30) scope.

42. Data stream (45) of embodiment 40 or embodiment 41, wherein the data stream (45) further indicates the predetermined basis and the data stream (45) indicates the predetermined exponent value at a scope finer than a scope at which the predetermined basis is indicated by the data stream (45).

43. Data stream (45) of any of previous embodiments 35 to 42, wherein the data stream (45) has the predetermined basis encoded thereinto in a non-integer format and the first and second exponent values in integer format.

44. Data stream (45) of any of embodiments 34 to 43, wherein the data stream (45) comprises, for indicating the first reconstruction rule (270₁, 270a₁), a first parameter set (264) defining a first quantization-index-to-reconstruction-level mapping (265), and for indicating the second reconstruction rule (270₂, 270a₂), a second parameter set (264) defining a second quantization-index-to-reconstruction-level mapping (265), the first reconstruction rule (270₁, 270a₁) is defined by the first quantization-index-to-reconstruction-level mapping (265), and the second reconstruction rule (270₂, 270a₂) is defined by an extension of the first quantization-index-to-reconstruction-level mapping (265) by the second quantization-index-to-reconstruction-level mapping (265) in a predetermined manner.

45. Data stream (45) of any of embodiments 34 to 44, wherein the data stream (45) comprises, for indicating the first reconstruction rule (270₁, 270a₁), a first parameter set (264) defining a first quantization-index-to-reconstruction-level mapping (265), and for indicating the second reconstruction rule (270₂, 270a₂), a second parameter set (264) defining a second quantization-index-to-reconstruction-level mapping (265), the first reconstruction rule (270₁, 270a₁) is defined by an extension of a predetermined quantization-index-to-reconstruction-level mapping (265) by the first quantization-index-to-reconstruction-level mapping (265) in a predetermined manner, and the second reconstruction rule (270₂, 270a₂) is defined by an extension of the predetermined quantization-index-to-reconstruction-level mapping (265) by the second quantization-index-to-reconstruction-level mapping (265) in the predetermined manner.

46. Data stream (45) of embodiment 45, wherein the data stream (45) further indicates the predetermined quantization-index-to-reconstruction-level mapping (265).

47. Data stream (45) of embodiment 46, wherein the data stream (45) indicates the predetermined quantization-index-to-reconstruction-level mapping (265) at a neural network scope or at a neural network layer (210, 30) scope.

48. Data stream (45) of any of previous embodiments 44 to 47, wherein, according to the predetermined manner, a mapping of each index value (32″), according to the quantization-index-to-reconstruction-level mapping to be extended, onto a first reconstruction level is superseded by, if present, a mapping of the respective index value (32″), according to the quantization-index-to-reconstruction-level mapping extending the quantization-index-to-reconstruction-level mapping to be extended, onto a second reconstruction level, and/or for any index value (32″), for which according to the quantization-index-to-reconstruction-level mapping to be extended, no reconstruction level is defined onto which the respective index value (32″) should be mapped, and which is, according to the quantization-index-to-reconstruction-level mapping extending the quantization-index-to-reconstruction-level mapping to be extended, mapped onto a corresponding reconstruction level, the mapping from the respective index value (32″) onto the corresponding reconstruction level is adopted, and/or for any index value (32″), for which according to the quantization-index-to-reconstruction-level mapping extending the quantization-index-to-reconstruction-level mapping to be extended, no reconstruction level is defined onto which the respective index value (32″) should be mapped, and which is, according to the quantization-index-to-reconstruction-level mapping to be extended, mapped onto a corresponding reconstruction level, the mapping from the respective index value (32″) onto the corresponding reconstruction level is adopted.

49. Data stream (45) of any previous embodiment 31 to 48, wherein the data stream (45) comprises, for indicating the reconstruction rule (270) of a predetermined neural network portion, a quantization step size parameter (262) indicating a quantization step size (263), and a parameter set (264) defining a quantization-index-to-reconstruction-level mapping (265), wherein the reconstruction rule (270) of the predetermined neural network portion is defined by the quantization step size (263) for quantization indices (32″) within a predetermined index interval (268), and the quantization-index-to-reconstruction-level mapping (265) for quantization indices (32″) outside the predetermined index interval (268).

50. Data stream (45) having neural network parameters (32) encoded thereinto, which represent a neural network, wherein the neural network parameters (32) are encoded into the data stream (45) in a manner quantized (260) onto quantization indices (32″), wherein the data stream (45) comprises, for indicating a reconstruction rule (270) for dequantizing (280) the neural network parameters (32), a quantization step size parameter (262) indicating a quantization step size (263), and a parameter set (264) defining a quantization-index-to-reconstruction-level mapping (265), wherein the reconstruction rule (270) of the predetermined neural network portion is defined by the quantization step size (263) for quantization indices (32″) within a predetermined index interval (268), and the quantization-index-to-reconstruction-level mapping (265) for quantization indices (32″) outside the predetermined index interval (268).

51. Data stream (45) of embodiment 49 or embodiment 50, wherein the predetermined index interval (268) includes zero.

52. Data stream (45) of embodiment 51, wherein the predetermined index interval (268) extends up to a predetermined magnitude threshold value and quantization indices (32″) exceeding the predetermined magnitude threshold value represent escape codes which signal that the quantization-index-to-reconstruction-level mapping (265) is to be used for dequantization (280).

53. Data stream (45) of any of previous embodiments 49 to 52, wherein the parameter set (264) defines the quantization-index-to-reconstruction-level mapping (265) by way of a list of reconstruction levels associated with quantization indices (32″) outside the predetermined index interval (268).

54. Data stream (45) of any of previous embodiments 31 to 53, wherein the neural network portions comprise one or more sub-portions of a neural network layer (210, 30) of the neural network and/or one or more neural network layers of the neural network.

55. Data stream (45) of any of previous embodiments 31 to 54, wherein the data stream (45) is structured into individually accessible portions (200), each individually accessible portion having the neural network parameters (32) for a corresponding neural network portion encoded thereinto.

56. Data stream (45) of embodiment 55, wherein the individually accessible portions (200) are encoded using context-adaptive arithmetic coding (600) and using context initialization at a start of each individually accessible portion.

57. Data stream (45) of embodiment 55 or embodiment 56, wherein the data stream (45) comprises for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream (45).

58. Data stream (45) of any previous embodiment 55 to 57, wherein the data stream (45) indicates, for each of the neural network portions, the reconstruction rule (270) for dequantizing (280) neural network parameters (32) relating to the respective neural network portion in a main header portion (47) of the data stream (45) relating the neural network as a whole, a neural network layer (210, 30) related header portion (110) of the data stream (45) relating to the neural network layer (210) the respective neural network portion is part of, or a neural network portion specific header portion of the data stream (45) relating to the respective neural network portion is part of.

59. Data stream (45) of any previous embodiment 1 to 58, having a representation of a neural network (10) encoded thereinto, wherein the data stream (45) is structured into individually accessible portions (200), each portion representing a corresponding neural network portion of the neural network, wherein the data stream (45) comprises for each of one or more predetermined individually accessible portions (200) an identification parameter (310) for identifying the respective predetermined individually accessible portion.

60. Data stream (45) having a representation of a neural network (10) encoded thereinto, wherein the data stream (45) is structured into individually accessible portions (200), each portion representing a corresponding neural network portion of the neural network, wherein the data stream (45) comprises for each of one or more predetermined individually accessible portions (200) an identification parameter (310) for identifying the respective predetermined individually accessible portion.

61. Data stream (45) of embodiment 59 or embodiment 60, wherein the identification parameter (310) is related to the respective predetermined individually accessible portion via a hash function or error detection code or error correction code.

62. Data stream (45) of any of previous embodiments 59 to 61, further comprising a higher-level identification parameter (310) for identifying a collection of more than one predetermined individually accessible portion.

63. Data stream (45) of embodiment 62, wherein the higher-level identification parameter (310) is related to the identification parameters (310) of the more than one predetermined individually accessible portion via a hash function or error detection code or error correction code.

64. Data stream (45) of any of previous embodiments 59 to 63, wherein the individually accessible portions (200) are encoded using context-adaptive arithmetic coding (600) and using context initialization at a start of each individually accessible portion.

65. Data stream (45) of any of previous embodiments 59 to 64, wherein the data stream (45) comprises for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

66. Data stream (45) of any of previous embodiments 59 to 65, wherein the neural network portions comprise one or more sub-portions of a neural network layer (210, 30) of the neural network and/or one or more neural network layers of the neural network.

67. Data stream (45) of any previous embodiment 1 to 66, having a representation of a neural network (10) encoded thereinto in a layered manner so that different versions (330) of the neural network are encoded into the data stream (45), wherein the data stream (45) is structured into one or more individually accessible portions (200), each portion relating to a corresponding version (330) of the neural network, wherein the data stream (45) has a first version (330₂) of the neural network encoded into a first portion delta-coded relative to a second version (330t) of the neural network encoded into a second portion, and/or in form of one or more compensating neural network portions (332) each of which is to be, for performing an inference based on the first version (SSCfe) of the neural network, executed in addition to an execution of a corresponding neural network portion (334) of a second version (330i) of the neural network encoded into a second portion, and wherein outputs of the respective compensating neural network portion (332) and corresponding neural network portion (334) are to be summed up.

68. Data stream (45) having a representation of a neural network (10) encoded thereinto in a layered manner so that different versions (330) of the neural network are encoded into the data stream (45), wherein the data stream (45) is structured into one or more individually accessible portions (200), each portion relating to a corresponding version of the neural network, wherein the data stream (45) has a first version (SSCfe) of the neural network encoded into a first portion delta-coded relative to a second version (330i) of the neural network encoded into a second portion, and/or in form of one or more compensating neural network portions (332) each of which is to be, for performing an inference based on the first version (330₂) of the neural network, executed in addition to an execution of a corresponding neural network portion (334) of a second version (330i) of the neural network encoded into a second portion, and wherein outputs of the respective compensating neural network portion (332) and corresponding neural network portion (334) are to be summed up.

69. Data stream (45) of embodiment 67 or embodiment 68, wherein the data stream (45) has the first version (330₂) of the neural network encoded into a first portion delta-coded relative to the second version (330i) of the neural network encoded into the second portion in terms of weight and/or bias differences, and/or additional neurons (14, 18, 20) or neuron interconnections (22, 24).

70. Data stream (45) of any previous embodiment 67 to 69, wherein the individually accessible portions (200) are encoded using context-adaptive arithmetic coding (600) and using context initialization at a start of each individually accessible portion.

71. Data stream (45) of any previous embodiment 67 to 70, wherein the data stream (45) comprises for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream (45).

72. Data stream (45) of any previous embodiment 67 to 71, wherein the data stream (45) comprises for each of one or more predetermined individually accessible portions (200) an identification parameter (310) for identifying the respective predetermined individually accessible portion.

73. Data stream (45) of any previous embodiment 1 to 72, having a representation of a neural network (10) encoded thereinto, wherein the data stream (45) is structured into individually accessible portions (200), each portion representing a corresponding neural network portion of the neural network, wherein the data stream (45) comprises for each of one or more predetermined individually accessible portions (200) a supplemental data (350) for supplementing the representation of the neural network.

74. Data stream (45) having a representation of a neural network (10) encoded thereinto, wherein the data stream (45) is structured into individually accessible portions (200), each portion representing a corresponding neural network portion of the neural network, wherein the data stream (45) comprises for each of one or more predetermined individually accessible portions (200) a supplemental data (350) for supplementing the representation of the neural network.

75. Data stream (45) of embodiment 73 or embodiment 74, wherein the data stream (45) indicates the supplemental data (350) as being dispensable for inference based on the neural network.

76. Data stream (45) of any previous embodiment 73 to 75, wherein the data stream (45) has the supplemental data (350) for supplementing the representation of the neural network for the one or more predetermined individually accessible portions (200) coded into further individually accessible portions (200) so that the data stream (45) comprises for each of the one or more predetermined individually accessible portions (200) a corresponding further predetermined individually accessible portion relating to the neural network portion to which the respective predetermined individually accessible portion corresponds.

77. Data stream (45) of any previous embodiment 73 to 76, wherein the neural network portions comprise neural network layers (210, 30) of the neural network and/or layer portions into which a predetermined neural network layer of the neural network is subdivided.

78. Data stream (45) of any previous embodiment 73 to 77, wherein the individually accessible portions (200) are encoded using context-adaptive arithmetic coding (600) and using context initialization at a start of each individually accessible portion.

79. Data stream (45) of any previous embodiment 73 to 78, wherein the data stream (45) comprises for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream (45).

80. Data stream (45) of any previous embodiment 73 to 79, wherein the supplemental data (350) relates to relevance scores of neural network parameters (32), and/or perturbation robustness of neural network parameters (32).

81. Data stream (45) of any previous embodiment 1 to 80, having a representation of a neural network (10) encoded thereinto, wherein the data stream (45) comprises hierarchical control data (400) structured into a sequence (410) of control data portions (420), wherein the control data portions (420) provide information on the neural network at increasing details along the sequence of control data portions (420).

82. Data stream (45) having a representation of a neural network (10) encoded thereinto, wherein the data stream (45) comprises hierarchical control data (400) structured into a sequence (410) of control data portions (420), wherein the control data portions (420) provide information on the neural network at increasing details along the sequence of control data portions (420).

83. Data stream (45) of embodiment 81 or embodiment 82, wherein at least some of the control data portions (420) provide information on the neural network which is partially redundant.

84. Data stream (45) of any previous embodiment 81 to 83, wherein a first control data portion provides the information on the neural network by way of indicating a default neural network type implying default settings and a second control data portion comprises a parameter to indicate each of the default settings.

85. Apparatus for encoding a representation of a neural network (10) into a data stream (45), wherein the apparatus is configured to provide the data stream (45) with a serialization parameter (102) indicating a coding order (104) at which neural network parameters (32), which define neuron interconnections (22, 24) of the neural network, are encoded into the data stream (45).

86. Apparatus of embodiment 85, wherein the apparatus is configured to encode, into the data stream (45), the neural network parameters (32) using context-adaptive arithmetic encoding.

87. Apparatus of embodiment 85 or embodiment 86, wherein the apparatus is configured to structure the data stream (45) into one or more individually accessible portions (200), each individually accessible portion representing a corresponding neural network layer (210, 30) of the neural network, and encode, into the data stream (45), neural network parameters, which define neuron interconnections (22, 24) of the neural network within a predetermined neural network layer, according to the coding order (104) to be indicated by the serialization parameter (102).

88. Apparatus of any previous embodiment 85 to 87, wherein the serialization parameter (102) is an n-ary parameter which indicates the coding order (104) out of a set (108) of n coding orders (104).

89. Apparatus of embodiment 88, wherein the set (108) of n coding orders (104) comprises first predetermined coding orders (106i) which differ in an order at which the predetermined coding orders traverse dimensions (34) of a tensor (30) describing a predetermined neural network layer (210, 30) of the neural network; and/or second predetermined coding orders (106₂) which differ in a number (107) of times at which the predetermined coding orders traverse a predetermined neural network layer of the neural network for sake of scalable coding of the neural network; and/or third predetermined coding orders (106₃) which differ in an order at which the predetermined coding orders traverse neural network layers of the neural network; and/or fourth predetermined coding orders (106₄) which differ in an order at which neurons (14, 18, 20) of a neural network layer (210, 30) of the neural network are traversed.

90. Apparatus of any previous embodiment 85 to 89, wherein the serialization parameter (102) is indicative of a permutation using which the coding order (104) permutes neurons (14, 18, 20) of a neural network layer (210, 30) relative to a default order.

91. Apparatus of embodiment 90, wherein the permutation orders the neurons (14, 18, 20) of the neural network layer (210, 30) in a manner so that the neural network parameters (32) monotonically increase along the coding order (104) or monotonically decrease along the coding order (104).

92. Apparatus of embodiment 90, wherein the permutation orders the neurons (14, 18, 20) of the neural network layer (210, 30) in a manner so that, among predetermined coding orders signalable by the serialization parameter (102), a bitrate for coding the neural network parameters (32) into the data stream (45) is lowest for the permutation indicated by the serialization parameter (102).

93. Apparatus of any previous embodiment 85 to 92, wherein the neural network parameters (32) comprise weights and biases.

94. Apparatus of any previous embodiment 85 to 93, wherein the apparatus is configured to structure the data stream into individually accessible sub-portions (43, 44, 240), each sub-portion (43, 44, 240) representing a corresponding neural network portion of the neural network, so that each sub-portion (43, 44, 240) is completely traversed by the coding order (104) before a subsequent sub-portion is traversed by the coding order (104).

95. Apparatus of any of embodiments 87 to 94, wherein the neural network parameters (32) are encoded into the data stream using context-adaptive arithmetic encoding and using context initialization at a start of any individually accessible portion (200) or sub-portion (43, 44, 240).

96. Apparatus of any of embodiments 87 to 95, wherein the apparatus is configured to encode, into the data stream, start codes (242) at which each individually accessible portion (200) or sub-portion (43, 44, 240) begins, and/or pointers (220, 244) pointing to beginnings of each individually accessible portion or sub-portion, and/or pointers data stream lengths (246) of each individually accessible portion or sub-portion for skipping the respective individually accessible portion or sub-portion in parsing the data stream.

97. Apparatus of any of the previous embodiments 85 to 96, wherein the apparatus is configured to encode, into the data stream, a numerical computation representation parameter (120) indicating a numerical representation and bit size at which the neural network parameters (32) are to be represented when using the neural network (10) for inference.

98. Apparatus for encoding a representation of a neural network (10) into a data stream (45), wherein the apparatus is configured to provide the data stream (45) with a numerical computation representation parameter (120) indicating a numerical representation and bit size at which neural network parameters (32) of the neural network, which are encoded into the data stream (45), are to be represented when using the neural network (10) for inference.

99. Apparatus of any of the previous embodiments 85 to 98, wherein the apparatus is configured to structure the data stream (45) into individually accessible sub-portions (43, 44, 240), each individually accessible sub-portion representing a corresponding neural network portion of the neural network, so that each individually accessible sub-portion is completely traversed by the coding order (104) before a subsequent individually accessible sub-portion is traversed by the coding order (104), wherein the apparatus is configured to encode, into the data stream (45), for a predetermined individually accessible sub-portion the neural network parameter and a type parameter indicting a parameter type of the neural network parameter encoded into the predetermined individually accessible sub-portion.

100. Apparatus of embodiment 99, wherein the type parameter discriminates, at least, between neural network weights and neural network biases.

101. Apparatus of any of the previous embodiments 85 to 100, wherein the apparatus is configured to structure the data stream (45) into one or more individually accessible portions (200), each individually accessible portion representing a corresponding neural network layer (210, 30) of the neural network, and encode, into the data stream (45), for a predetermined neural network layer, a neural network layer type parameter (130) indicating a neural network layer type of the predetermined neural network layer of the neural network.

102. Apparatus for encoding a representation of a neural network (10) into a data stream (45), so that the data stream (45) is structured into one or more individually accessible portions (200), each individually accessible portion representing a corresponding neural network layer (210, 30) of the neural network, wherein the apparatus is configured to provide the data stream (45) with, for a predetermined neural network layer, a neural network layer type parameter (130) indicating a neural network layer type of the predetermined neural network layer of the neural network.

103. Apparatus of any of embodiments 101 and 102, wherein the neural network layer type parameter (130) discriminates, at least, between a fully-connected and a convolutional layer type.

104. Apparatus of any of the previous embodiments 85 to 103, wherein the apparatus is configured to structure the data stream (45) into individually accessible portions (200), each individually accessible portion representing a corresponding neural network portion of the neural network, and encode, into the data stream (45), for each of one or more predetermined individually accessible portions, a pointer (220, 244) pointing to a beginning of each individually accessible portion.

105. Apparatus for encoding a representation of a neural network (10) into a data stream (45), so that the data stream (45) is structured into one or more individually accessible portions (200), each portion representing a corresponding neural network layer (210, 30) of the neural network, wherein the apparatus is configured to provide the data stream (45) with, for each of one or more predetermined individually accessible portions, a pointer (220, 244) pointing to a beginning of the respective predetermined individually accessible portion.

106. Apparatus of any of previous embodiments 104 and 105, wherein each individually accessible portion represents a corresponding neural network layer (210) of the neural network or a neural network portion (43, 44, 240) of a neural network layer (210) of the neural network.

107. Apparatus of any of embodiments 85 to 106, wherein the apparatus is configured to encode a representation of a neural network (10) into the data stream (45), so that the data stream (45) is structured into one or more individually accessible portions (200), each individually accessible portion representing a corresponding neural network layer (210, 30) of the neural network, and so that the data stream (45) is, within a predetermined portion, further structured into individually accessible sub-portions (43, 44, 240), each sub-portion (43, 44, 240) representing a corresponding neural network portion of the respective neural network layer of the neural network, wherein the apparatus is configured to provide the data stream (45) with, for each of one or more predetermined individually accessible sub-portions (43, 44, 240) a start code (242) at which the respective predetermined individually accessible subportion begins, and/or a pointer (244) pointing to a beginning of the respective predetermined individually accessible sub-portion, and/or a data stream length parameter indicating a data stream length (246) of the respective predetermined individually accessible sub-portion for skipping the respective predetermined individually accessible sub-portion in parsing the data stream.

108. Apparatus of embodiment 107, wherein the apparatus is configured to encode, into the data stream (45), the representation of the neural network using context-adaptive arithmetic encoding and using context initialization at a start of each individually accessible portion and each individually accessible sub-portion.

109. Apparatus for encoding a representation of a neural network (10) into a data stream (45), so that the data stream (45) is structured into one or more individually accessible portions (200), each individually accessible portion representing a corresponding neural network layer (210, 30) of the neural network, and so that the data stream (45) is, within a predetermined portion, further structured into individually accessible sub-portions (43, 44, 240), each sub-portion (43, 44, 240) representing a corresponding neural network portion of the respective neural network layer of the neural network, wherein the apparatus is configured to provide the data stream (45) with, for each of one or more predetermined individually accessible sub-portions (43, 44, 240) a start code (242) at which the respective predetermined individually accessible subportion begins, and/or a pointer (244) pointing to a beginning of the respective predetermined individually accessible sub-portion, and/or a data stream length parameter indicating a data stream length (246) of the respective predetermined individually accessible sub-portion for skipping the respective predetermined individually accessible sub-portion in parsing the data stream (45).

110. Apparatus of embodiment 109, wherein the apparatus is configured to encode, into the data stream (45), the representation of the neural network using context-adaptive arithmetic encoding and using context initialization at a start of each individually accessible portion and each individually accessible sub-portion.

111. Apparatus of any previous embodiment 85 to 110, wherein the apparatus is configured to encode a representation of a neural network (10) into a data stream, so that the data stream (45) is structured into individually accessible portions (200), each individually accessible portion representing a corresponding neural network portion of the neural network, wherein the apparatus is configured to provide the data stream (45) with, for each of one or more predetermined individually accessible portions, a processing option parameter (250) indicating one or more processing options (252) which have to be used or which may optionally be used when using the neural network (10) for inference.

112. Apparatus of embodiment 111, wherein the processing option parameter (250) indicates the one or more available processing options (252) out of a set of predetermined processing options (252) including parallel processing capability of the respective predetermined individually accessible portion; and/or sample wise parallel processing capability (252₂) of the respective predetermined individually accessible portion; and/or channel wise parallel processing capability (252i) of the respective predetermined individually accessible portion; and/or classification category wise parallel processing capability of the respective predetermined individually accessible portion; and/or dependency of the neural network portion represented by the respective predetermined individually accessible portion on a computation result gained from another individually accessibly portion of the data stream (45) relating to the same neural network portion but belonging to another version of versions (330) of the neural network which are encoded into the data stream (45) in a layered manner.

113. Apparatus for encoding a representation of a neural network (10) into a data stream (45), so that the data stream (45) is structured into individually accessible portions (200), each individually accessible portion representing a corresponding neural network portion of the neural network, wherein the apparatus is configured to provide the data stream (45) with, for each of one or more predetermined individually accessible portions, a processing option parameter (250) indicating one or more processing options (252) which have to be used or which may optionally be used when using the neural network (10) for inference.

114. Apparatus of embodiment 113, wherein the processing option parameter (250) indicates the one or more available processing options (252) out of a set of predetermined processing options (252) including parallel processing capability of the respective predetermined individually accessible portion; and/or sample wise parallel processing capability (252₂) of the respective predetermined individually accessible portion; and/or channel wise parallel processing capability (252i) of the respective predetermined individually accessible portion; and/or classification category wise parallel processing capability of the respective predetermined individually accessible portion; and/or dependency of the neural network portion represented by the respective predetermined individually accessible portion on a computation result gained from another individually accessibly portion of the data stream (45) relating to the same neural network portion but belonging to another version of versions (330) of the neural network which are encoded into the data stream (45) in a layered manner.

115. Apparatus of one of embodiments 85 to 114, wherein the apparatus is configured to encode neural network parameters (32), which represent a neural network, into a data stream (45), so that the neural network parameters (32) are encoded into the data stream (45) in a manner quantized (260) onto quantization indices (32″), and the neural network parameters (32) are encoded into the data stream (45) so that neural network parameters (32) in different neural network portions of the neural network are quantized (260) differently, wherein the apparatus is configured to provide the data stream (45) indicating, for each of the neural network portions, a reconstruction rule (270) for dequantizing (280) neural network parameters (32) relating to the respective neural network portion.

116. Apparatus for encoding neural network parameters (32), which represent a neural network, into a data stream (45), so that the neural network parameters (32) are encoded into the data stream (45) in a manner quantized (260) onto quantization indices (32″), and the neural network parameters (32) are encoded into the data stream (45) so that neural network parameters (32) in different neural network portions of the neural network are quantized (260) differently, wherein the apparatus is configured to provide the data stream (45) indicating, for each of the neural network portions, a reconstruction rule (270) for dequantizing (280) neural network parameters (32) relating to the respective neural network portion.

117. Apparatus of embodiment 115 or embodiment 116, wherein the neural network portions comprise neural network layers (210, 30) of the neural network and/or layer portions into which a predetermined neural network layer of the neural network is subdivided.

118. Apparatus of any previous embodiment 115 to 117, wherein the apparatus is configured to encode, into the data stream (45), a first reconstruction rule (270₁, 270a₁) for dequantizing (280) neural network parameters (32) relating to a first neural network portion, in a manner delta-encoded relative to a second reconstruction rule (270₂, 270a₂) for dequantizing (280) neural network parameters (32) relating to a second neural network portion.

119. Apparatus of embodiment 118, wherein the apparatus is configured to encode, into the data stream (45), for indicating the first reconstruction rule (270₁, 270a₁), a first exponent value and, for indicating the second reconstruction rule (270₂, 270a₂), a second exponent value, the first reconstruction rule (270₁, 270a₁) is defined by a first quantization step size (263) defined by an exponentiation of a predetermined basis and a first exponent defined by the first exponent value, and the second reconstruction rule (270₂, 270a₂) is defined by a second quantization step size (263) defined by an exponentiation of the predetermined basis and a second exponent defined by a sum over the first and second exponent values.

120. Apparatus of embodiment 119, wherein the data stream further indicates the predetermined basis.

121. Apparatus of any previous embodiment 115 to 118, wherein the apparatus is configured to encode, into the data stream, for indicating a first reconstruction rule (270₁, 270a₁) for dequantizing (280) neural network parameters (32) relating to a first neural network portion, a first exponent value and, for indicating a second reconstruction rule (270₂, 270&₂) for dequantizing (280) neural network parameters (32) relating to a second neural network portion, a second exponent value, the first reconstruction rule (270₁, 270a₁) is defined by a first quantization step size (263) defined by an exponentiation of a predetermined basis and a first exponent defined by a sum over the first exponent value and a predetermined exponent value, and the second reconstruction rule (270₂, 270a₂) is defined by a second quantization step size (263) defined by an exponentiation of the predetermined basis and a second exponent defined by a sum over the second exponent values and the predetermined exponent value.

122. Apparatus of embodiment 121, wherein the data stream further indicates the predetermined basis.

123. Apparatus of embodiment 122, wherein the data stream indicates the predetermined basis at a neural network scope.

124. Apparatus of any previous embodiment 121 to 123, wherein the data stream further indicates the predetermined exponent value.

125. Apparatus of embodiment 125, wherein the data stream indicates the predetermined exponent value at a neural network layer (210, 30) scope.

126. Apparatus of embodiment 124 or embodiment 125, wherein the data stream further indicates the predetermined basis and the data stream indicates the predetermined exponent value at a scope finer than a scope at which the predetermined basis is indicated by the data stream.

127. Apparatus of any of previous embodiments 119 to 126, wherein the apparatus is configured to encode, into the data stream, the predetermined basis in a non-integer format and the first and second exponent values in integer format.

128. Apparatus of any of embodiments 118 to 127, wherein the apparatus is configured to encode, into the data stream, for indicating the first reconstruction rule (270₁, 270a₁), a first parameter set (264) defining a first quantization-index-to-reconstruction-level mapping (265), and for indicating the second reconstruction rule (270₂, 270a₂), a second parameter set (264) defining a second quantization-index-to-reconstruction-level mapping (265), the first reconstruction rule (270₁, 270a₁) is defined by the first quantization-index-to-reconstruction-level mapping (265), and the second reconstruction rule (270₂, 270a₂) is defined by an extension of the first quantization-index-to-reconstruction-level mapping (265) by the second quantization-index-to-reconstruction-level mapping (265) in a predetermined manner.

129. Apparatus of any of embodiments 118 to 128, wherein the apparatus is configured to encode, into the data stream, for indicating the first reconstruction rule (270₁, 270a₁), a first parameter set (264) defining a first quantization-index-to-reconstruction-level mapping (265), and for indicating the second reconstruction rule (270₂, 270a₂), a second parameter set (264) defining a second quantization-index-to-reconstruction-level mapping (265), the first reconstruction rule (270₁, 270a₁) is defined by an extension of a predetermined quantization-index-to-reconstruction-level mapping (265) by the first quantization-index-to-reconstruction-level mapping (265) in a predetermined manner, and the second reconstruction rule (270₂, 270a₂) is defined by an extension of the predetermined quantization-index-to-reconstruction-level mapping (265) by the second quantization-index-to-reconstruction-level mapping (265) in the predetermined manner.

130. Apparatus of embodiment 129, wherein the data stream further indicates the predetermined quantization-index-to-reconstruction-level mapping (265).

131. Apparatus of embodiment 130, wherein the data stream indicates the predetermined quantization-index-to-reconstruction-level mapping (265) at a neural network scope or at a neural network layer (210, 30) scope.

132. Apparatus of any of previous embodiments 128 to 131, wherein, according to the predetermined manner, a mapping of each index value (32″), according to the quantization-index-to-reconstruction-level mapping to be extended, onto a first reconstruction level is superseded by, if present, a mapping of the respective index value (32″), according to the quantization-index-to-reconstruction-level mapping extending the quantization-index-to-reconstruction-level mapping to be extended, onto a second reconstruction level, and/or for any index value (32″), for which according to the quantization-index-to-reconstruction-level mapping to be extended, no reconstruction level is defined onto which the respective index value (32″) should be mapped, and which is, according to the quantization-index-to-reconstruction-level mapping extending the quantization-index-to-reconstruction-level mapping to be extended, mapped onto a corresponding reconstruction level, the mapping from the respective index value (32″) onto the corresponding reconstruction level is adopted, and/or for any index value (32″), for which according to the quantization-index-to-reconstruction-level mapping extending the quantization-index-to-reconstruction-level mapping to be extended, no reconstruction level is defined onto which the respective index value (32″) should be mapped, and which is, according to the quantization-index-to-reconstruction-level mapping to be extended, mapped onto a corresponding reconstruction level, the mapping from the respective index value (32″) onto the corresponding reconstruction level is adopted.

133. Apparatus of any previous embodiment 115 to 132, wherein the apparatus is configured to encode, into the data stream, for indicating the reconstruction rule (270) of a predetermined neural network portion, a quantization step size parameter (262) indicating a quantization step size (263), and a parameter set (264) defining a quantization-index-to-reconstruction-level mapping (265), wherein the reconstruction rule (270) of the predetermined neural network portion is defined by the quantization step size (263) for quantization indices (32″) within a predetermined index interval (268), and the quantization-index-to-reconstruction-level mapping (265) for quantization indices (32″) outside the predetermined index interval (268).

134. Apparatus for encoding neural network parameters (32), which represent a neural network, into a data stream (45), so that the neural network parameters (32) are encoded into the data stream (45) in a manner quantized (260) onto quantization indices (32″), wherein the apparatus is configured to provide the data stream (45) with, for indicating a reconstruction rule (270) for dequantizing (280) the neural network parameters (32), a quantization step size parameter (262) indicating a quantization step size (263), and a parameter set (264) defining a quantization-index-to-reconstruction-level mapping (265), wherein the reconstruction rule (270) of the predetermined neural network portion is defined by the quantization step size (263) for quantization indices (32″) within a predetermined index interval (268), and the quantization-index-to-reconstruction-level mapping (265) for quantization indices (32″) outside the predetermined index interval (268).

135. Apparatus of embodiment 133 or embodiment 134, wherein the predetermined index interval (268) includes zero.

136. Apparatus of embodiment 135, wherein the predetermined index interval (268) extends up to a predetermined magnitude threshold value and quantization indices (32″) exceeding the predetermined magnitude threshold value represent escape codes which signal that the quantization-index-to-reconstruction-level mapping (265) is to be used for dequantization (280).

137. Apparatus of any of previous embodiments 133 to 136, wherein the parameter set (264) defines the quantization-index-to-reconstruction-level mapping (265) by way of a list of reconstruction levels associated with quantization indices (32″) outside the predetermined index interval (268).

138. Apparatus of any of previous embodiments 115 to 137, wherein the neural network portions comprise one or more sub-portions of a neural network layer (210, 30) of the neural network and/or one or more neural network layers of the neural network.

139. Apparatus of any of previous embodiments 115 to 138, wherein the apparatus is configured to structure the data stream (45) into individually accessible portions (200), and encode into each individually accessible portion the neural network parameters (32) for a corresponding neural network portion.

140. Apparatus of 139, wherein the apparatus is configured to encode, into the data stream, the individually accessible portions (200) using context-adaptive arithmetic encoding and using context initialization at a start of each individually accessible portion.

141. Apparatus of embodiment 139 or embodiment 140, wherein the apparatus is configured to encode, into the data stream, for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

142. Apparatus of any previous embodiment 139 to 141, wherein the apparatus is configured to encode, into the data stream, for each of the neural network portions, an indication of the reconstruction rule (270) for dequantizing (280) neural network parameters (32) relating to the respective neural network portion in a main header portion (47) of the data stream relating the neural network as a whole, a neural network layer (210, 30) related header portion (110) of the data stream relating to the neural network layer the respective neural network portion is part of, or a neural network portion specific header portion of the data stream relating to the respective neural network portion is part of.

143. Apparatus of any previous embodiment 85 to 142, wherein the apparatus is configured to encode a representation of a neural network (10) into a data stream (45), so that the data stream (45) is structured into individually accessible portions (200), each portion representing a corresponding neural network portion of the neural network, wherein the apparatus is configured to provide the data stream (45) with, for each of one or more predetermined individually accessible portions, an identification parameter (310) for identifying the respective predetermined individually accessible portion.

144. Apparatus for encoding a representation of a neural network (10) into a data stream (45), so that the data stream (45) is structured into individually accessible portions (200), each portion representing a corresponding neural network portion of the neural network, wherein the apparatus is configured to provide the data stream (45) with, for each of one or more predetermined individually accessible portions, an identification parameter (310) for identifying the respective predetermined individually accessible portion.

145. Apparatus of embodiment 143 or embodiment 144, wherein the identification parameter (310) is related to the respective predetermined individually accessible portion via a hash function or error detection code or error correction code.

146. Apparatus of any of previous embodiments 143 to 145, wherein the apparatus is configured to encode, into the data stream (45), a higher-level identification parameter (310) for identifying a collection of more than one predetermined individually accessible portion.

147. Apparatus of embodiment 146, wherein the higher-level identification parameter (310) is related to the identification parameters (310) of the more than one predetermined individually accessible portion via a hash function or error detection code or error correction code.

148. Apparatus of any of previous embodiments 143 to 147, wherein the apparatus is configured to encode, into the data stream, the individually accessible portions (200) using context-adaptive arithmetic encoding and using context initialization at a start of each individually accessible portion.

149. Apparatus of any of previous embodiments 143 to 148, wherein the apparatus is configured to encode, into the data stream, for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

150. Apparatus of any of previous embodiments 143 to 149, wherein the neural network portions comprise one or more sub-portions of a neural network layer (210, 30) of the neural network and/or one or more neural network layers (210, 30) of the neural network.

151. Apparatus of any previous embodiment 85 to 150, wherein the apparatus is configured to encode a representation of a neural network (10) into a data stream (45) in a layered manner so that different versions (330) of the neural network are encoded into the data stream (45), and so that the data stream (45) is structured into one or more individually accessible portions (200), each portion relating to a corresponding version of the neural network, wherein the apparatus is configured encode a first version (330₂) of the neural network encoded into a first portion delta-coded relative to a second version (330i) of the neural network encoded into a second portion, and/or in form of one or more compensating neural network portions (332) each of which is to be, for performing an inference based on the first version (330₂) of the neural network, executed in addition to an execution of a corresponding neural network portion (334) of a second version (330i) of the neural network encoded into a second portion, and wherein outputs of the respective compensating neural network portion (332) and corresponding neural network portion (334) are to be summed up.

152. Apparatus for encoding a representation of a neural network (10) into a data stream (45) in a layered manner so that different versions (330) of the neural network are encoded into the data stream (45), and so that the data stream (45) is structured into one or more individually accessible portions (200), each portion relating to a corresponding version of the neural network, wherein the apparatus is configured encode a first version (330₂) of the neural network into a first portion delta-coded relative to a second version (330i) of the neural network encoded into a second portion, and/or in form of one or more compensating neural network portions (332) each of which is to be, for performing an inference based on the first version (330₂) of the neural network, executed in addition to an execution of a corresponding neural network portion (334) of a second version (330i) of the neural network encoded into a second portion, and wherein outputs of the respective compensating neural network portion (332) and corresponding neural network portion (334) are to be summed up.

153. Apparatus of embodiment 151 or embodiment 152, wherein the apparatus is configured to encode, into a second portion of the data stream, the second version (330i) of the neural network; and wherein the apparatus is configured to encode, into a first portion of the data stream, the first version (330₂) of the neural network delta-coded relative to the second version (330i) of the neural network encoded into the second portion in terms of weight and/or bias differences, and/or additional neurons (14, 18, 20) or neuron interconnections (22, 24).

154. Apparatus of any previous embodiment 151 to 153, wherein the apparatus is configured to encode, into the data stream, the individually accessible portions (200) using context-adaptive arithmetic coding (600) and using context initialization at a start of each individually accessible portion.

155. Apparatus of any previous embodiment 151 to 154, wherein the apparatus is configured to encode, into the data stream, for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

156. Apparatus of any previous embodiment 151 to 155, wherein the apparatus is configured to encode, into the data stream, for each of one or more predetermined individually accessible portions (200) an identification parameter (310) for identifying the respective predetermined individually accessible portion.

157. Apparatus of any previous embodiment 85 to 156, wherein the apparatus is configured to encode a representation of a neural network (10) into a data stream (45), so that the data stream (45) is structured into individually accessible portions (200), each portion representing a corresponding neural network portion of the neural network, wherein the apparatus is configured to provide the data stream (45) with, for each of one or more predetermined individually accessible portions (200) a supplemental data (350) for supplementing the representation of the neural network.

158. Apparatus for encoding a representation of a neural network (10) into a data stream (45), so that the data stream (45) is structured into individually accessible portions (200), each portion representing a corresponding neural network portion of the neural network, wherein the apparatus is configured to provide the data stream (45) with, for each of one or more predetermined individually accessible portions (200) a supplemental data (350) for supplementing the representation of the neural network.

159. Apparatus (45) of embodiment 157 or embodiment 158, wherein the data stream (45) indicates the supplemental data (350) as being dispensable for inference based on the neural network.

160. Apparatus of any previous embodiment 157 to 159, wherein the apparatus is configured to encode the supplemental data (350) for supplementing the representation of the neural network for the one or more predetermined individually accessible portions (200) into further individually accessible portions (200) so that the data stream comprises for each of the one or more predetermined individually accessible portions (200) a corresponding further predetermined individually accessible portion relating to the neural network portion to which the respective predetermined individually accessible portion corresponds.

161. Apparatus of any previous embodiment 157 to 160, wherein the neural network portions comprise neural network layers (210, 30) of the neural network and/or layer portions into which a predetermined neural network layer (210, 30) of the neural network is subdivided.

162. Apparatus of any previous embodiment 157 to 161, wherein the apparatus is configured to encode the individually accessible portions (200) using context-adaptive arithmetic encoding and using context initialization at a start of each individually accessible portion.

163. Apparatus of any previous embodiment 157 to 162, wherein the apparatus is configured to encode, into the data stream, for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

164. Apparatus of any previous embodiment 157 to 163, wherein the supplemental data (350) relates to relevance scores of neural network parameters (32), and/or perturbation robustness of neural network parameters (32).

165. Apparatus of any previous embodiment 85 to 164, for encoding a representation of a neural network (10) into a data stream (45), wherein the apparatus is configured to provide the data stream (45) with hierarchical control data (400) structured into a sequence (410) of control data portions (420), wherein the control data portions provide information on the neural network at increasing details along the sequence of control data portions.

166. Apparatus for encoding a representation of a neural network (10) into a data stream (45), wherein the apparatus is configured to provide the data stream (45) with hierarchical control data (400) structured into a sequence (410) of control data portions (420), wherein the control data portions provide information on the neural network at increasing details along the sequence of control data portions.

167. Apparatus of embodiment 165 or embodiment 166, wherein at least some of the control data portions (420) provide information on the neural network which is partially redundant.

168. Apparatus of any previous embodiment 165 to 167, wherein a first control data portion provides the information on the neural network by way of indicating a default neural network type implying default settings and a second control data portion comprises a parameter to indicate each of the default settings.

169. Apparatus for decoding a representation of a neural network (10) from a data stream (45), wherein the apparatus is configured to decode from the data stream (45) a serialization parameter (102) indicating a coding order (104) at which neural network parameters (32), which define neuron interconnections (22, 24) of the neural network, are encoded into the data stream (45).

170. Apparatus of embodiment 169, wherein the apparatus is configured to decode, from the data stream (45), the neural network parameters (32) using context-adaptive arithmetic decoding.

171. Apparatus of embodiment 169 or embodiment 170, wherein the data stream is structured into one or more individually accessible portions (200), each individually accessible portion representing a corresponding neural network layer (210, 30) of the neural network, and wherein the apparatus is configured to decode serially, from the data stream (45), neural network parameters, which define neuron interconnections (22, 24) of the neural network within a predetermined neural network layer, and use the coding order (104) to assign neural network parameters serially decoded from the data stream (45) to the neuron interconnections (22, 24).

172. Apparatus of any previous embodiment 169 to 171, wherein the serialization parameter (102) is an n-ary parameter which indicates the coding order (104) out of a set (108) of n coding orders (104).

173. Apparatus of embodiment 172, wherein the set (108) of n coding orders (104) comprises first predetermined coding orders (106i) which differ in an order at which the predetermined coding orders traverse dimensions (34) of a tensor (30) describing a predetermined neural network layer (210, 30) of the neural network; and/or second predetermined coding orders (106₂) which differ in a number (107) of times at which the predetermined coding orders traverse a predetermined neural network layer (210, 30) of the neural network for sake of scalable coding of the neural network; and/or third predetermined coding orders (106₃) which differ in an order at which the predetermined coding orders traverse neural network layers of the neural network; and/or fourth predetermined coding orders (106₄) which differ in an order at which neurons (14, 18, 20) of a neural network layer of the neural network are traversed.

174. Apparatus of any previous embodiment 169 to 173, wherein the serialization parameter (102) is indicative of a permutation using which the coding order (104) permutes neurons (14, 18, 20) of a neural network layer (210, 30) relative to a default order.

175. Apparatus of embodiment 174, wherein the permutation orders the neurons (14, 18, 20) of the neural network layer (210, 30) in a manner so that the neural network parameters (32) monotonically increase along the coding order (104) or monotonically decrease along the coding order (104).

176. Apparatus of embodiment 174, wherein the permutation orders the neurons (14, 18, 20) of the neural network layer (210, 30) in a manner so that, among predetermined coding orders signalable by the serialization parameter (102), a bitrate for coding the neural network parameters (32) into the data stream (45) is lowest for the permutation indicated by the serialization parameter (102).

177. Apparatus of any previous embodiment 169 to 176, wherein the neural network parameters (32) comprise weights and biases.

178. Apparatus of any previous embodiment 169 to 177, wherein the apparatus is configured to decode, from the data stream, individually accessible sub-portions (43, 44, 240), into which individually accessible portions (200) the data stream is structured, each subportion (43, 44, 240) representing a corresponding neural network portion of the neural network, so that each sub-portion (43, 44, 240) is completely traversed by the coding order (104) before a subsequent sub-portion is traversed by the coding order (104).

179. Apparatus of any of embodiments 171 to 178, wherein the neural network parameters (32) are decoded from the data stream using context-adaptive arithmetic decoding and using context initialization at a start of any individually accessible portion (200) or sub-portion (43, 44, 240).

180. Apparatus of any of embodiments 171 to 179, wherein the apparatus is configured to decode, from the data stream, start codes (242) at which each individually accessible portion (200) or sub-portion (43, 44, 240) begins, and/or pointers (220, 244) pointing to beginnings of each individually accessible portion or sub-portion, and/or pointers data stream lengths (246) of each individually accessible portion or sub-portion for skipping the respective individually accessible portion or sub-portion in parsing the data stream.

181. Apparatus of any of the previous embodiments 169 to 180, wherein the apparatus is configured to decode, from the data stream, a numerical computation representation parameter (120) indicating a numerical representation and bit size at which the neural network parameters (32) are to be represented when using the neural network (10) for inference.

182. Apparatus for decoding a representation of a neural network (10) from a data stream (45), wherein the apparatus is configured to decode from the data stream (45) a numerical computation representation parameter (120) indicating a numerical representation and bit size at which neural network parameters (32) of the neural network, which are encoded into the data stream (45), are to be represented when using the neural network (10) for inference, and to use the numerical representation and bit size for representing the neural network parameters (32) decoded from the data stream (45).

183. Apparatus of any of the previous embodiments 169 to 182, wherein the data stream (45), is structured into individually accessible sub-portions (43, 44, 240), each individually accessible sub-portion representing a corresponding neural network portion of the neural network, so that each individually accessible sub-portion is completely traversed by the coding order (104) before a subsequent individually accessible sub-portion is traversed by the coding order (104), wherein the apparatus is configured to decode, from the data stream (45), for a predetermined individually accessible sub-portion the neural network parameter and a type parameter indicting a parameter type of the neural network parameter decoded from the predetermined individually accessible sub-portion.

184. Apparatus of embodiment 183, wherein the type parameter discriminates, at least, between neural network weights and neural network biases.

185. Apparatus of any of the previous embodiments 169 to 184, wherein the data stream (45), is structured into one or more individually accessible portions (200), each one or more individually accessible portion representing a corresponding neural network layer (210, 30) of the neural network, and wherein the apparatus is configured to decode, from the data stream (45), for a predetermined neural network layer, a neural network layer type parameter (130) indicating a neural network layer type of the predetermined neural network layer of the neural network.

186. Apparatus for decoding a representation of a neural network (10) from a data stream (45), wherein the data stream (45) is structured into one or more individually accessible portions (200), each portion representing a corresponding neural network layer (210, 30) of the neural network, wherein the apparatus is configured to decode from the data stream (45), for a predetermined neural network layer (210, 30), a neural network layer type parameter (130) indicating a neural network layer type of the predetermined neural network layer of the neural network.

187. Apparatus of any of embodiments 185 and 186, wherein the neural network layer type parameter (130) discriminates, at least, between a fully-connected and a convolutional layer type.

188. Apparatus of any of the previous embodiments 169 to 187, wherein the data stream (45), is structured into individually accessible portions (200), each individually accessible portion representing a corresponding neural network portion of the neural network, and wherein the apparatus is configured to decode, from the data stream (45), for each of one or more predetermined individually accessible portions (200), a pointer (220, 244) pointing to a beginning of each individually accessible portion.

189. Apparatus for decoding a representation of a neural network (10) from a data stream (45), wherein the data stream (45) is structured into one or more individually accessible portions (200), each portion representing a corresponding neural network layer (210, 30) of the neural network, wherein the apparatus is configured to decode from the data stream (45), for each of one or more predetermined individually accessible portions, a pointer (220, 244) pointing to a beginning of the respective predetermined individually accessible portion.

190. Apparatus of any of previous embodiments 188 and 189, wherein each individually accessible portion represents a corresponding neural network layer (210) of the neural network or a neural network portion (43, 44, 240) of a neural network layer (210) of the neural network.

191. Apparatus of any of embodiments 169 to 190, wherein the apparatus is configured to decode a representation of a neural network (10) from the data stream (45), wherein the data stream (45) is structured into one or more individually accessible portions (200), each individually accessible portion representing a corresponding neural network layer (210, 30) of the neural network, and wherein the data stream (45) is, within a predetermined portion, further structured into individually accessible sub-portions (43, 44, 240), each sub-portion (43, 44, 240) representing a corresponding neural network portion of the respective neural network layer (210, 30) of the neural network, wherein the apparatus is configured to decode from the data stream (45), for each of one or more predetermined individually accessible sub-portions (43, 44, 240) a start code (242) at which the respective predetermined individually accessible subportion begins, and/or a pointer (244) pointing to a beginning of the respective predetermined individually accessible sub-portion, and/or a data stream length parameter indicating a data stream length (246) of the respective predetermined individually accessible sub-portion for skipping the respective predetermined individually accessible sub-portion in parsing the data stream (45).

192. Apparatus of embodiment 191, wherein the apparatus is configured to decode, from the data stream (45), the representation of the neural network using context-adaptive arithmetic decoding and using context initialization at a start of each individually accessible portion and each individually accessible sub-portion.

193. Apparatus for decoding a representation of a neural network (10) from a data stream (45), wherein the data stream (45) is structured into one or more individually accessible portions (200), each individually accessible portion representing a corresponding neural network layer (210, 30) of the neural network, and wherein the data stream (45) is, within a predetermined portion, further structured into individually accessible sub-portions (43, 44, 240), each sub-portion (43, 44, 240) representing a corresponding neural network portion of the respective neural network layer (210, 30) of the neural network, wherein the apparatus is configured to decode from the data stream (45), for each of one or more predetermined individually accessible sub-portions (43, 44, 240) a start code (242) at which the respective predetermined individually accessible sub-portion begins, and/or a pointer (244) pointing to a beginning of the respective predetermined individually accessible sub-portion, and/or a data stream length parameter indicating a data stream length (246) of the respective predetermined individually accessible sub-portion for skipping the respective predetermined individually accessible sub-portion in parsing the data stream (45).

194. Apparatus of embodiment 193, wherein the apparatus is configured to decode, from the data stream (45), the representation of the neural network using context-adaptive arithmetic decoding and using context initialization at a start of each individually accessible portion and each individually accessible sub-portion.

195. Apparatus of any previous embodiment 169 to 194, wherein the apparatus is configured to decode a representation of a neural network (10) from a data stream (45), wherein the data stream (45) is structured into individually accessible portions (200), each individually accessible portion representing a corresponding neural network portion of the neural network, wherein the apparatus is configured to decode from the data stream (45), for each of one or more predetermined individually accessible portions (200), a processing option parameter (250) indicating one or more processing options (252) which have to be used or which may optionally be used when using the neural network (10) for inference.

196. Apparatus of embodiment 195, wherein the processing option parameter (250) indicates the one or more available processing options (252) out of a set of predetermined processing options (252) including parallel processing capability of the respective predetermined individually accessible portion; and/or sample wise parallel processing capability (252₂) of the respective predetermined individually accessible portion; and/or channel wise parallel processing capability (252i) of the respective predetermined individually accessible portion; and/or classification category wise parallel processing capability of the respective predetermined individually accessible portion; and/or dependency of the neural network portion represented by the respective predetermined individually accessible portion on a computation result gained from another individually accessibly portion of the data stream (45) relating to the same neural network portion but belonging to another version of versions (330) of the neural network which are encoded into the data stream (45) in a layered manner.

197. Apparatus for decoding a representation of a neural network (10) from a data stream (45), wherein the data stream (45) is structured into individually accessible portions (200), each individually accessible portion representing a corresponding neural network portion of the neural network, wherein the apparatus is configured to decode from the data stream (45), for each of one or more predetermined individually accessible portions, a processing option parameter (250) indicating one or more processing options (252) which have to be used or which may optionally be used when using the neural network (10) for inference.

198. Apparatus of embodiment 197, wherein the processing option parameter (250) indicates the one or more available processing options (252) out of a set of predetermined processing options (252) including parallel processing capability of the respective predetermined individually accessible portion; and/or sample wise parallel processing capability (252₂) of the respective predetermined individually accessible portion; and/or channel wise parallel processing capability (252i) of the respective predetermined individually accessible portion; and/or classification category wise parallel processing capability of the respective predetermined individually accessible portion; and/or dependency of the neural network portion represented by the respective predetermined individually accessible portion on a computation result gained from another individually accessibly portion of the data stream (45) relating to the same neural network portion but belonging to another version of versions (330) of the neural network which are encoded into the data stream (45) in a layered manner.

199. Apparatus of one of embodiments 169 to 198, wherein the apparatus is configured to decode neural network parameters (32), which represent a neural network, from a data stream (45), wherein the neural network parameters (32) are encoded into the data stream (45) in a manner quantized (260) onto quantization indices (32″), and the neural network parameters (32) are encoded into the data stream (45) so that neural network parameters (32) in different neural network portions of the neural network are quantized (260) differently, wherein the apparatus is configured to decode from the data stream (45), for each of the neural network portions, a reconstruction rule (270) for dequantizing (280) neural network parameters (32) relating to the respective neural network portion.

200. Apparatus for decoding neural network parameters (32), which represent a neural network, from a data stream (45), wherein the neural network parameters (32) are encoded into the data stream (45) in a manner quantized (260) onto quantization indices (32″), and the neural network parameters (32) are encoded into the data stream (45) so that neural network parameters (32) in different neural network portions of the neural network are quantized (260) differently, wherein the apparatus is configured to decode from the data stream (45), for each of the neural network portions, a reconstruction rule (270) for dequantizing (280) neural network parameters (32) relating to the respective neural network portion.

201. Apparatus of embodiment 199 or embodiment 200, wherein the neural network portions comprise neural network layers (210, 30) of the neural network and/or layer portions into which a predetermined neural network layer of the neural network is subdivided.

202. Apparatus of any previous embodiment 199 to 201, wherein the apparatus is configured to decode, from the data stream (45), a first reconstruction rule (270₁, 270a₁) for dequantizing (280) neural network parameters (32) relating to a first neural network portion, in a manner delta-decoded relative to a second reconstruction rule (270₂, 270a₂) for dequantizing (280) neural network parameters (32) relating to a second neural network portion.

203. Apparatus of embodiment 202, wherein the apparatus is configured to decode, from the data stream (45), for indicating the first reconstruction rule (270₁, 270a₁), a first exponent value and, for indicating the second reconstruction rule (270₂, 270a₂), a second exponent value, the first reconstruction rule (270₁, 270a₁) is defined by a first quantization step size (263) defined by an exponentiation of a predetermined basis and a first exponent defined by the first exponent value, and the second reconstruction rule (270₂, 270a₂) is defined by a second quantization step size (263) defined by an exponentiation of the predetermined basis and a second exponent defined by a sum over the first and second exponent values.

204. Apparatus of embodiment 203, wherein the data stream (45) further indicates the predetermined basis.

205. Apparatus of any previous embodiment 199 to 202, wherein the apparatus is configured to decode, from the data stream (45), for indicating a first reconstruction rule (270₁, 270a₁) for dequantizing (280) neural network parameters (32) relating to a first neural network portion, a first exponent value and, for indicating a second reconstruction rule (270₂, 270a₂) for dequantizing (280) neural network parameters (32) relating to a second neural network portion, a second exponent value, the first reconstruction rule (270₁, 270a₁) is defined by a first quantization step size (263) defined by an exponentiation of a predetermined basis and a first exponent defined by a sum over the first exponent value and a predetermined exponent value, and the second reconstruction rule (270₂, 270a₂) is defined by a second quantization step size (263) defined by an exponentiation of the predetermined basis and a second exponent defined by a sum over the second exponent values and the predetermined exponent value.

206. Apparatus of embodiment 205, wherein the data stream further indicates the predetermined basis.

207. Apparatus of embodiment 206, wherein the data stream indicates the predetermined basis at a neural network scope.

208. Apparatus of any previous embodiment 205 to 207, wherein the data stream further indicates the predetermined exponent value.

209. Apparatus of embodiment 208, wherein the data stream indicates the predetermined exponent value at a neural network layer (210, 30) scope.

210. Apparatus of embodiment 208 or embodiment 209, wherein the data stream further indicates the predetermined basis and the data stream indicates the predetermined exponent value at a scope finer than a scope at which the predetermined basis is indicated by the data stream.

211. Apparatus of any of previous embodiments 203 to 210, wherein the apparatus is configured to decode, from the data stream, the predetermined basis in a non-integer format and the first and second exponent values in integer format.

212. Apparatus of any of embodiments 202 to 211, wherein the apparatus is configured to decode, from the data stream, for indicating the first reconstruction rule (270₁, 270a₁), a first parameter set (264) defining a first quantization-index-to-reconstruction-level mapping (265), and for indicating the second reconstruction rule (270₂, 270a₂), a second parameter set (264) defining a second quantization-index-to-reconstruction-level mapping (265), the first reconstruction rule (270₁, 270a₁) is defined by the first quantization-index-to-reconstruction-level mapping (265), and the second reconstruction rule (270z, 270a₂) is defined by an extension of the first quantization-index-to-reconstruction-level mapping (265) by the second quantization-index-to-reconstruction-level mapping (265) in a predetermined manner.

213. Apparatus of any of embodiments 202 to 212, wherein the apparatus is configured to decode, from the data stream, for indicating the first reconstruction rule (270₁, 270a₁), a first parameter set (264) defining a first quantization-index-to-reconstruction-level mapping (265), and for indicating the second reconstruction rule (270₂, 270a₂), a second parameter set (264) defining a second quantization-index-to-reconstruction-level mapping (265), the first reconstruction rule (270₁, 270a₁) is defined by an extension of a predetermined quantization-index-to-reconstruction-level mapping (265) by the first quantization-index-to-reconstruction-level mapping (265) in a predetermined manner, and the second reconstruction rule (270₂, 270a₂) is defined by an extension of the predetermined quantization-index-to-reconstruction-level mapping (265) by the second quantization-index-to-reconstruction-level mapping (265) in the predetermined manner.

214. Apparatus of embodiment 213, wherein the data stream further indicates the predetermined quantization-index-to-reconstruction-level mapping (265).

215. Apparatus of embodiment 214, wherein the data stream indicates the predetermined quantization-index-to-reconstruction-level mapping (265) at a neural network scope or at a neural network layer (210, 30) scope.

216. Apparatus of any of previous embodiments 212 to 215, wherein, according to the predetermined manner, a mapping of each index value (32″), according to the quantization-index-to-reconstruction-level mapping to be extended, onto a first reconstruction level is superseded by, if present, a mapping of the respective index value (32″), according to the quantization-index-to-reconstruction-level mapping extending the quantization-index-to-reconstruction-level mapping to be extended, onto a second reconstruction level, and/or for any index value (32″), for which according to the quantization-index-to-reconstruction-level mapping to be extended, no reconstruction level is defined onto which the respective index value (32″) should be mapped, and which is, according to the quantization-index-to-reconstruction-level mapping extending the quantization-index-to-reconstruction-level mapping to be extended, mapped onto a corresponding reconstruction level, the mapping from the respective index value (32″) onto the corresponding reconstruction level is adopted, and/or for any index value (32″), for which according to the quantization-index-to-reconstruction-level mapping extending the quantization-index-to-reconstruction-level mapping to be extended, no reconstruction level is defined onto which the respective index value (32″) should be mapped, and which is, according to the quantization-index-to-reconstruction-level mapping to be extended, mapped onto a corresponding reconstruction level, the mapping from the respective index value (32″) onto the corresponding reconstruction level is adopted.

217. Apparatus of any previous embodiment 199 to 216, wherein the apparatus is configured to decode, from the data stream, for indicating the reconstruction rule (270) of a predetermined neural network portion, a quantization step size parameter (262) indicating a quantization step size (263), and a parameter set (264) defining a quantization-index-to-reconstruction-level mapping (265), wherein the reconstruction rule (270) of the predetermined neural network portion is defined by the quantization step size (263) for quantization indices (32″) within a predetermined index interval (268), and the quantization-index-to-reconstruction-level mapping (265) for quantization indices (32″) outside the predetermined index interval (268).

218. Apparatus for decoding neural network parameters (32), which represent a neural network, from a data stream (45), wherein the neural network parameters (32) are encoded into the data stream (45) in a manner quantized (260) onto quantization indices (32″), wherein the apparatus is configured to derive from the data stream (45) a reconstruction rule (270) for dequantizing (280) the neural network parameters (32) by decoding from the data stream (45) a quantization step size parameter (262) indicating a quantization step size (263), and a parameter set (264) defining a quantization-index-to-reconstruction-level mapping (265), wherein the reconstruction rule (270) of the predetermined neural network portion is defined by the quantization step size (263) for quantization indices (32″) within a predetermined index interval (268), and the quantization-index-to-reconstruction-level mapping (265) for quantization indices (32″) outside the predetermined index interval (268).

219. Apparatus of embodiment 217 or embodiment 218, wherein the predetermined index interval (268) includes zero.

220. Apparatus of embodiment 219, wherein the predetermined index interval (268) extends up to a predetermined magnitude threshold value and quantization indices (32″) exceeding the predetermined magnitude threshold value represent escape codes which signal that the quantization-index-to-reconstruction-level mapping (265) is to be used for dequantization (280).

221. Apparatus of any of previous embodiments 217 to 220, wherein the parameter set (264) defines the quantization-index-to-reconstruction-level mapping (265) by way of a list of reconstruction levels associated with quantization indices (32″) outside the predetermined index interval (268).

222. Apparatus of any of previous embodiments 199 to 221, wherein the neural network portions comprise one or more sub-portions of a neural network layer (210, 30) of the neural network and/or one or more neural network layers of the neural network.

223. Apparatus of any of previous embodiments 199 to 222, wherein the data stream (45) is structured into individually accessible portions (200), and the apparatus is configured to decode from each individually accessible portion the neural network parameters (32) for a corresponding neural network portion.

224. Apparatus of 223, wherein the apparatus is configured to decode, from the data stream (45), the individually accessible portions (200) using context-adaptive arithmetic decoding and using context initialization at a start of each individually accessible portion.

225. Apparatus of embodiment 223 or embodiment 224, wherein the apparatus is configured to read, from the data stream (45), for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream (45).

226. Apparatus of any previous embodiment 223 to 225, wherein the apparatus is configured to read, from the data stream (45), for each of the neural network portions, an indication of the reconstruction rule (270) for dequantizing (280) neural network parameters (32) relating to the respective neural network portion in a main header portion (47) of the data stream (45) relating the neural network as a whole, a neural network layer (210, 30) related header portion (110) of the data stream (45) relating to the neural network layer the respective neural network portion is part of, or a neural network portion specific header portion of the data stream (45) relating to the respective neural network portion is part of.

227. Apparatus of any previous embodiment 169 to 226, wherein the apparatus is configured to decode a representation of a neural network (10) from a data stream (45), wherein the data stream (45) is structured into individually accessible portions (200), each portion representing a corresponding neural network portion of the neural network, wherein the apparatus is configured to decode from the data stream (45), for each of one or more predetermined individually accessible portions, an identification parameter (310) for identifying the respective predetermined individually accessible portion.

228. Apparatus for decoding a representation of a neural network (10) from a data stream (45), wherein the data stream (45) is structured into individually accessible portions (200), each portion representing a corresponding neural network portion of the neural network, wherein the apparatus is configured to decode from the data stream (45), for each of one or more predetermined individually accessible portions, an identification parameter (310) for identifying the respective predetermined individually accessible portion.

229. Apparatus of embodiment 227 or embodiment 228, wherein the identification parameter (310) is related to the respective predetermined individually accessible portion via a hash function or error detection code or error correction code.

230. Apparatus of any of previous embodiments 227 to 229, wherein the apparatus is configured to decode, from the data stream (45), a higher-level identification parameter (310) for identifying a collection of more than one predetermined individually accessible portion.

231. Apparatus of embodiment 230, wherein the higher-level identification parameter (310) is related to the identification parameters (310) of the more than one predetermined individually accessible portion via a hash function or error detection code or error correction code.

232. Apparatus of any of previous embodiments 227 to 231, wherein the apparatus is configured to decode, from the data stream (45), the individually accessible portions (200) using context-adaptive arithmetic decoding and using context initialization at a start of each individually accessible portion.

233. Apparatus of any of previous embodiments 227 to 232, wherein the apparatus is configured to read, from the data stream, for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

234. Apparatus of any of previous embodiments 227 to 233, wherein the neural network portions comprise one or more sub-portions of a neural network layer (210, 30) of the neural network and/or one or more neural network layers of the neural network.

235. Apparatus of any previous embodiment 169 to 234, wherein the apparatus is configured to decode a representation of a neural network (10) from a data stream (45), into which same is encoded in a layered manner so that different versions (330) of the neural network are encoded into the data stream (45), and so that the data stream (45) is structured into one or more individually accessible portions (200), each portion relating to a corresponding version of the neural network, wherein the apparatus is configured decode a first version (330₂) of the neural network encoded from a first portion by using delta-decoding relative to a second version (330i) of the neural network encoded into a second portion, and/or by decoding from the data stream (45) one or more compensating neural network portions (332) each of which is to be, for performing an inference based on the first version (330₂) of the neural network, executed in addition to an execution of a corresponding neural network portion (334) of a second version (330i) of the neural network encoded into a second portion, and wherein outputs of the respective compensating neural network portion (332) and corresponding neural network portion (334) are to be summed up.

236. Apparatus for decoding a representation of a neural network (10) from a data stream (45), into which same is encoded in a layered manner so that different versions (330) of the neural network are encoded into the data stream (45), and so that the data stream (45) is structured into one or more individually accessible portions (200), each portion relating to a corresponding version of the neural network, wherein the apparatus is configured to decode a first version (330₂) of the neural network from a first portion by using delta-decoding relative to a second version (330i) of the neural network encoded into a second portion, and/or by decoding from the data stream (45) one or more compensating neural network portions (332) each of which is to be, for performing an inference based on the first version (330₂) of the neural network, executed in addition to an execution of a corresponding neural network portion (334) of a second version (330i) of the neural network encoded into a second portion, and wherein outputs of the respective compensating neural network portion (332) and corresponding neural network portion (334) are to be summed up.

237. Apparatus of embodiment 235 or embodiment 236, wherein the apparatus is configured to decode, from a second portion of the data stream (45), the second version (330i) of the neural network; and wherein the apparatus is configured to decode, from a first portion of the data stream (45), the first version (330₂) of the neural network delta-decoding relative to the second version (330i) of the neural network encoded into the second portion in terms of weight and/or bias differences, and/or additional neurons (14, 18, 20) or neuron interconnections (22, 24).

238. Apparatus of any previous embodiment 235 to 237, wherein the apparatus is configured to decode, from the data stream (45), the individually accessible portions (200) using context-adaptive arithmetic decoding (600) and using context initialization at a start of each individually accessible portion.

239. Apparatus of any previous embodiment 235 to 238, wherein the apparatus is configured to decode, from the data stream (45), for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

240. Apparatus of any previous embodiment 235 to 239, wherein the apparatus is configured to decode, from the data stream, for each of one or more predetermined individually accessible portions (200) an identification parameter (310) for identifying the respective predetermined individually accessible portion.

241. Apparatus of any previous embodiment 169 to 240, wherein the apparatus is configured to decode a representation of a neural network (10) from a data stream (45), wherein the data stream (45) is structured into individually accessible portions (200), each portion representing a corresponding neural network portion of the neural network, wherein the apparatus is configured to decode from the data stream (45), for each of one or more predetermined individually accessible portions a supplemental data (350) for supplementing the representation of the neural network.

242. Apparatus for decoding a representation of a neural network (10) from a data stream (45), wherein the data stream (45) is structured into individually accessible portions (200), each portion representing a corresponding neural network portion of the neural network, wherein the apparatus is configured to decode from the data stream (45), for each of one or more predetermined individually accessible portions (200) a supplemental data (350) for supplementing the representation of the neural network.

243. Apparatus of embodiment 241 or embodiment 242, wherein the data stream (45) indicates the supplemental data (350) as being dispensable for inference based on the neural network.

244. Apparatus of any previous embodiment 241 to 243, wherein the apparatus is configured to decode the supplemental data (350) for supplementing the representation of the neural network for the one or more predetermined individually accessible portions (200) from further individually accessible portions, wherein the data stream (45) comprises for each of the one or more predetermined individually accessible portions a corresponding further predetermined individually accessible portion relating to the neural network portion to which the respective predetermined individually accessible portion corresponds.

245. Apparatus of any previous embodiment 241 to 244, wherein the neural network portions comprise neural network layers (210, 30) of the neural network and/or layer portions into which a predetermined neural network layer of the neural network is subdivided.

246. Apparatus of any previous embodiment 241 to 245, wherein the apparatus is configured to decode the individually accessible portions (200) using context-adaptive arithmetic decoding and using context initialization at a start of each individually accessible portion.

247. Apparatus of any previous embodiment 241 to 246, wherein the apparatus is configured to read, from the data stream, for each individually accessible portion a start code (242) at which the respective individually accessible portion begins, and/or a pointer (220, 244) pointing to a beginning of the respective individually accessible portion, and/or a data stream length parameter indicating a data stream length (246) of the respective individually accessible portion for skipping the respective individually accessible portion in parsing the data stream.

248. Apparatus of any previous embodiment 241 to 247, wherein the supplemental data (350) relates to relevance scores of neural network parameters (32), and/or perturbation robustness of neural network parameters (32).

249. Apparatus of any previous embodiment 169 to 248, for decoding a representation of a neural network (10) from a data stream (45), wherein the apparatus is configured to decode from the data stream (45) hierarchical control data (400) structured into a sequence (410) of control data portions (420), wherein the control data portions provide information on the neural network at increasing details along the sequence of control data portions.

250. Apparatus for decoding a representation of a neural network (10) from a data stream (45), wherein the apparatus is configured to decode from the data stream (45) hierarchical control data (400) structured into a sequence (410) of control data portions (420), wherein the control data portions provide information on the neural network at increasing details along the sequence of control data portions.

251. Apparatus of embodiment 249 or embodiment 250, wherein at least some of the control data portions (420) provide information on the neural network which is partially redundant.

252. Apparatus of any previous embodiment 249 to 251, wherein a first control data portion provides the information on the neural network by way of indicating a default neural network type implying default settings and a second control data portion comprises a parameter to indicate each of the default settings.

253. Apparatus for performing an inference using a neural network, comprising an apparatus for decoding a data stream (45) according to any of embodiments 169 to 252, so as to derive from the data stream (45) the neural network, and a processor configured to perform the inference based on the neural network.

254. Method for encoding a representation of a neural network into a data stream (45), comprising providing the data stream with a serialization parameter indicating a coding order at which neural network parameters, which define neuron interconnections of the neural network, are encoded into the data stream.

255. Method for encoding a representation of a neural network into a data stream, providing the data stream with a numerical computation representation parameter indicating a numerical representation and bit size at which neural network parameters of the neural network, which are encoded into the data stream, are to be represented when using the neural network for inference.

256. Method for encoding a representation of a neural network into a data stream, so that the data stream is structured into one or more individually accessible portions, each individually accessible portion representing a corresponding neural network layer of the neural network, wherein the method comprises providing the data stream with, for a predetermined neural network layer, a neural network layer type parameter indicating a neural network layer type of the predetermined neural network layer of the neural network.

257. Method for encoding a representation of a neural network into a data stream, so that the data stream is structured into one or more individually accessible portions, each portion representing a corresponding neural network layer of the neural network, wherein the comprises providing the data stream with, for each of one or more predetermined individually accessible portions, a pointer pointing to a beginning of the respective predetermined individually accessible portion.

258. Method for encoding a representation of a neural network into a data stream, so that the data stream is structured into one or more individually accessible portions, each individually accessible portion representing a corresponding neural network layer of the neural network, and so that the data stream is, within a predetermined portion, further structured into individually accessible sub-portions, each sub-portion representing a corresponding neural network portion of the respective neural network layer of the neural network, wherein the method comprises providing the data stream with, for each of one or more predetermined individually accessible sub-portions a start code at which the respective predetermined individually accessible subportion begins, and/or a pointer pointing to a beginning of the respective predetermined individually accessible sub-portion, and/or a data stream length parameter indicating a data stream length of the respective predetermined individually accessible sub-portion for skipping the respective predetermined individually accessible sub-portion in parsing the data stream.

259. Method for encoding a representation of a neural network into a data stream, so that the data stream is structured into individually accessible portions, each individually accessible portion representing a corresponding neural network portion of the neural network, wherein the method comprises providing the data stream with, for each of one or more predetermined individually accessible portions, a processing option parameter indicating one or more processing options which have to be used or which may optionally be used when using the neural network for inference.

260. Method for encoding neural network parameters, which represent a neural network, into a data stream, so that the neural network parameters are encoded into the data stream in a manner quantized onto quantization indices, and the neural network parameters are encoded into the data stream so that neural network parameters in different neural network portions of the neural network are quantized differently, wherein the method comprises providing the data stream indicating, for each of the neural network portions, a reconstruction rule for dequantizing neural network parameters relating to the respective neural network portion.

261. Method for encoding neural network parameters, which represent a neural network, into a data stream, so that the neural network parameters are encoded into the data stream in a manner quantized onto quantization indices, wherein the method comprises providing the data stream with, for indicating a reconstruction rule for dequantizing the neural network parameters, a quantization step size parameter indicating a quantization step size, and a parameter set defining a quantization-index-to-reconstruction-level mapping, wherein the reconstruction rule of the predetermined neural network portion is defined by the quantization step size for quantization indices within a predetermined index interval, and the quantization-index-to-reconstruction-level mapping for quantization indices outside the predetermined index interval.

262. Method for encoding a representation of a neural network into a data stream, so that the data stream is structured into individually accessible portions, each portion representing a corresponding neural network portion of the neural network, wherein the method comprises providing the data stream with, for each of one or more predetermined individually accessible portions, an identification parameter for identifying the respective predetermined individually accessible portion.

263. Method for encoding a representation of a neural network into a data stream in a layered manner so that different versions of the neural network are encoded into the data stream, and so that the data stream is structured into one or more individually accessible portions, each portion relating to a corresponding version of the neural network, wherein the method comprises encoding a first version of the neural network into a first portion delta-coded relative to a second version of the neural network encoded into a second portion, and/or in form of one or more compensating neural network portions each of which is to be, for performing an inference based on the first version of the neural network, executed in addition to an execution of a corresponding neural network portion of a second version of the neural network encoded into a second portion, and wherein outputs of the respective compensating neural network portion and corresponding neural network portion are to be summed up.

264. Method for encoding a representation of a neural network into a data stream, so that the data stream is structured into individually accessible portions, each portion representing a corresponding neural network portion of the neural network, wherein the method comprises providing the data stream with, for each of one or more predetermined individually accessible portions a supplemental data for supplementing the representation of the neural network.

265. Method for encoding a representation of a neural network into a data stream, wherein the method comprises providing the data stream with hierarchical control data structured into a sequence of control data portions, wherein the control data portions provide information on the neural network at increasing details along the sequence of control data portions.

266. Method for decoding a representation of a neural network from a data stream, comprising decoding from the data stream a serialization parameter indicating a coding order at which neural network parameters, which define neuron interconnections of the neural network, are encoded into the data stream.

267. Method for decoding a representation of a neural network from a data stream, wherein the method comprises decoding from the data stream a numerical computation representation parameter indicating a numerical representation and bit size at which neural network parameters of the neural network, which are encoded into the data stream, are to be represented when using the neural network for inference, and to use the numerical representation and bit size for representing the neural network parameters decoded from the data stream.

268. Method for decoding a representation of a neural network from a data stream, wherein the data stream is structured into one or more individually accessible portions, each portion representing a corresponding neural network layer of the neural network, wherein the method comprises decoding from the data stream, for a predetermined neural network layer, a neural network layer type parameter indicating a neural network layer type of the predetermined neural network layer of the neural network.

269. Method for decoding a representation of a neural network from a data stream, wherein the data stream is structured into one or more individually accessible portions, each portion representing a corresponding neural network layer of the neural network, wherein the method comprises decoding from the data stream, for each of one or more predetermined individually accessible portions, a pointer pointing to a beginning of the respective predetermined individually accessible portion.

270. Method for decoding a representation of a neural network from a data stream, wherein the data stream is structured into one or more individually accessible portions, each individually accessible portion representing a corresponding neural network layer of the neural network, and wherein the data stream is, within a predetermined portion, further structured into individually accessible sub-portions, each sub-portion representing a corresponding neural network portion of the respective neural network layer of the neural network, wherein the method comprises decoding from the data stream, for each of one or more predetermined individually accessible sub-portions a start code at which the respective predetermined individually accessible sub-portion begins, and/or a pointer pointing to a beginning of the respective predetermined individually accessible sub-portion, and/or a data stream length parameter indicating a data stream length of the respective predetermined individually accessible sub-portion for skipping the respective predetermined individually accessible sub-portion in parsing the data stream.

271. Method for decoding a representation of a neural network from a data stream, wherein the data stream is structured into individually accessible portions, each individually accessible portion representing a corresponding neural network portion of the neural network, wherein the method comprises decoding from the data stream, for each of one or more predetermined individually accessible portions, a processing option parameter indicating one or more processing options which have to be used or which may optionally be used when using the neural network for inference.

272. Method Apparatus for decoding neural network parameters, which represent a neural network, from a data stream, wherein the neural network parameters are encoded into the data stream in a manner quantized onto quantization indices, and the neural network parameters are encoded into the data stream so that neural network parameters in different neural network portions of the neural network are quantized differently, wherein the method comprises decoding from the data stream, for each of the neural network portions, a reconstruction rule for dequantizing neural network parameters relating to the respective neural network portion.

273. Method for decoding neural network parameters, which represent a neural network, from a data stream, wherein the neural network parameters are encoded into the data stream in a manner quantized onto quantization indices, wherein the method comprises deriving from the data stream a reconstruction rule for dequantizing the neural network parameters by decoding from the data stream a quantization step size parameter indicating a quantization step size, and a parameter set defining a quantization-index-to-reconstruction-level mapping, wherein the reconstruction rule of the predetermined neural network portion is defined by the quantization step size for quantization indices within a predetermined index interval, and the quantization-index-to-reconstruction-level mapping for quantization indices outside the predetermined index interval.

274. Method for decoding a representation of a neural network from a data stream, wherein the data stream is structured into individually accessible portions, each portion representing a corresponding neural network portion of the neural network, wherein the method comprises decoding from the data stream, for each of one or more predetermined individually accessible portions, an identification parameter for identifying the respective predetermined individually accessible portion.

275. Method for decoding a representation of a neural network from a data stream, into which same is encoded in a layered manner so that different versions of the neural network are encoded into the data stream, and so that the data stream is structured into one or more individually accessible portions, each portion relating to a corresponding version of the neural network, wherein the method comprises decoding a first version of the neural network from a first portion by using delta-decoding relative to a second version of the neural network encoded into a second portion, and/or by decoding from the data stream one or more compensating neural network portions each of which is to be, for performing an inference based on the first version of the neural network, executed in addition to an execution of a corresponding neural network portion of a second version of the neural network encoded into a second portion, and wherein outputs of the respective compensating neural network portion and corresponding neural network portion are to be summed up.

276. Method for decoding a representation of a neural network from a data stream, wherein the data stream is structured into individually accessible portions, each portion representing a corresponding neural network portion of the neural network, wherein the method comprises decoding from the data stream, for each of one or more predetermined individually accessible portions a supplemental data for supplementing the representation of the neural network.

277. Method for decoding a representation of a neural network from a data stream, wherein the method comprises decoding from the data stream hierarchical control data structured into a sequence of control data portions, wherein the control data portions provide information on the neural network at increasing details along the sequence of control data portions.

278. Computer program for, when executed by a computer, causing the computer to perform any method of embodiments 254 to 277.

### Implementation Alternatives:

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are advantageously performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### 8 BIBLIOGRAPHY

Andrew Kerr, D. M. (2017, 5). Retrieved from https://devblogs.nvidia.com/cutlass-linear-algebra-cuda/
Chollet, F. (2016). Xception: Deep Learning with Depthwise Separable Convolutions. Retrieved from https://arxiv.org/abs/1610.02357
Christos Louizos, K. U. (2017). Bayesian Compression for Deep Learning. NIPS.
Sebastian Lapuschkin, S. W.-R. (2019). Unmasking Clever Hans predictors and assessing what machines really learn. Nature Communications.
Tao, K. C. (2018). Once for All: A Two-Flow Convolutional Neural Network for Visual Tracking. IEEE Transactions on Circuits and Systems for Video Technology, 3377-3386.

I/We claim:

1. Data stream having a representation of a neural network encoded thereinto, the data stream comprising serialization parameter indicating a coding order at which neural network parameters, which define neuron interconnections of the neural network, are encoded into the data stream, wherein the neural network parameters are coded into the data stream using context-adaptive arithmetic coding.

2. Apparatus for encoding a representation of a neural network into a data stream, wherein the apparatus is configured to provide the data stream with a serialization parameter indicating a coding order at which neural network parameters, which define neuron interconnections of the neural network, are encoded into the data stream, wherein the apparatus is configured to encode, into the data stream, the neural network parameters using context-adaptive arithmetic encoding.

3. Apparatus for decoding a representation of a neural network from a data stream, wherein the apparatus is configured to decode from the data stream a serialization parameter indicating a coding order at which neural network parameters, which define neuron interconnections of the neural network, are encoded into the data stream, wherein the apparatus is configured to decode, from the data stream, the neural network parameters using context-adaptive arithmetic decoding.

4. Apparatus of claim 3, wherein the data stream is structured into one or more individually accessible portions, each individually accessible portion representing a corresponding neural network layer of the neural network, and
wherein the apparatus is configured to decode serially, from the data stream, neural network parameters, which define neuron interconnections of the neural network within a predetermined neural network layer, and
use the coding order to assign neural network parameters serially decoded from the data stream to the neuron interconnections.

5. Apparatus of claim 3, wherein the serialization parameter is indicative of a permutation using which the coding order permutes neurons of a neural network layer relative to a default order.

6. Apparatus of claim 5, wherein the permutation orders the neurons of the neural network layer in a manner so that the neural network parameters monotonically increase along the coding order or monotonically decrease along the coding order.

7. Apparatus of claim 5, wherein the permutation orders the neurons of the neural network layer in a manner so that, among predetermined coding orders signalable by the serialization parameter, a bitrate for coding the neural network parameters into the data stream is lowest for the permutation indicated by the serialization parameter.

8. Apparatus of claim 3, wherein the neural network parameters comprise weights and biases.

9. Apparatus of claim 3, wherein the apparatus is configured to decode, from the data stream, individually accessible sub-portions, into which individually accessible portions the data stream is structured, each sub-portion representing a corresponding neural network portion of the neural network, so that each sub-portion is completely traversed by the coding order before a subsequent sub-portion is traversed by the coding order.

10. Apparatus of claim 4, wherein the neural network parameters are decoded from the data stream using context-adaptive arithmetic decoding and using context initialization at a start of any individually accessible portion or sub-portion.

11. Apparatus of claim 4, wherein the apparatus is configured to decode, from the data stream, start codes at which each individually accessible portion or sub-portion begins, and/or pointers pointing to beginnings of each individually accessible portion or sub-portion, and/or pointers data stream lengths of each individually accessible portion or sub-portion for skipping the respective individually accessible portion or sub-portion in parsing the data stream.

12. Apparatus of claim 3, wherein the apparatus is configured to decode, from the data stream, a numerical computation representation parameter indicating a numerical representation and bit size at which the neural network parameters are to be represented when using the neural network for inference.

13. Apparatus of claim 3, wherein the data stream, is structured into individually accessible sub-portions, each individually accessible sub-portion representing a corresponding neural network portion of the neural network, so that each individually accessible sub-portion is completely traversed by the coding order before a subsequent individually accessible sub-portion is traversed by the coding order, wherein the apparatus is configured to decode, from the data stream, for a predetermined individually accessible sub-portion the neural network parameter and a type parameter indicting a parameter type of the neural network parameter decoded from the predetermined individually accessible sub-portion.

14. Apparatus of claim 13, wherein the type parameter discriminates, at least, between neural network weights and neural network biases.

15. Apparatus of claim 3, wherein the data stream, is structured into one or more individually accessible portions, each one or more individually accessible portion representing a corresponding neural network layer of the neural network, and
wherein the apparatus is configured to decode, from the data stream, for a predetermined neural network layer, a neural network layer type parameter indicating a neural network layer type of the predetermined neural network layer of the neural network.

16. Apparatus of claim 15, wherein the neural network layer type parameter discriminates, at least, between a fully-connected and a convolutional layer type.

17. Apparatus of claim 3, wherein the apparatus is configured to decode a representation of a neural network from the data stream, wherein the data stream is structured into one or more individually accessible portions, each individually accessible portion representing a corresponding neural network layer of the neural network, and wherein the data stream is, within a predetermined portion, further structured into individually accessible sub-portions, each sub-portion representing a corresponding neural network portion of the respective neural network layer of the neural network, wherein the apparatus is configured to decode from the data stream, for each of one or more predetermined individually accessible sub-portions
a start code at which the respective predetermined individually accessible sub-portion begins, and/or
a pointer pointing to a beginning of the respective predetermined individually accessible sub-portion, and/or
a data stream length parameter indicating a data stream length of the respective predetermined individually accessible sub-portion for skipping the respective predetermined individually accessible sub-portion in parsing the data stream.

18. Apparatus of claim 17, wherein the apparatus is configured to decode, from the data stream, the representation of the neural network using context-adaptive arithmetic decoding and using context initialization at a start of each individually accessible portion and each individually accessible sub-portion.

19. Apparatus of claim 3, wherein the apparatus is configured to decode a representation of a neural network from a data stream, wherein the data stream is structured into individually accessible portions, each portion representing a corresponding neural network portion of the neural network, wherein the apparatus is configured to decode from the data stream, for each of one or more predetermined individually accessible portions, an identification parameter for identifying the respective predetermined individually accessible portion.

20. Apparatus of claim 19, wherein the identification parameter is related to the respective predetermined individually accessible portion via a hash function or error detection code or error correction code.

21. Apparatus of claim 19, wherein the apparatus is configured to decode, from the data stream, a higher-level identification parameter for identifying a collection of more than one predetermined individually accessible portion.

22. Apparatus of claim 21, wherein the higher-level identification parameter is related to the identification parameters of the more than one predetermined individually accessible portion via a hash function or error detection code or error correction code.

23. Apparatus of claim 3, wherein the apparatus is configured to decode a representation of a neural network from a data stream, wherein the data stream is structured into individually accessible portions, each portion representing a corresponding neural network portion of the neural network, wherein the apparatus is configured to decode from the data stream, for each of one or more predetermined individually accessible portions a supplemental data for supplementing the representation of the neural network.

24. Apparatus of claim 23, wherein the data stream indicates the supplemental data as being dispensable for inference based on the neural network.

25. Apparatus of claim 23, wherein the apparatus is configured to decode the supplemental data for supplementing the representation of the neural network for the one or more predetermined individually accessible portions from further individually accessible portions, wherein the data stream comprises for each of the one or more predetermined individually accessible portions a corresponding further predetermined individually accessible portion relating to the neural network portion to which the respective predetermined individually accessible portion corresponds.

26. Apparatus of claim 23, wherein the supplemental data relates to
relevance scores of neural network parameters, and/or
perturbation robustness of neural network parameters.

27. Apparatus of claim 3, for decoding a representation of a neural network from a data stream, wherein the apparatus is configured to decode from the data stream hierarchical control data structured into a sequence of control data portions, wherein the control data portions provide information on the neural network at increasing details along the sequence of control data portions.

28. Apparatus of claim 27, wherein at least some of the control data portions provide information on the neural network which is partially redundant.

29. Apparatus of claim 27, wherein a first control data portion provides the information on the neural network by way of indicating a default neural network type implying default settings and a second control data portion comprises a parameter to indicate each of the default settings.

30. Apparatus for performing an inference using a neural network, comprising
an apparatus for decoding a data stream according to claim 3, so as to derive from the data stream the neural network, and
a processor configured to perform the inference based on the neural network.

31. Method for encoding a representation of a neural network into a data stream, comprising providing the data stream with a serialization parameter indicating a coding order at which neural network parameters, which define neuron interconnections of the neural network, are encoded into the data stream, wherein the method comprises encoding, into the data stream, the neural network parameters using context-adaptive arithmetic encoding.

32. Method for decoding a representation of a neural network from a data stream, comprising decoding from the data stream a serialization parameter indicating a coding order at which neural network parameters, which define neuron interconnections of the neural network, are encoded into the data stream, wherein the method comprises decoding, from the data stream, the neural network parameters using context-adaptive arithmetic decoding.

33. A non-transitory digital storage medium having a computer program stored thereon to perform the method for encoding a representation of a neural network into a data stream, comprising providing the data stream with a serialization parameter indicating a coding order at which neural network parameters, which define neuron interconnections of the neural network, are encoded into the data stream, wherein the method comprises encoding, into the data stream, the neural network parameters using context-adaptive arithmetic encoding,
when said computer program is run by a computer.

34. A non-transitory digital storage medium having a computer program stored thereon to perform the method for decoding a representation of a neural network from a data stream, comprising decoding from the data stream a serialization parameter indicating a coding order at which neural network parameters, which define neuron interconnections of the neural network, are encoded into the data stream, wherein the method comprises decoding, from the data stream, the neural network parameters using context-adaptive arithmetic decoding,
when said computer program is run by a computer.
